(19) United States
(12) Patent Application Publication
(10) Pub. No.: US 2020/0006328 A1
(43) Pub. Date: Jan. 2, 2020

(54) SEMICONDUCTOR DEVICE AND METHOD FOR MANUFACTURING THE SAME

(71) Applicant: SEMICONDUCTOR ENERGY LABORATORY CO., LTD., ATSUGI-SHI, KANAGAWA-KEN (JP)

(72) Inventors: Shunpei YAMAZAKI, Setagaya, Tokyo (JP); Yuta ENDO, Atsugi, Kanagawa (JP); Shinya SASAGAWA, Chigasaki, Kanagawa (JP); Shuhei NAGATSUKA, Atsugi, Kanagawa (JP)

(73) Assignee: SEMICONDUCTOR ENERGY LABORATORY CO., LTD., ATSUGI-SHI, KANAGAWA-KEN (JP)

(21) Appl. No.: 16/483,302

(22) PCT Filed: Jan. 31, 2018
(86) PCT No.: PCT/IB2018/050581

§ 371 Date: Aug. 2, 2019

(30) Foreign Application Priority Data
Feb. 10, 2017 (JP) 2017-023595
Feb. 17, 2017 (JP) 2017-027613

(51) Int. Cl. H01L 27/07; H01L 29/786

(52) U.S. Cl. CPC H01L 27/0733; H01L 29/7869

(57) ABSTRACT

A favorable semiconductor device for miniaturization and high integration is provided. One embodiment of the present invention includes a first oxide including a first region and second region adjacent to each other, a third region and a fourth region with the first region and the second region provided therebetween, a second oxide over the first region, a first insulator over the second oxide, a first conductor over the first insulator, a second insulator over the second oxide and on side surfaces of the first insulator and the first conductor, a third insulator over the second region and on a side surface of the second insulator, and a second conductor over the second region with the third insulator provided therebetween. A part of the third insulator is positioned between the second conductor and the side surface of the second insulator.

### TECHNICAL FIELD

One embodiment of the present invention relates to a semiconductor device and a manufacturing method thereof. Another embodiment of the present invention relates to a semiconductor wafer, a module, and an electronic device.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. A display device (e.g., a liquid crystal display device and a light-emitting display device), a projection device, a lighting device, an electro-optical device, a power storage device, a memory device, a semiconductor circuit, an imaging device, an electronic device, and the like may include a semiconductor device.

Note that one embodiment of the present invention is not limited to the above technical field. One embodiment of the invention disclosed in this specification and the like relates to an object, a method, or a manufacturing method. Furthermore, one embodiment of the present invention relates to a process, a machine, manufacture, or a composition of matter.

### BACKGROUND ART

In recent years, semiconductor devices have been developed to be used mainly for an LSI, a CPU, or a memory. A CPU is an aggregation of semiconductor elements each provided with an electrode which is a connection terminal, which includes a semiconductor integrated circuit (including at least a transistor and a memory) separated from a semiconductor wafer.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is applied to a wide range of electronic devices such as an integrated circuit (IC) or an image display device (also simply referred to as a display device). A silicon-based semiconductor material is widely known as a material for a semiconductor thin film applicable to the transistor; in addition, an oxide semiconductor has attracted attention as another material.

It is known that a transistor including an oxide semiconductor has an extremely low leakage current in an off state. For example, a low-power-consumption CPU utilizing a characteristic of low leakage current of the transistor including an oxide semiconductor has been disclosed (see Patent Document 1).

In addition, a technique in which oxide semiconductor layers with different electron affinities (or conduction band minimum states) are stacked to increase the carrier mobility of a transistor is disclosed (see Patent Documents 2 and 3).

In recent years, demand for an integrated circuit in which transistors and the like are integrated with high density has risen with reductions in the size and weight of an electronic device. In addition, the productivity of a semiconductor device including an integrated circuit is required to be improved.

### REFERENCE

### Patent Document

### [Patent Document 1] Japanese Published Patent Application No. 2012-257187

### [Patent Document 2] Japanese Published Patent Application No. 2011-124360

### [Patent Document 3] Japanese Published Patent Application No. 2011-138934

### DISCLOSURE OF INVENTION

Another object of one embodiment of the present invention is to provide a semiconductor device that can be miniaturized or highly integrated. Another object of one embodiment of the present invention is to provide a semiconductor device that can be manufactured with high productivity. Another object of one embodiment of the present invention is to provide a semiconductor device with high design flexibility. Another object of one embodiment of the present invention is to provide a low-power semiconductor device.

An object of one embodiment of the present invention is to provide a semiconductor device having favorable electrical characteristics. Another object of one embodiment of the present invention is to provide a semiconductor device capable of retaining data for a long time. Another object of one embodiment of the present invention is to provide a semiconductor device capable of high-speed data writing. Another object of one embodiment of the present invention is to provide a novel semiconductor device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention is a semiconductor device including a first oxide including a first region and a second region adjacent to each other and a third region and a fourth region with the first region and the second region provided between the third region and the fourth region, a second oxide over the first region, a first insulator over the second oxide, a first conductor over the first insulator, a second insulator over the second oxide and on a side surface of the first insulator and on a side surface of the first conductor, a third insulator over the second region and on a side surface of the second insulator, and a second conductor over the second region with the third insulator provided between the second conductor and the second region. A part of the third insulator is positioned between the second conductor and the side surface of the second insulator.

One embodiment of the present invention is a semiconductor device including a transistor, a capacitor, a first oxide including a first region and a second region adjacent to each other and a third region and a fourth region with the first region and the second region provided between the third region and the fourth region, a second oxide over the first region, a first insulator over the second oxide, a first conductor over the first insulator, a second insulator over the second oxide and on a side surface of the first insulator and on a side surface of the first conductor, a third insulator over the second region and on a side surface of the second insulator, and a second conductor over the second region with the third insulator provided between the second conductor and the second region. A part of the third insulator is positioned between the second conductor and the side surface of the second insulator. A part of the first region serves as a channel formation region of the transistor. The first insulator serves as a gate insulating film of the transistor. The first conductor serves as a gate electrode of the transistor. The second region serves as a first electrode of the capacitor. The third insulator serves as a dielectric of the capacitor. The second conductor serves as a second electrode of the capacitor.

In the above structure, the fourth region is adjacent to the second region, the third region serves as one of a source and a drain of the transistor, and the second region and the fourth region serves as the other of the source and the drain of the transistor.

In the above structure, the first oxide is over a third conductor and a bottom surface of the fourth region is in contact with a top surface of the third conductor.

One embodiment of the present invention is a semiconductor device including a first oxide including a first region and a second region adjacent to each other and a third region and a fourth region with the first region and the second region provided between the third region and the fourth region, a second oxide over the first region, a first insulator over the second oxide, a first conductor over the first insulator, a second insulator provided over the second oxide and on a side surface of the first insulator and on a side surface of the first conductor, a third insulator provided over the second region and on a side surface of the second insulator, a second conductor over the second region with the third insulator provided between the second conductor and the second region, and a third conductor overlapping with the second conductor with the second region provided between the third conductor and the second conductor. A part of the third insulator is positioned between the second conductor and the side surface of the second insulator

One embodiment of the present invention is a semiconductor device including a transistor, a capacitor, a first oxide comprising a first region and a second region adjacent to each other and a third region and a fourth region with the first region and the second region provided between the third region and the fourth region, a second oxide over the first region, a first insulator over the second oxide, a first conductor over the first insulator, a second insulator over the second oxide and on a side surface of the first insulator and on a side surface of the first conductor, a third insulator over the second region and on a side surface of the second insulator, and a second conductor over the second region with the third insulator provided between the second conductor and the second region, and a third conductor overlapping with the second conductor with the second region provided between the third conductor and the second conductor. A part of the third insulator is positioned between the second conductor and the side surface of the second insulator. A part of the first region serves as a channel formation region of the transistor. The first insulator serves as a gate insulating film of the transistor. The first conductor serves as a gate electrode of the transistor. The second region serves as a first electrode of the capacitor. The third insulator serves as a dielectric of the capacitor. The second conductor serves as a second electrode of the capacitor. The third conductor serves as a plug electrically connected to the transistor.

In the above structure, the second region serves as one of a source and a drain of the transistor and wherein the third region serves as the other of the source and the drain of the transistor.

In the above structure, the first oxide over a third conductor and a bottom surface of the second region is in contact with a top surface of the third conductor.

In the above structure, the second insulator includes an oxide comprising one of or both aluminum and hafnium.

In the above structure, the first oxide includes In, an element M, and Zn, and the element M is Al, Ga, Y, or Sn.

In the above structure, the second oxide comprises In, an element M, and Zn, and the element M is Al, Ga, Y, or Sn.

According to one embodiment of the present invention, a semiconductor device that can be miniaturized or highly integrated can be provided. According to one embodiment of the present invention, a semiconductor device with high productivity can be provided. A semiconductor device with high design flexibility can be provided. A low-power semiconductor device can be provided.

One embodiment of the present invention can provide a semiconductor device with a simplified manufacturing process and a manufacturing method thereof. Furthermore, one embodiment of the present invention can provide a semiconductor device whose area is reduced and a manufacturing method thereof.

One embodiment of the present invention can provide a semiconductor device having favorable electric characteristics. A semiconductor device capable of retaining data for a long time can be provided. A semiconductor device capable of high-speed data writing can be provided. Alternatively, a novel semiconductor device can be provided.

Note that the description of these effects does not preclude the existence of other effects. One embodiment of the present invention does not have to have all the effects listed above. Other effects will be apparent from and can be derived from the description of the specification, the drawings, the claims, and the like.

### BRIEF DESCRIPTION OF DRAWINGS

FIGS. 1A to 1C are a top view and cross-sectional views of a semiconductor device of one embodiment of the present invention.

FIGS. 2A and 2B are each a cross-sectional view of a semiconductor device of one embodiment of the present invention.

FIGS. 3A to 3C are a top view and cross-sectional views of a semiconductor device of one embodiment of the present invention.

FIG. 4 is a cross-sectional view of a semiconductor device of one embodiment of the present invention.

FIGS. 5A to 5C are a top view and cross-sectional views of a semiconductor device of one embodiment of the present invention.

FIGS. 6A to 6C are a top view and cross-sectional views of a semiconductor device of one embodiment of the present invention.

FIGS. 7A to 7C are a top view and cross-sectional views illustrating a method for manufacturing a semiconductor device of one embodiment of the present invention.

FIGS. 8A to 8C are a top view and cross-sectional views illustrating a method for manufacturing a semiconductor device of one embodiment of the present invention.

FIGS. 9A to 9C are a top view and cross-sectional views illustrating a method for manufacturing a semiconductor device of one embodiment of the present invention.

FIGS. 10A to 10C are a top view and cross-sectional views illustrating a method for manufacturing a semiconductor device of one embodiment of the present invention.

FIGS. 11A to 11C are a top view and cross-sectional views illustrating a method for manufacturing a semiconductor device of one embodiment of the present invention.

FIGS. 12A to 12C are a top view and cross-sectional views illustrating a method for manufacturing a semiconductor device of one embodiment of the present invention.

FIGS. 13A to 13C are a top view and cross-sectional views illustrating a method for manufacturing a semiconductor device of one embodiment of the present invention.

FIGS. 14A to 14C are a top view and cross-sectional views illustrating a method for manufacturing a semiconductor device of one embodiment of the present invention.

FIGS. 15A to 15C are a top view and cross-sectional views illustrating a method for manufacturing a semiconductor device of one embodiment of the present invention.

FIGS. 16A to 16C are a top view and cross-sectional views illustrating a method for manufacturing a semiconductor device of one embodiment of the present invention.

FIGS. 17A to 17C are a top view and cross-sectional views illustrating a method for manufacturing a semiconductor device of one embodiment of the present invention.

FIGS. 18A to 18C are a top view and cross-sectional views illustrating a method for manufacturing a semiconductor device of one embodiment of the present invention.

FIGS. 19A to 19C are a top view and cross-sectional views illustrating a method for manufacturing a semiconductor device of one embodiment of the present invention.

FIGS. 20A to 20C are a top view and cross-sectional views illustrating a method for manufacturing a semiconductor device of one embodiment of the present invention.

FIGS. 21A to 21C are a top view and cross-sectional views of a semiconductor device of one embodiment of the present invention.

FIGS. 22A to 22D are a top view and cross-sectional views of a semiconductor device of one embodiment of the present invention.

FIGS. 23A and 23B are a circuit diagram and a cross-sectional view of a semiconductor device of one embodiment of the present invention.

FIGS. 24A and 24B are a circuit diagram and a cross-sectional view of a semiconductor device of one embodiment of the present invention.

FIGS. 25A to 25C are a top view and cross-sectional views of a semiconductor device of one embodiment of the present invention.

FIGS. 26A to 26C are a top view and cross-sectional views of a semiconductor device of one embodiment of the present invention.

FIG. 27 is a cross-sectional view illustrating a structure of a memory device of one embodiment of the present invention.

FIG. 28 is a cross-sectional view illustrating a structure of a memory device of one embodiment of the present invention.

FIG. 29 is a block diagram showing a configuration example of a memory device of one embodiment of the present invention.

FIGS. 30A to 30E are circuit diagrams illustrating a configuration example of a memory device of one embodiment of the present invention.

FIG. 31 is a block diagram illustrating a configuration example of a memory device of one embodiment of the present invention.

FIGS. 32A and 32B are a block diagram and a circuit diagram each illustrating a configuration example of a memory device of one embodiment of the present invention.

FIGS. 33A to 33C are block diagrams illustrating a configuration example of a semiconductor device of one embodiment of the present invention.

FIGS. 34A and 34B are a block diagram and a circuit diagram illustrating configuration examples of a semiconductor device of one embodiment of the present invention and FIG. 34C is a timing chart showing an operation example of the semiconductor device.

FIG. 35 is block diagram illustrating a configuration example of a semiconductor device of one embodiment of the present invention.

FIG. 36A is a circuit diagram illustrating a configuration example of a semiconductor device of one embodiment of the present invention and FIG. 36B is a timing chart showing an operation example of the semiconductor device.

FIG. 37 is a block diagram illustrating a structure example of an AI system of one embodiment of the present invention.

FIGS. 38A and 38B are block diagrams illustrating application examples of an AI system of one embodiment of the present invention.

FIG. 39 is a schematic perspective view illustrating a structure example of an IC including an AI system of one embodiment of the present invention.

FIGS. 40A to 40F each illustrate an electronic device of one embodiment of the present invention.

### BEST MODE FOR CARRYING OUT THE INVENTION

Hereinafter, embodiments will be described with reference to drawings. Note that the embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings are schematic views showing ideal examples, and embodiments of the present invention are not limited to shapes or values shown in the drawings. For example, in the actual manufacturing process, a layer, a resist mask, or the like might be unintentionally reduced in size by treatment such as etching, which is not illustrated in some cases for easy understanding. In the drawings, the same portions or portions having similar functions are denoted by the same reference numerals in different drawings, and explanation thereof will not be repeated in some cases. Furthermore, the same hatching pattern is applied to portions having similar functions, and the portions are not especially denoted by reference numerals in some cases.

Especially in a top view (also referred to as a “plan view”), a perspective view, or the like, some components might not be illustrated for easy understanding of the invention. In addition, some hidden lines and the like might not be shown.

Note that the ordinal numbers such as “first”, “second”, and the like in this specification and the like are used for convenience and do not denote the order of steps or the stacking order of layers. Therefore, for example, description can be made even when “first” is replaced with “second” or “third”, as appropriate. In addition, the ordinal numbers in this specification and the like are not necessarily the same as those which specify one embodiment of the present invention.

In this specification, terms for describing arrangement, such as “over”, “above”, “under”, and “below”, are used for convenience in describing a positional relation between components with reference to drawings. Furthermore, the positional relationship between components is changed as appropriate in accordance with the direction in which each component is described. Thus, there is no limitation on terms used in this specification, and description can be made appropriately depending on the situation.

For example, in this specification and the like, an explicit description “X and Y are connected” means that X and Y are electrically connected, X and Y are functionally connected, and X and Y are directly connected. Accordingly, without being limited to a predetermined connection relationship, for example, a connection relationship shown in drawings or texts, another connection relationship is included in the drawings or the texts.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, or a load) is not connected between X and Y, and the case where X and Y are connected without the element that allows the electrical connection between X and Y provided therebetween.

For example, in the case where X and Y are electrically connected, one or more elements that allow an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is turned on or off to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that allow a functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; or a control circuit) can be connected between X and Y. For example, even when another circuit is interposed between X and Y, X and Y are functionally connected if a signal output from X is transmitted to Y. Note that the case where X and Y are functionally connected includes the case where X and Y are directly connected and the case where X and Y are electrically connected.

In this specification and the like, a transistor is an element having at least three terminals of a gate, a drain, and a source. The transistor has a channel formation region between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Furthermore, functions of a source and a drain might be switched when a transistor of opposite polarity is employed or the direction of current flow is changed in circuit operation, for example. Therefore, the terms “source” and “drain” can be switched in some cases in this specification and the like.

Note that the channel length refers to, for example, the distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not fixed to one value in some cases. Thus, in this specification, the channel length is any one of values, the maximum value, the minimum value, or the average value in a region where a channel is formed.

The channel width refers to, for example, the length of a portion where a source and a drain face each other in a region where a semiconductor (or a portion where a current flows in a semiconductor when a transistor is on) and a gate electrode overlap with each other, or a region where a channel is formed. In one transistor, channel widths in all regions are not necessarily the same. In other words, the channel width of one transistor is not fixed to one value in some cases. Thus, in this specification, the channel width is any one of values, the maximum value, the minimum value, or the average value in a region where a channel is formed.

Note that depending on transistor structures, a channel width in a region where a channel is actually formed (hereinafter referred to as an “effective channel width”) is different from a channel width shown in a top view of a transistor (hereinafter referred to as an “apparent channel width”) in some cases. For example, in a transistor having a gate electrode covering the side surface of a semiconductor, an effective channel width is greater than an apparent channel width, and its influence cannot be ignored in some cases. For example, in a miniaturized transistor having a gate electrode covering the side surface of a semiconductor, the proportion of a channel formation region formed in the side surface of a semiconductor is increased. In that case, an effective channel width is greater than an apparent channel width.

In such a case, an effective channel width is difficult to measure in some cases. For example, to estimate an effective channel width from a design value, it is necessary to assume that the shape of a semiconductor is known as an assumption condition. Accordingly, in the case where the shape of a semiconductor is not known accurately, it is difficult to measure an effective channel width accurately.

Thus, in this specification, an apparent channel width is referred to as a surrounded channel width (SCW) in some cases. Furthermore, in this specification, in the case where the term “channel width” is simply used, it may represent a surrounded channel width or an apparent channel width. Alternatively, in this specification, in the case where the term “channel width” is simply used, it may represent an effective channel width. Note that a channel length, a channel width, an effective channel width, an apparent channel width, a surrounded channel width, and the like can be determined by analyzing a cross-sectional TEM image and the like.

Note that an impurity in a semiconductor refers to, for example, elements other than the main components of a semiconductor. For example, an element with a concentration lower than 0.1 atomic % can be regarded as an impurity. When an impurity is contained, the density of states (DOS) in a semiconductor may be increased, or the crystallinity may be decreased. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components of the oxide semiconductor; there are hydrogen, lithium, sodium, silicon, boron, phosphorus, carbon, and nitrogen, for example. For an oxide semiconductor, water also serves as an impurity in some cases. For an oxide semiconductor, entry of impurities may lead to formation of oxygen vacancies, for example. Furthermore, when the semiconductor is silicon, examples of an impurity which changes the characteristics of the semiconductor include oxygen, Group 1 elements except hydrogen, Group 2 elements, Group 13 elements, and Group 15 elements.

In this specification and the like, a silicon oxynitride film contains more oxygen than nitrogen. A silicon oxynitride film preferably contains, for example, oxygen, nitrogen, silicon, and hydrogen in the ranges of 55 atomic % to 65 atomic % inclusive, 1 atomic % to 20 atomic % inclusive, 25 atomic % to 35 atomic % inclusive, and 0.1 atomic % to 10 atomic % inclusive, respectively. A silicon nitride oxide film contains more nitrogen than oxygen. A silicon nitride oxide film preferably contains nitrogen, oxygen, silicon, and hydrogen in the ranges of 55 atomic % to 65 atomic % inclusive, 1 atomic % to 20 atomic % inclusive, 25 atomic % to 35 atomic % inclusive, and 0.1 atomic % to 10 atomic % inclusive, respectively.

In this specification and the like, the terms “film” and “layer” can be interchanged with each other. For example, the term “conductive layer” can be changed into the term “conductive film” in some cases. Also, the term “insulating film” can be changed into the term “insulating layer” in some cases.

In addition, in this specification and the like, the term “insulator” can be replaced with the term “insulating film” or “insulating layer”. Moreover, the term “conductor” can be replaced with the term “conductive film” or “conductive layer”. Furthermore, the term “semiconductor” can be replaced with the term “semiconductor film” or “semiconductor layer”.

Furthermore, unless otherwise specified, transistors described in this specification and the like are field effect transistors. Unless otherwise specified, transistors described in this specification and the like are n-channel transistors. Thus, unless otherwise specified, the threshold voltage (also referred to as “Vth”) is higher than 0 V.

In this specification and the like, the term “parallel” indicates that the angle formed between two straight lines is greater than or equal to −10° and less than or equal to 100, and accordingly also includes the case where the angle is greater than or equal to −50 and less than or equal to 50. In addition, the term “substantially parallel” indicates that the angle formed between two straight lines is greater than or equal to −300 and less than or equal to 300. The term “perpendicular” indicates that the angle formed between two straight lines is greater than or equal to 800 and less than or equal to 1000, and accordingly also includes the case where the angle is greater than or equal to 850 and less than or equal to 950. In addition, the term “substantially perpendicular” indicates that the angle formed between two straight lines is greater than or equal to 600 and less than or equal to 1200.

In this specification, trigonal and rhombohedral crystal systems are included in a hexagonal crystal system.

Note that in this specification, a barrier film refers to a film having a function of inhibiting the penetration of oxygen and impurities such as hydrogen. The barrier film that has conductivity may be referred to as a conductive barrier film.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is called an oxide semiconductor in some cases. In other words, an OS FET is a transistor including an oxide or an oxide semiconductor.

### Embodiment 1

An example of a semiconductor device including a transistor 200 of one embodiment of the present invention is described below.

### Structure Example 1 of Semiconductor Device

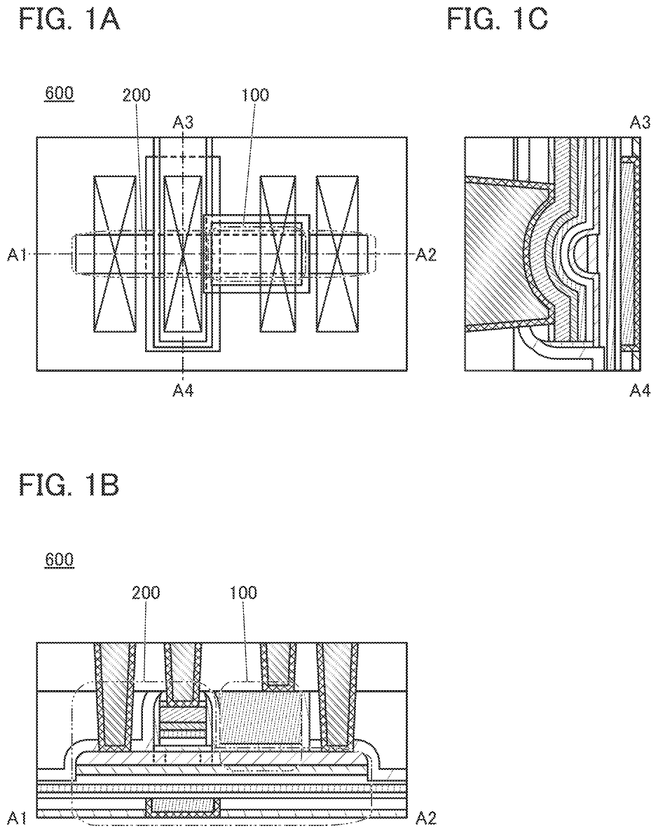

FIGS. 1A to 1C are a top view and cross-sectional views illustrating the transistor 200 and a capacitor 100 and the periphery of the transistor 200 of one embodiment of the present invention. Note that in this specification, a semiconductor device including one capacitor and at least one transistor is referred to as a cell.

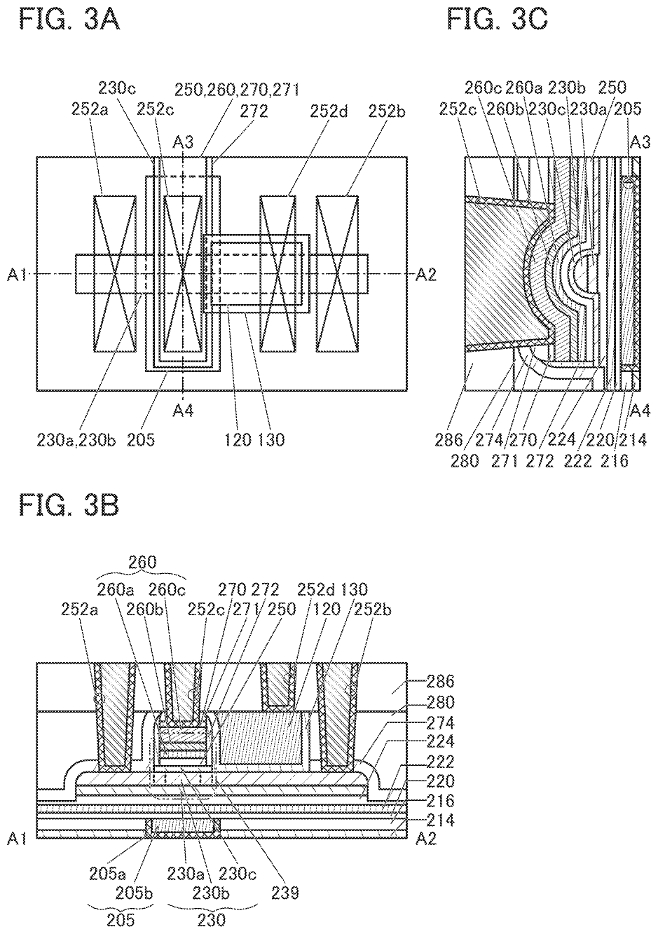

FIG. 1A is a top view of a cell 600 including the transistor 200 and the capacitor 100. FIGS. 1B and 1C are cross-sectional views of the cell 600. FIG. 1B is a cross-sectional view taken along dashed-dotted line A1-A2 in FIG. 1A, which corresponds to a cross-sectional view in the channel length direction of the transistor 200. FIG. 1C is a cross-sectional view taken along dashed-dotted line A3-A4 in FIG. 1A, which corresponds to a cross-sectional view in the channel width direction of the transistor 200. For simplification of the drawing, some components are not illustrated in the top view in FIG. 1A. Note that for simplification of the drawing, only some components are denoted by reference numerals in FIGS. 1A to 1C. Furthermore, components of the cell 600 illustrated in FIGS. 1A to 1C are denoted by reference numerals in FIGS. 3A to 3C, and detailed description thereof is given below.

The transistor 200 and the capacitor 100 are provided on the same layer, whereby part of components in the transistor 200 and part of components in the capacitor 100 can be used in common in the cell 600 of FIGS. 1A to 1C. That is, part of the components of the transistor 200 may function as part of the components of the capacitor 100.

Furthermore, part of the capacitor 100 or the entire capacitor 100 overlaps with the transistor 200, so that the total area of the projected area of the transistor 200 and the projected area of the capacitor 100 can be reduced.

Furthermore, the top surface of the capacitor 100 and the top surface of an insulator 280 that covers the transistor 200 are preferably at the same level in the cell 600 in FIGS. 1A to 1C. With this structure, the cell 600 whose surface has high planarity is formed. Thus, another structure body can be easily stacked over the cell 600.

With this structure, miniaturization or high integration of the semiconductor device can be achieved. Moreover, the design flexibility of the semiconductor device can be increased. Furthermore, the transistor 200 and the capacitor 100 can be formed through the same process. Accordingly, the process can be shortened, leading to an improvement in productivity.

### <Structure of Cell Array>

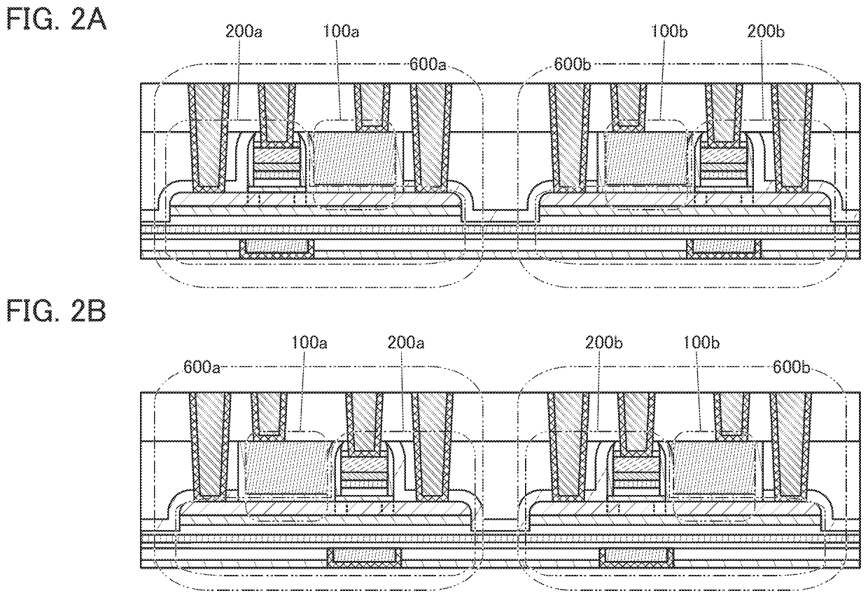

FIGS. 2A and 2B illustrate examples of cell arrays of this embodiment. For example, the cells 600 each including the transistor 200 and the capacitor 100 illustrated in FIGS. 1A to 1C are arranged in a matrix, whereby a cell array can be formed. FIGS. 2A and 2B are cross-sectional views that illustrate part of a row in which the cells 600 each of which is illustrated in FIGS. 1A to 1C are arranged in a matrix.

The semiconductor device in which a cell 600a including a transistor 200a and a capacitor 100a and the cell 600b including the transistor 200b and the capacitor 100b are arranged in one row is illustrated in FIGS. 2A and 2B.

The cell arrays illustrated in FIGS. 2A and 2B include a plurality of transistors (the transistor 200a and the transistor 200b in FIGS. 2A and 2B) and capacitors (the capacitor 100a and the capacitor 100b in FIGS. 2A and 2B).

### [Cell 600]

The semiconductor device of one embodiment of the present invention includes the transistor 200, the capacitor 100, the insulator 280 functioning as an interlayer film, and an insulator 286. Furthermore, a conductor 252 (a conductor 252a, a conductor 252b, a conductor 252c, and a conductor 252d) functioning as a plug that is electrically connected to the transistor 200 is included.

The conductors 252 are in contact with inner walls of an opening in the insulator 280 and the insulator 286. Here, the top surface of the conductor 252 can be substantially level with the top surface of the insulator 286. Note that although the conductors 252 in the transistor 200 each have a two-layer structure, one embodiment of the present invention is not limited thereto. For example, the conductors 252 may have a single-layer structure or a stacked-layer structure of three or more layers.

### [Transistor 200]

As illustrated in FIGS. 1A to 1C and FIGS. 3A to 3C, the transistor 200 includes insulators 214 and 216 provided over a substrate (not illustrated); a conductor 205 provided to be embedded in the insulators 214 and 216; an insulator 220 provided over the insulator 216 and the conductor 205; an insulator 222 provided over the insulator 220; an insulator 224 provided over the insulator 222; an oxide 230 (an oxide 230a, an oxide 230b, and an oxide 230c) provided over the insulator 224; an insulator 250 provided over the oxide 230; a conductor 260 (a conductor 260a, a conductor 260b, and a conductor 260c) provided over the insulator 250; an insulator 270 and an insulator 271 provided over the conductor 260; an insulator 272 provided in contact with at least side surfaces of the insulator 250 and the conductor 260; and an insulator 274 provided in contact with the oxide 230 and the insulator 272.

Although the transistor 200 has a structure in which the oxide 230a, the oxide 230b, and the oxide 230c are stacked, the present invention is not limited to this structure. For example, as illustrated in FIGS. 3A to 3C, the transistor 200 may have a three-layer structure of the oxide 230a, the oxide 230b, and the oxide 230c or may have a stacked-layer structure of three or more layers. Alternatively, the transistor 200 may have a structure in which only the oxide 230b is provided as an oxide or only the oxide 230b and the oxide 230c are provided as an oxide. Although the conductor 260a, the conductor 260b, and the conductor 260c are stacked in the transistor 200, the present invention is not limited to this structure. For example, the transistor 200 may have a single-layer structure, a two-layer structure, or a stacked-layer structure of four or more layers.

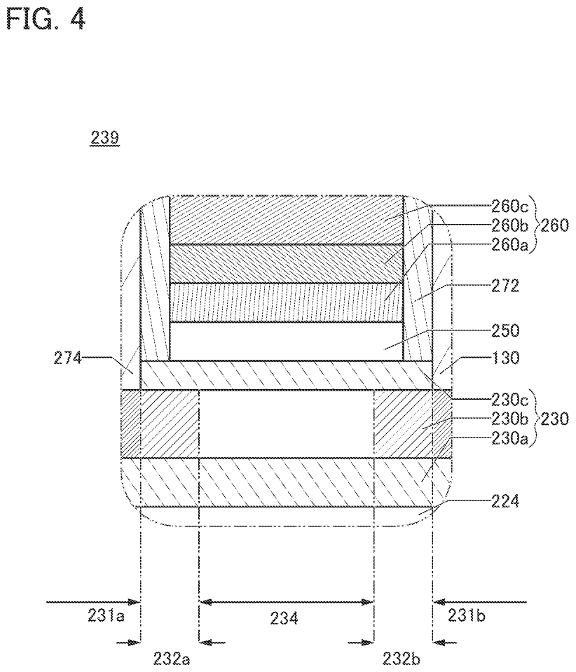

FIG. 4 is an enlarged view illustrating a region 239 including a channel and the vicinity thereof, which is surrounded by a dashed line in FIG. 3B.

As illustrated in FIG. 4, the oxide 230 includes a junction region 232 (a junction region 232a and a junction region 232b) between a region 234 functioning as a channel formation region of the transistor 200 and regions 231 (a region 231a and a region 231b) functioning as a source region and a drain region. The region 231 functioning as the source region or the drain region has a high carrier density and reduced resistance. The region 234 functioning as the channel formation region has a lower carrier density than the region 231 functioning as the source region or the drain region. The junction region 232 has a lower carrier density than the region 231 functioning as the source region or the drain region and has a higher carrier density than the region 234 functioning as the channel formation region. That is, the junction region 232 functions as a junction region between the channel formation region and the source region or the drain region.

The junction region 232 prevents a high-resistance region from being formed between the region 231 functioning as the source region or the drain region and the region 234 functioning as the channel formation region, thereby increasing on-state current of the transistor.

The junction region 232 sometimes functions as an overlap region (also referred to as an Lov region) which overlaps with the conductor 260 that functions as a gate electrode.

Note that the region 231 is preferably in contact with the insulator 274. The concentration of at least one of a metal element such as indium and impurity elements such as hydrogen and nitrogen in the region 231 is preferably higher than that in each of the junction region 232 and the region 234.

The junction region 232 includes a region overlapping with the insulator 272. The concentration of at least one of a metal element such as indium and impurity elements such as hydrogen and nitrogen in the junction region 232 is preferably higher than that in the region 234. On the other hand, the concentration of at least one of a metal element such as indium and impurity elements such as hydrogen and nitrogen in the junction region 232 is preferably lower than that in the region 231.

The region 234 overlaps with the conductor 260. The region 234 is provided between the junction region 232a and the junction region 232b, and the concentration of at least one of a metal element such as indium and impurity elements such as hydrogen and nitrogen in the region 234 is preferably lower than that in each of the regions 231 and 232.

In the oxide 230, a boundary between the region 231, the junction region 232, and the region 234 cannot be observed clearly in some cases. The concentration of at least one of a metal element such as indium and impurity elements such as hydrogen and nitrogen, which is detected in each region, may be gradually changed (such a change is also referred to as gradation) not only between the regions but also in each region. That is, the region closer to the region 234 preferably has a lower concentration of a metal element such as indium and impurity elements such as hydrogen and nitrogen. The concentration of impurity elements in the region 232 is lower than that in the region 231.

Furthermore, in FIG. 4, the region 234, the region 231, and the junction region 232 are formed in the oxide 230b; however, the present invention is not limited thereto. For example, these regions may be formed in the oxide 230a or the oxide 230c. Although the boundaries between the regions are indicated substantially perpendicularly to the top surface of the oxide 230 in FIG. 4, this embodiment is not limited thereto. For example, the junction region 232 may project to the conductor 260 side in the vicinity of the surface of the oxide 230b, and the junction region 232 may recede to the conductor 252a or 252b side in the vicinity of the bottom surface of the oxide 230b.

In the transistor 200, the oxide 230 is preferably formed using a metal oxide functioning as an oxide semiconductor (hereinafter, the metal oxide is also referred to as an oxide semiconductor). A transistor formed using an oxide semiconductor has an extremely low leakage current (off-state current) in an off state; thus, a semiconductor device with low power consumption can be provided. An oxide semiconductor can be formed by a sputtering method or the like and thus can be used in a transistor included in a highly integrated semiconductor device.

However, the transistor formed using an oxide semiconductor is likely to have its electrical characteristics changed by impurities and oxygen vacancies in the oxide semiconductor; as a result, the reliability is reduced, in some cases. Hydrogen contained in an oxide semiconductor reacts with oxygen bonded to a metal atom to be water, and thus causes an oxygen vacancy, in some cases. Entry of hydrogen into the oxygen vacancy generates an electron serving as a carrier in some cases. Accordingly, a transistor including an oxide semiconductor containing oxygen vacancies is likely to have normally-on characteristics. Thus, it is preferable that oxygen vacancies in the oxide semiconductor be reduced as much as possible.

When oxygen vacancies exist at an interface between the region 234 in the oxide 230 where a channel is formed and the insulator 250 functioning as a gate insulating film, a variation in the electrical characteristics is likely to occur and the reliability is reduced in some cases.

In view of the above, the insulator 250 in contact with the region 234 of the oxide 230 preferably contains oxygen at a higher proportion than oxygen in the stoichiometric composition (also referred to as “excess oxygen”). That is, excess oxygen contained in the insulator 250 is diffused into the region 234, whereby oxygen vacancies in the region 234 can be reduced.

The insulator 272 is preferably provided in contact with the insulator 250. For example, the insulator 272 preferably has a function of suppressing diffusion of oxygen (e.g., at least one of oxygen atoms, oxygen molecules, and the like). That is, it is preferable that the above oxygen be less likely to pass through the insulator 272. When the insulator 272 has a function of suppressing diffusion of oxygen, oxygen in an excess-oxygen region is not diffused to the insulator 274 side and thus is supplied to the region 234 efficiently. Thus, the formation of oxygen vacancies at the interface between the oxide 230 and the insulator 250 can be inhibited, leading to an improvement in the reliability of the transistor 200.

Furthermore, the transistor 200 is preferably covered with an insulator which has a barrier property and prevents entry of impurities such as water and hydrogen. The insulator having a barrier property is formed using an insulating material having a function of suppressing diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom, that is, an insulating material having a barrier property through which the above impurities are less likely to pass. Alternatively, the insulator having a barrier property is preferably formed using an insulating material having a function of suppressing diffusion of oxygen (e.g., at least one of oxygen atoms, oxygen molecules, and the like), that is, an insulating material having a barrier property through which the above oxygen is less likely to pass.

The structure of a semiconductor device including the transistor 200 of one embodiment of the present invention is described in detail below.

The conductor 205 functioning as a second gate electrode is provided to overlap with the oxide 230 and the conductor 260.

The conductor 205 is preferably larger than the region 234 in the oxide 230. It is particularly preferable that the conductor 205 extend beyond the end portion of the region 234 in the oxide 230 that intersects with the dashed-dotted line A3-A4 (the channel width direction). That is, it is preferable that the conductor 205 and the conductor 260 overlap with each other with the insulator therebetween to overlap with the side surface of the oxide 230 in the channel width direction.

Here, the conductor 260 functions as a first gate electrode in some cases. The conductor 205 functions as a second gate electrode in some cases. In that case, by changing a potential applied to the conductor 205 independently of a potential applied to the conductor 260, the threshold voltage of the transistor 200 can be controlled. In particular, by applying a negative potential to the conductor 205, the threshold voltage of the transistor 200 can be higher than 0 V, and the off-state current can be reduced. Accordingly, a drain current when a voltage applied to the conductor 260 is 0 V can be reduced.

As illustrated in FIG. 3A, the conductor 205 is provided to overlap with the oxide 230 and the conductor 260. The conductor 205 is preferably provided to overlap with the conductor 260 even in a region on an outer side of the end portions of the oxide 230 that intersect with the dashed-dotted line A3-A4 (the channel width direction (the W length direction)). That is, the conductor 205 and the conductor 260 preferably overlap with each other with the insulator therebetween on an outer side than the side surface of the oxide 230.

With the above structure, in the case where potentials are applied to the conductor 260 and the conductor 205, an electric field generated from the conductor 260 and an electric field generated from the conductor 205 are connected, so that a closed circuit which covers the channel formation region in the oxide 230 can be formed.

That is, the channel formation region in the region 234 can be electrically surrounded by the electric field of the conductor 260 functioning as the first gate electrode and the electric field of the conductor 205 functioning as the second gate electrode. In this specification, such a transistor structure in which the channel formation region is electrically surrounded by the electric fields of the first gate electrode and the second gate electrode is referred to as a surrounded channel (s-channel) structure.

In the conductor 205, a conductor 205a is formed in contact with an inner wall of an opening of the insulators 214 and 216 and a conductor 205b is formed on an inner side than the conductor 205a. Here, top surfaces of the conductors 205a and 205b can be at substantially the same level as the top surface of the insulator 216. Note that although the conductor 205a and the conductor 205b are stacked in the transistor 200, the structure of the present invention is not limited to this structure. For example, a structure in which only the conductor 205b is provided may be employed.

The conductor 205a is preferably formed using a conductive material having a function of suppressing diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom, that is, a conductive material through which the above impurities are less likely to pass. Alternatively, the conductor 205a is preferably formed using a conductive material having a function of suppressing diffusion of oxygen (e.g., at least one of oxygen atoms, oxygen molecules, or the like), that is, a conductive material through which the above oxygen is less likely to pass. Note that in this specification, a function of inhibiting diffusion of impurities or oxygen means a function of inhibiting diffusion of any one or all of the above impurities or the above oxygen.

When the conductor 205a has a function of suppressing diffusion of oxygen, the conductivity of the conductor 205b can be prevented from being lowered because of oxidation. As a conductive material having a function of suppressing diffusion of oxygen, for example, tantalum, tantalum nitride, ruthenium, ruthenium oxide, or the like is preferably used. Accordingly, the conductor 205a may be a single layer or a stacked layer of the above conductive materials. Thus, impurities such as hydrogen and water can be prevented from being diffused to the transistor 200 side of the through the conductor 205 from the substrate side of the insulator 214.

Furthermore, the conductor 205b is preferably formed using a conductive material including tungsten, copper, or aluminum as its main component. Note that the conductor 205b is a single layer in the drawing but may have a stacked-layer structure, for example, a stacked layer of titanium, titanium nitride, and any of the above conductive materials.

The insulator 214 preferably functions as a barrier insulating film for preventing impurities such as water and hydrogen from entering the transistor from the substrate side. Accordingly, the insulator 214 is preferably formed using an insulating material having a function of suppressing diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom, that is, an insulating material through which the above impurities are less likely to pass. Alternatively, the insulator 214 is preferably formed using an insulating material having a function of suppressing diffusion of oxygen (e.g., at least one of oxygen atoms or oxygen molecules), that is, an insulating material through which the above oxygen is less likely to pass.

For example, aluminum oxide, silicon nitride, or the like is preferably used for the insulator 214. Thus, impurities such as hydrogen and water can be prevented from being diffused to the transistor side of the insulator 214. In addition, oxygen contained in the insulator 224 and the like can be prevented from being diffused to the substrate side from the insulator 214.

The permittivity of each of the insulators 216, 280, and 286 functioning as an interlayer film is preferably lower than that of the insulator 214. In the case where a material with a low permittivity is used as an interlayer film, the parasitic capacitance between wirings can be reduced.

For example, the insulators 216, 280, and 286 can be formed to have a single layer or a stacked layer using any of insulators such as silicon oxide, silicon oxynitride, silicon nitride oxide, aluminum oxide, hafnium oxide, tantalum oxide, zirconium oxide, lead zirconate titanate (PZT), strontium titanate (SrTiO₃), and (Ba,Sr)TiO₃ (BST). Aluminum oxide, bismuth oxide, germanium oxide, niobium oxide, silicon oxide, titanium oxide, tungsten oxide, yttrium oxide, or zirconium oxide may be added to the insulator, for example. The insulator may be subjected to nitriding treatment. A layer of silicon oxide, silicon oxynitride, or silicon nitride may be stacked over the insulator.

The insulators 220, 222, and 224 have a function of a gate insulator.

Here, as the insulator 224 in contact with the oxide 230, an oxide insulator that contains more oxygen than that in the stoichiometric composition is preferably used. That is, an excess-oxygen region is preferably formed in the insulator 224. When such an insulator containing excess oxygen is provided in contact with the oxide 230, oxygen vacancies in the oxide 230 can be reduced, leading to an improvement in reliability.

As the insulator including the excess-oxygen region, specifically, an oxide material that releases part of oxygen by heating is preferably used. An oxide that releases part of oxygen by heating is an oxide film in which the amount of released oxygen converted into oxygen molecules is greater than or equal to 1.0×10¹⁸ molecules/cm³, preferably greater than or equal to 3.0×10²⁰ molecules/cm³ in thermal desorption spectroscopy (TDS) analysis. In the TDS analysis, the film surface temperature is preferably higher than or equal to 100° C. and lower than or equal to 700° C., or higher than or equal to 100° C. and lower than or equal to 400° C.

In the case where the insulator 224 includes an excess-oxygen region, the insulator 222 preferably has a function of suppressing diffusion of oxygen (e.g., at least one of oxygen atoms or oxygen molecules). That is, it is preferable that the above oxygen be less likely to pass through the insulator 222.

When the insulator 222 has a function of suppressing diffusion of oxygen, oxygen in the excess-oxygen region is not diffused to the insulator 220 side and thus can be supplied to the oxide 230 efficiently. The conductor 205 can be inhibited from reacting with oxygen in the excess-oxygen region of the insulator 224.

The insulator 222 preferably has a single-layer structure or a stacked-layer structure using an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST). When a high-k material is used for the insulator functioning as a gate insulator, miniaturization and high integration of the transistor becomes possible. It is particularly preferable to use an insulating material (through which oxygen is unlikely to pass) having a function of suppressing diffusion of impurities such as aluminum oxide and hafnium oxide, oxygen, and the like. The insulator 222 formed of such a material serves as a layer that prevents release of oxygen from the oxide 230 and entry of impurities such as hydrogen from the periphery of the transistor 200.

Alternatively, aluminum oxide, bismuth oxide, germanium oxide, niobium oxide, silicon oxide, titanium oxide, tungsten oxide, yttrium oxide, or zirconium oxide may be added to these insulators, for example. These insulators may be subjected to nitriding treatment. A layer of silicon oxide, silicon oxynitride, or silicon nitride may be stacked over the insulator.

It is preferable that the insulator 220 be thermally stable. Because silicon oxide and silicon oxynitride have thermal stability, combination of silicon oxide or silicon oxynitride with an insulator which is a high-k material allows the stacked-layer structure to be thermally stable and have a high relative permittivity, for example.

Note that the insulators 220, 222, and 224 each may have a stacked-layer structure of two or more layers. In this case, the stacked layers are not necessarily formed of the same material but may be formed of different materials. The insulators 220, 222, and 224 functioning as a gate insulator in the transistor 200 are described; however this embodiment is not limited to this. For example, a structure of two layers or one layer of any of the insulators 220, 222, and 224 may be formed as a gate insulator.

The oxide 230 includes the oxide 230a, the oxide 230b over the oxide 230a, and the oxide 230c over the oxide 230b. The oxide 230 includes the region 231, the junction region 232, and the region 234. Note that at least part of the region 231 is preferably in contact with the insulator 274. Note that it is preferable that the concentration of at least one of a metal element such as indium, hydrogen, and nitrogen in at least part of the region 231 be higher than that of the region 234.

When the transistor 200 is turned on, the region 231a or 231b functions as the source region or the drain region. At least part of the region 234 functions as a channel formation region.

As illustrated in FIG. 4, the oxide 230 preferably includes the junction region 232. With this structure, the transistor 200 can have a high on-state current and a low leakage current (off-state current) in an off state.

When the oxide 230b is provided over the oxide 230a, impurities can be prevented from being diffused into the oxide 230b from the components formed below the oxide 230a. Moreover, when the oxide 230b is provided under the oxide 230c as illustrated in FIGS. 3A to 3C, impurities can be prevented from being diffused into the oxide 230b from the components formed above the oxide 230c.

The oxide 230 has a curved surface between the side surface and the top surface. That is, an end portion of the side surface and an end portion of the top surface are preferably curved (hereinafter such a curved shape is also referred to as a rounded shape). The radius of curvature of the curved surface at an end portion of the oxide 230b is greater than or equal to 3 nm and less than or equal to 10 nm, preferably greater than or equal to 5 nm and less than or equal to 6 nm.

The oxide 230 is preferably formed using a metal oxide functioning as an oxide semiconductor (hereinafter, the metal oxide is also referred to as an oxide semiconductor). For example, the metal oxide to be the region 234 preferably has an energy gap of 2 eV or more, preferably 2.5 eV or more. With the use of a metal oxide having such a wide energy gap, the off-state current of the transistor can be reduced.

Note that in this specification and the like, a metal oxide including nitrogen is also called a metal oxide in some cases. Moreover, a metal oxide including nitrogen may be called a metal oxynitride.

A transistor formed using an oxide semiconductor has an extremely low leakage current in an off state; thus, a semiconductor device with low power consumption can be provided. An oxide semiconductor can be formed by a sputtering method or the like and thus can be used in a transistor included in a highly integrated semiconductor device.

For example, as the oxide 230, a metal oxide such as an In-M-Zn oxide (M is one or a plurality of aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like) is used. In—Ga oxide or In—Zn oxide may be used as the oxide 230.

Here, the region 234 in the oxide 230 is described.

The region 234 preferably has a stacked-layer structure of metal oxides which differ in the atomic ratio of metal elements. Specifically, in the case where the region 234 has the stacked-layer structure of the oxide 230a and 230b, the atomic ratio of the element M to constituent elements in the metal oxide used as the oxide 230a is preferably greater than that in the metal oxide used as the oxide 230b. Moreover, the atomic ratio of the element M to In in the metal oxide used as the oxide 230a is preferably greater than that in the metal oxide used as the oxide 230b. Moreover, the atomic ratio of the element In to M in the metal oxide used as the oxide 230b is preferably greater than that in the metal oxide used as the oxide 230a. The oxide 230c can be formed using a metal oxide which can be used for the oxide 230a or 230b.

Next, the region 231 and the junction region 232 which are included in the oxide 230 are described.

The region 231 and the junction region 232 are low-resistance regions which are obtained by adding a metal atom such as indium or impurities to a metal oxide formed as the oxide 230. Note that each of the regions has higher conductivity than at least the oxide 230b in the region 234. For addition of impurities to the region 231 and junction region 232, for example, a dopant which is at least one of a metal element such as indium and impurities can be added by plasma treatment, an ion implantation method by which an ionized source gas is subjected to mass separation and then added, an ion doping method by which an ionized source gas is added without mass separation, a plasma immersion ion implantation method, or the like.

That is, when the content of a metal atom such as indium in the region 231 and the junction region 232 in the oxide 230 is increased, the electron mobility can be increased and the resistance can be decreased.

When the insulator 274 containing impurity elements is formed in contact with the oxide 230, impurities can be added to the region 231 and the junction region 232.

That is, when an element that forms an oxygen vacancy or an element trapped by an oxygen vacancy is added to the region 231 and the junction region 232, the resistances of the region 231 and the junction region 232 are reduced. Typical examples of the element are hydrogen, boron, carbon, nitrogen, fluorine, phosphorus, sulfur, chlorine, titanium, and a rare gas. Typical examples of the rare gas element are helium, neon, argon, krypton, and xenon. Accordingly, the region 231 and the junction region 232 are made to include one or more of the above elements.

When the junction region 232 is provided in the transistor 200, high-resistance regions are not formed between the region 231 functioning as the source region and the drain region and the region 234 where a channel is formed, so that the on-state current and the carrier mobility of the transistor can be increased. Since the gate does not overlap with the source and drain regions in the channel length direction by including the junction region 232, formation of unnecessary capacitance can be suppressed. Furthermore, leakage current in an off state can be reduced owing to the junction region 232.

Thus, by appropriately selecting the areas of the junction region 232, a transistor having electrical characteristics necessary for the circuit design can be easily provided.

The insulator 250 functions as a gate insulating film. The insulator 250 is preferably provided in contact with the top surface of the oxide 230c. The insulator 250 is preferably formed using an insulator from which oxygen is released by heating. The insulator 250 is an oxide film of which the amount of released oxygen converted into oxygen molecules is greater than or equal to 1.0×10¹⁸ molecules/cm³, preferably greater than or equal to 3.0×10²⁰ molecules/cm³ in thermal desorption spectroscopy (TDS) analysis, for example. Note that the temperature of the film surface in the TDS analysis is preferably higher than or equal to 100° C. and lower than or equal to 700° C., or higher than or equal to 100° C. and lower than or equal to 500° C.

When as the insulator 250, an insulator from which oxygen is released by heating is provided in contact with the top surface of the oxide 230c, oxygen can be efficiently supplied to the region 234 of the oxide 230b. Furthermore, like the insulator 224, the concentration of impurities such as water and hydrogen in the insulator 250 is preferably lowered. The thickness of the insulator 250 is preferably greater than or equal to 1 nm and less than or equal to 20 nm.

The conductor 260 functioning as the first gate electrode includes the conductor 260a, the conductor 260b over the conductor 260a, and the conductor 260c over the conductor 260b. The conductor 260a is preferably formed using a conductive oxide. For example, the metal oxide that can be used for the oxide 230a or 230b can be used. In particular, an In—Ga—Zn-based oxide with an atomic ratio of In:Ga:Zn=4:2:3 to 4.1 or in the neighborhood thereof, which has high conductivity, is preferably used. When the conductor 260a is formed using such a material, oxygen can be prevented from entering the conductor 260b, and an increase in electric resistance value of the conductor 260b due to oxidation can be prevented.

When such a conductive oxide is formed by a sputtering method, oxygen can be added to the insulator 250, so that oxygen can be supplied to the oxide 230b. Thus, oxygen vacancies in the region 234 of the oxide 230 can be reduced.

As the conductor 260b, a conductor that can add impurities such as nitrogen to the conductor 260a to improve the conductivity of the conductor 260a may be used. For example, titanium nitride or the like is preferably used for the conductor 260b. The conductor 260c can be formed using a metal with high conductivity such as tungsten, for example.

In the case where the conductor 205 extends beyond the end portions of the oxide 230 that intersect with the dashed-dotted line A3-A4 (the channel width direction) as illustrated in FIG. 3C, the conductor 260 preferably overlaps with the conductor 205 with the insulator 250 provided therebetween. That is, a stacked-layer structure of the conductor 205, the insulator 250, and the conductor 260 is preferably formed outside the side surface of the oxide 230.

With the above structure, in the case where potentials are applied to the conductor 260 and the conductor 205, an electric field generated from the conductor 260 and an electric field generated from the conductor 205 are connected, so that a closed circuit which covers the channel formation region in the oxide 230 can be formed.

That is, the channel formation region in the region 234 can be electrically surrounded by the electric field of the conductor 260 functioning as the first gate electrode and the electric field of the conductor 205 functioning as the second gate electrode.

Furthermore, the insulator 270 functioning as a barrier film can be provided over the conductor 260c. Here, the insulator 270 is preferably formed using an insulating material that has a function of inhibiting the penetration of oxygen and impurities such as water and hydrogen. For example, aluminum oxide or hafnium oxide is preferably used. Thus, oxidation of the conductor 260 can be prevented. This can prevent entry of impurities such as water or hydrogen into the oxide 230 through the conductor 260 and the insulator 250.

Furthermore, the insulator 271 functioning as a hard mask is preferably provided over the insulator 270. By provision of the insulator 270, the conductor 260 can be processed to have a side surface that is substantially perpendicular. Specifically, an angle formed by the side surface of the conductor 260 and a surface of the substrate can be greater than or equal to 75° and less than or equal to 100°, preferably greater than or equal to 80° and less than or equal to 95°. When the conductor is processed into such a shape, the insulator 272 that is subsequently formed can be formed into a desired shape.

The insulator 272 functioning as a barrier film is provided in contact with the side surface of the insulator 250, the side surface of the conductor 260, and the side surface of the insulator 270.

Here, the insulator 272 is preferably formed using an insulating material that has a function of inhibiting the penetration of oxygen and impurities such as water and hydrogen. For example, aluminum oxide or hafnium oxide is preferably used. In this manner, oxygen in the insulator 250 can be prevented from diffusing outward. In addition, impurities such as hydrogen and water can be prevented from entering the oxide 230 through the end portion of the insulator 250 or the like.

By provision of the insulator 272, the top surface and the side surface of the conductor 260 and the side surface of the insulator 250 can be covered with an insulator having a function of inhibiting the penetration of oxygen and impurities such as water and hydrogen. This can prevent entry of impurities such as water and hydrogen into the oxide 230 through the conductor 260 and the insulator 250. Thus, the insulator 272 functions as a side barrier for protecting the side surfaces of the gate electrode and the gate insulating film.

In the case where the transistor is miniaturized and has a channel length of approximately greater than or equal to 10 nm and less than or equal to 30 nm, impurity elements contained in the structure bodies provided in the vicinity of the transistor 200 might be diffused, and the region 231a might be electrically connected to the region 231b or the junction region 232b.

In view of the above, when the insulator 272 is formed as described in this embodiment, impurities such as hydrogen and water can be prevented from entering the insulator 250 and the conductor 260, and oxygen in the insulator 250 can be prevented from being diffused to the outside. Accordingly, when a first gate voltage is 0 V, the source region and the drain region can be prevented from being electrically connected to each other directly or through the junction region 232.

The insulator 274 includes at least a region in contact with the insulator 272, the oxide 230, and the insulator 224. In particular, the insulator 274 preferably includes a region in contact with the region 231 of the oxide 230.

Moreover, the insulator 274 is preferably formed using an insulating material having a function of inhibiting the penetration of impurities such as water and hydrogen and oxygen. For example, as the insulator 274, silicon nitride, silicon nitride oxide, silicon oxynitride, aluminum nitride, aluminum nitride oxide, or the like is preferably used. When the insulator 274 is formed using any of the above materials, entry of oxygen through the insulator 274 to be supplied to oxygen vacancies in the regions 231a and 231b, which decreases the carrier density, can be prevented. Furthermore, impurities such as water and hydrogen can be prevented from passing through the insulator 274 and excessively enlarging the region 231a and the region 231b to the region 234 side.

Note that in the case where the region 231 and the junction region 232 are provided with formation of the insulator 274, the insulator 274 preferably includes at least one of hydrogen and nitrogen. When an insulator including impurities such as hydrogen and nitrogen is used as the insulator 274, impurities such as hydrogen and nitrogen are added to the oxide 230, so that the region 231, the junction region 232 can be formed in the oxide 230.

The insulator 280 functioning as interlayer film is preferably provided over the insulator 274. Like the insulator 224 or the like, the concentration of impurities such as water and hydrogen in the insulator 280 is preferably lowered. Note that an insulator 286 similar to the insulator 224 may be provided over the insulator 280.

Furthermore, the conductors 252a, 252b, 252c, and 252d are provided in the opening formed in the insulators 286, 280, 274, 271, and 270. Note that top surfaces of the conductors 252a, 252b, 252c, and 252d may be at the same level as the top surface of the insulator 286.

The conductor 252c is in contact with the conductor 260 functioning as the first gate electrode of the transistor 200 through the opening formed in the insulators 270 and 271. The conductor 252d is in contact with a conductor 120 serving as one of electrodes of the capacitor 100 described later.

Here, the conductor 252a is in contact with the region 231a functioning as one of a source region and a drain region of the transistor 200, and the conductor 252b is in contact with the region 231b functioning as the other of the source region and the drain region of the transistor 200. Because the region 231a and the region 231b are reduced in resistance, the contact resistance between the conductor 252a and the region 231a and the contact resistance between the conductor 252b and the region 231b are reduced, leading to a large on-state current of the transistor 200.

The conductor 252a (the conductor 252b) is in contact with at least the top surface of the oxide 230. It is preferable that the conductor 252a (the conductor 252b) be in contact with the side surface of the oxide 230. It is particularly preferable that the conductor 252a (the conductor 252b) be in contact with one of or both the side surface of the oxide 230 on the A3 side and the side surface of the oxide 230 on the A4 side, which intersect with the channel width direction of the oxide 230. The conductor 252a (the conductor 252b) may be in contact with the side surface of the oxide 230 on the A1 side (the A2 side) in the direction intersecting with the channel length direction. When the conductor 252a (the conductor 252b) is in contact with not only the top surface of the oxide 230 but also the side surface of the oxide 230, the area where the conductor 252a (the conductor 252b) and the oxide 230 are in contact with each other can be increased without an increase in the area of the top surface of the contact portion, so that the contact resistance between the conductor 252a (the conductor 252b) and the oxide 230 can be reduced. Accordingly, miniaturization of the source electrode and the drain electrode of the transistor can be achieved and, in addition, the on-state current can be increased.

The conductor 252a, the conductor 252b, and the conductor 252c are preferably formed using a conductive material including tungsten, copper, or aluminum as its main component. Although not shown, the conductor 252a, the conductor 252b, and the conductor 252c may have a stacked-layer structure, and for example, a stacked layer of titanium, titanium nitride, and any of the above conductive materials may be used.

In the case where the conductor 252 has a stacked-layer structure, a conductive material having a function of inhibiting the penetration of impurities such as water and hydrogen is preferably used for a conductor in contact with the insulators 274, 280, and 286, as in the conductor 205a or the like. For example, tantalum, tantalum nitride, titanium, titanium nitride, ruthenium, ruthenium oxide, or the like is preferably used. The conductive material having a function of inhibiting the penetration of impurities such as water and hydrogen may be used for forming a single layer or a stacked layer. When the conductive material is used, impurities such as hydrogen and water can be prevented from entering the oxide 230 through the conductor 252 from a layer above the insulators 280 and 286.

An insulator which has a function of inhibiting the passage of impurities such as water and hydrogen may be provided in contact with the inner wall of the opening in the insulators 274 and 280 in which the conductor 252 is embedded. As for such an insulator, an insulator which can be used for the insulator 214, such as aluminum oxide is preferably used. Accordingly, the insulator prevents impurities such as hydrogen and water from entering the oxide 230 through the conductor 252 from the insulator 280. The insulator can be formed with good coverage by using an ALD method, a CVD method, or the like.

Although not illustrated, conductors functioning as wirings may be provided in contact with the top surface of the conductor 252. A conductive material containing tungsten, copper, or aluminum as its main component is preferably used for the conductors functioning as the wirings.

### [Capacitor 100]

The capacitor 100 has common components as the transistor 200 as illustrated in FIGS. 1A to 1C and FIGS. 3A to 3C. In this embodiment, the region 231b provided in the oxide 230 of the transistor 200 is illustrated as an example of the capacitor 100 serving as one electrode of the capacitor 100.

The capacitor 100 includes the region 231b of the oxide 230, an insulator 130 over the region 231b, and the conductor 120 over the insulator 130. Moreover, the conductor 120 is preferably provided over the insulator 130 to at least partly overlap with the region 231b of the oxide 230.

The region 231b of the oxide 230 functions as one electrode of the capacitor 100, and the conductor 120 functions as the other electrode of the capacitor 100. The insulator 130 functions as a dielectric of the capacitor 100. The resistance of the region 231b of the oxide 230 is reduced, and is a conductive oxide. Thus, the region 231b of the oxide 230 can function as one electrode of the capacitor 100.

The insulators 280 and 274 have an opening in the region overlapping with the region 231b of the oxide 230. In a bottom portion of the opening, the region 231b of the oxide 230 is exposed. The insulator 130 is provided in contact with the side surface of the opening and the region 231b of the oxide 230. The conductor 120 is preferably provided so as to be embedded in the opening with the insulator 130 provided therebetween.

The insulator 130 may be, for example, a single layer or a stacked layer using aluminum oxide or silicon oxynitride.

Like the conductor 120, the conductor 120 is preferably formed with a conductive material containing tungsten, copper, or aluminum as its main component. Although not illustrated, the conductor 120 may have a stacked-layer structure, and for example, may be a stacked layer of titanium, titanium nitride, and the above-described conductive material.

Furthermore, the conductor 252d is in contact with the conductor 120 functioning as one electrode of the capacitor 100. The conductor 252d can be formed at the same time as the conductors 252a, 252b, and 252c; thus, the manufacturing process can be shortened.

### <Material for Semiconductor Device>

Materials that can be used for a semiconductor device will be described below.

### <<Substrate>>

As a substrate over which the transistor 200 is formed, for example, an insulator substrate, a semiconductor substrate, or a conductor substrate may be used. As the insulator substrate, a glass substrate, a quartz substrate, a sapphire substrate, a stabilized zirconia substrate (e.g., an yttria-stabilized zirconia substrate), or a resin substrate is used, for example. As the semiconductor substrate, a semiconductor substrate of silicon, germanium, or the like, or a compound semiconductor substrate of silicon carbide, silicon germanium, gallium arsenide, indium phosphide, zinc oxide, or gallium oxide can be used, for example. A semiconductor substrate in which an insulator region is provided in the above semiconductor substrate, e.g., a silicon on insulator (SOI) substrate or the like is used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate. As a method for providing a transistor over a flexible substrate, there is a method in which the transistor is formed over a non-flexible substrate and then the transistor is separated and transferred to the substrate which is a flexible substrate. In that case, a separation layer is preferably provided between the non-flexible substrate and the transistor. The substrate may have elasticity. The substrate may have a property of returning to its original shape when bending or pulling is stopped. Alternatively, the substrate may have a property of not returning to its original shape. The substrate has a region with a thickness of, for example, greater than or equal to 5 μm and less than or equal to 700 μm, preferably greater than or equal to 10 μm and less than or equal to 500 μm, further preferably greater than or equal to 15 μm and less than or equal to 300 μm. When the substrate has a small thickness, the weight of the semiconductor device including the transistor can be reduced. When the substrate has a small thickness, even in the case of using glass or the like, the substrate may have elasticity or a property of returning to its original shape when bending or pulling is stopped. Therefore, an impact applied to the semiconductor device over the substrate due to dropping or the like can be reduced. That is, a durable semiconductor device can be provided.

For the substrate which is a flexible substrate, metal, an alloy, resin, glass, or fiber thereof can be used, for example. As the substrate, a sheet, a film, or a foil containing a fiber may be used. The flexible substrate preferably has a lower coefficient of linear expansion because deformation due to an environment is suppressed. The flexible substrate is formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, and acrylic. In particular, aramid is preferably used for the flexible substrate because of its low coefficient of linear expansion.

### <Insulator>

Examples of an insulator include an insulating oxide, an insulating nitride, an insulating oxynitride, an insulating nitride oxide, an insulating metal oxide, an insulating metal oxynitride, and an insulating metal nitride oxide.

When a high-k material having a high relative permittivity is used for the insulator functioning as the gate insulator, miniaturization and high integration of the transistor can be achieved. In contrast, when a material having a low relative permittivity is used for the insulator functioning as an interlayer film, the parasitic capacitance between the wirings can be reduced. In this manner, a material is preferably selected depending on the function of an insulator.

As the insulator having a high relative permittivity, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, or the like can be given.

As the insulator having a low relative permittivity, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like can be given.

In particular, silicon oxide and silicon oxynitride are thermally stable. Accordingly, a stacked-layer structure which is thermally stable and has a low relative permittivity can be obtained by combination with a resin, for example. Examples of the resin include polyester, polyolefin, polyamide (e.g., nylon or aramid), polyimide, polycarbonate, and acrylic. Furthermore, combination of silicon oxide or silicon oxynitride with an insulator with a high relative permittivity allows the stacked-layer structure to be thermally stable and have a high relative permittivity, for example.

Note that when the transistor including an oxide semiconductor is surrounded by an insulator that has a function of inhibiting the penetration of oxygen and impurities such as hydrogen, the electrical characteristics of the transistor can be stabilized.

The insulator that has a function of inhibiting the penetration of oxygen and impurities such as hydrogen can have, for example, a single-layer structure or a stacked-layer structure of an insulator including boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting the penetration of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide, silicon nitride oxide, silicon nitride, or the like can be used.

For example, an insulator that has a function of inhibiting the penetration of oxygen and impurities such as hydrogen may be used as each of the insulators 222 and 214. Note that the insulators 222 and 214 preferably contain aluminum oxide, hafnium oxide, or the like.

For example, the insulators 216, 220, 224, 250, and 271 may be formed using a single layer or a stacked layer of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, the insulators 216, 220, 224, 250, and 271 preferably contain silicon oxide, silicon oxynitride, or silicon nitride.

For example, when aluminum oxide, gallium oxide, or hafnium oxide in each of the insulators 224 and 250 functioning as a gate insulator is in contact with the oxide 230, entry of silicon included in silicon oxide or silicon oxynitride into the oxide 230 can be suppressed. When silicon oxide or silicon oxynitride in each of the insulators 224 and 250 is in contact with the oxide 230, for example, trap centers might be formed at the interface between aluminum oxide, gallium oxide, or hafnium oxide and silicon oxide or silicon oxynitride. The trap centers can shift the threshold voltage of the transistor in the positive direction by trapping electrons in some cases.

The insulator 130 functioning as a dielectric has a single-layer structure or a stacked-layer structure formed using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, or hafnium nitride. For example, a stacked-layer structure of a high-k material such as aluminum oxide and a material with high dielectric strength such as silicon oxynitride is preferably used. The structure enables the capacitor 100 to include a high-k material and a material with high dielectric strength; thus, the required capacitance can be provided, the dielectric strength can be increased, and the electrostatic breakdown of the capacitor 100 can be prevented, which leads to improvement in the reliability of the capacitor 100.

The insulator 216, the insulator 280, and the insulator 286 preferably include an insulator with a low relative permittivity. For example, the insulator 216 and the insulator 280 preferably include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, each of the insulator 216 and the insulator 280 preferably has a stacked-layer structure of a resin and one of the following materials: silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide. When silicon oxide or silicon oxynitride, which is thermally stable, is combined with resin, the stacked-layer structure can have thermal stability and low relative permittivity. Examples of the resin include polyester, polyolefin, polyamide (e.g., nylon or aramid), polyimide, polycarbonate, and acrylic.

As the insulators 270 and 272, an insulator having a function of inhibiting the penetration of impurities such as hydrogen and oxygen may be used. For the insulator 270 and the insulator 272, a metal oxide such as aluminum oxide, hafnium oxide, magnesium oxide, gallium oxide, germanium oxide, yttrium oxide, zirconium oxide, lanthanum oxide, neodymium oxide, or tantalum oxide; silicon nitride oxide; silicon nitride; or the like may be used, for example.

### <<Conductor>>

The conductors can be formed using a material containing one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like. Alternatively, a semiconductor having a high electric conductivity typified by polycrystalline silicon including an impurity element such as phosphorus, or silicide such as nickel silicide may be used.

A stack of a plurality of conductive layers formed with the above materials may be used. For example, a stacked-layer structure formed using a combination of a material including any of the metal elements listed above and a conductive material including oxygen may be used. Alternatively, a stacked-layer structure formed using a combination of a material including any of the metal elements listed above and a conductive material including nitrogen may be used. Alternatively, a stacked-layer structure formed using a combination of a material including any of the metal elements listed above, a conductive material including oxygen, and a conductive material including nitrogen may be used.

When oxide is used for the channel formation region of the transistor, a stacked-layer structure formed using a material containing the above-described metal element and a conductive material containing oxygen is preferably used for the conductor functioning as the gate electrode. In this case, the conductive material containing oxygen is preferably formed on the channel formation region side. In that case, the conductive material including oxygen is preferably provided on the channel formation region side so that oxygen released from the conductive material is easily supplied to the channel formation region.

It is particularly preferable to use a conductive material containing oxygen and a metal element contained in the metal oxide forming a channel for the conductor functioning as the gate electrode. A conductive material containing the above metal element and nitrogen may be used. For example, a conductive material containing nitrogen such as titanium nitride or tantalum nitride may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. By using such a material, hydrogen contained in the metal oxide forming a channel can be captured in some cases. Alternatively, hydrogen entering from an external insulator or the like can be captured in some cases.

The conductors 260, 205, 120, and 252 can be formed using a material containing one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like. Alternatively, a semiconductor having a high electric conductivity typified by polycrystalline silicon including an impurity element such as phosphorus, or silicide such as nickel silicide may be used.

### <<Metal Oxide>>

The oxide 230 is preferably formed using a metal oxide functioning as an oxide semiconductor (hereinafter, the metal oxide is also referred to as an oxide semiconductor). A metal oxide that can be used as the oxide 230 of one embodiment of the present invention is described below.

An oxide semiconductor preferably contains at least indium or zinc. In particular, indium and zinc are preferably contained. In addition, aluminum, gallium, yttrium, tin, or the like is preferably contained. Furthermore, one or more elements selected from boron, silicon, titanium, iron, nickel, germanium, zirconium, molybdenum, lanthanum, cerium, neodymium, hafnium, tantalum, tungsten, magnesium, or the like may be contained.

Here, the case where the oxide semiconductor is an In-M-Zn oxide that contains indium, an element M, and zinc is considered. The element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, and magnesium. Note that two or more of the above elements may be used in combination as the element M.

Note that in this specification and the like, a metal oxide including nitrogen is also called a metal oxide in some cases. Moreover, a metal oxide including nitrogen may be called a metal oxynitride.

### [Composition of Metal Oxide]

Described below is the composition of a cloud-aligned composite oxide semiconductor (CAC-OS) applicable to a transistor disclosed in one embodiment of the present invention.

In this specification and the like, “c-axis aligned crystal (CAAC)” or “cloud-aligned composite (CAC)” might be stated. Note that CAAC refers to an example of a crystal structure, and CAC refers to an example of a function or a material composition.

A CAC-OS or a CAC metal oxide has a conducting function in a part of the material and has an insulating function in another part of the material; as a whole, the CAC-OS or the CAC metal oxide has a function of a semiconductor. In the case where the CAC-OS or the CAC metal oxide is used in an active layer of a transistor, the conducting function is to allow electrons (or holes) serving as carriers to flow, and the insulating function is to not allow electrons serving as carriers to flow. By the complementary action of the conducting function and the insulating function, the CAC-OS or the CAC metal oxide can have a switching function (on/off function). In the CAC-OS or the CAC metal oxide, separation of the functions can maximize each function.

The CAC-OS or the CAC metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. The conductive regions are observed to be coupled in a cloud-like manner with their boundaries blurred, in some cases.

Furthermore, in the CAC-OS or the CAC metal oxide, the conductive regions and the insulating regions each have a size of greater than or equal to 0.5 nm and less than or equal to 10 nm, preferably greater than or equal to 0.5 nm and less than or equal to 3 nm and are dispersed in the material, in some cases.

The CAC-OS or the CAC metal oxide includes components having different bandgaps. For example, the CAC-OS or the CAC metal oxide contains a component having a wide gap due to the insulating region and a component having a narrow gap due to the conductive region. In the case of such a composition, carriers mainly flow in the component having a narrow gap. The component having a narrow gap complements the component having a wide gap, and carriers also flow in the component having a wide gap in conjunction with the component having a narrow gap. Therefore, in the case where the above-described CAC-OS or the CAC metal oxide is used in a channel formation region of a transistor, high current drive capability in the on state of the transistor, that is, high on-state current and high field-effect mobility, can be obtained.

In other words, the CAC-OS or the CAC metal oxide can be called a matrix composite or a metal matrix composite.

### [Structure of Metal Oxide]

An oxide semiconductor is classified into a single crystal oxide semiconductor and a non-single-crystal oxide semiconductor. Examples of a non-single-crystal oxide semiconductor include a c-axis-aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

The CAAC-OS has c-axis alignment, its nanocrystals are connected in the a-b plane direction, and its crystal structure has distortion. Note that distortion refers to a portion where the direction of a lattice arrangement changes between a region with a uniform lattice arrangement and another region with a uniform lattice arrangement in a region where the nanocrystals are connected.

The shape of the nanocrystal is basically a hexagon but is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of distortion in the CAAC-OS. That is, a lattice arrangement is distorted and thus formation of a grain boundary is inhibited. This is probably because the CAAC-OS can tolerate distortion owing to a low density of oxygen atom arrangement in the a-b plane direction, a change in interatomic bond distance by substitution of a metal element, and the like.

The CAAC-OS tends to have a layered crystal structure (also referred to as a stacked-layer structure) in which a layer containing indium and oxygen (hereinafter, In layer) and a layer containing the element M, zinc, and oxygen (hereinafter, (M, Zn) layer) are stacked. Note that indium and the element M can be replaced with each other, and when the element M of the (M, Zn) layer is replaced by indium, the layer can also be referred to as an (In, M, Zn) layer. When indium of the In layer is replaced by the element M, the layer can also be referred to as an (In, M) layer.

The CAAC-OS is an oxide semiconductor with high crystallinity. By contrast, in the CAAC-OS, a reduction in electron mobility due to the grain boundary is less likely to occur because a clear grain boundary cannot be observed. Entry of impurities, formation of defects, or the like might decrease the crystallinity of an oxide semiconductor. This means that the CAAC-OS has small amounts of impurities and defects (e.g., oxygen vacancies). Thus, an oxide semiconductor including a CAAC-OS is physically stable. Therefore, the oxide semiconductor including a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different nanocrystals in the nc-OS. Thus, the orientation of the whole film is not observed. Accordingly, in some cases, the nc-OS cannot be distinguished from an a-like OS or an amorphous oxide semiconductor, depending on an analysis method.

The a-like OS has a structure between those of the nc-OS and the amorphous oxide semiconductor. The a-like OS has a void or a low-density region. That is, the a-like OS has low crystallinity as compared with the nc-OS and the CAAC-OS.

An oxide semiconductor can have any of various structures which show various different properties. Two or more of the amorphous oxide semiconductor, the polycrystalline oxide semiconductor, the a-like OS, the nc-OS, and the CAAC-OS may be included in an oxide semiconductor of one embodiment of the present invention.

### [Transistor Containing Oxide Semiconductor]

Next, the case where the oxide semiconductor is used for a transistor will be described.

When the oxide semiconductor is used in a transistor, the transistor can have high field-effect mobility. In addition, the transistor can have high reliability.

Moreover, an oxide semiconductor with low carrier density is preferably used for the transistor. In order to reduce the carrier density of the oxide semiconductor film, the concentration of impurities in the oxide semiconductor film is reduced so that the density of defect states can be reduced. In this specification and the like, a state with a low impurity concentration and a low density of defect states is referred to as a highly purified intrinsic or substantially highly purified intrinsic state. The oxide semiconductor has, for example, a carrier density lower than 8×10¹¹/cm³, preferably lower than 1×10¹¹/cm³, and further preferably lower than 1×10¹⁰/cm³, and higher than or equal to 1×10⁹/cm³.

A highly purified intrinsic or substantially highly purified intrinsic oxide semiconductor film has a low density of defect states and accordingly has a low density of trap states in some cases.

Charges trapped by the trap states in the oxide semiconductor takes a long time to be released and may behave like fixed charges. Thus, a transistor whose channel formation region is formed in the oxide semiconductor having a high density of trap states has unstable electrical characteristics in some cases.

In order to obtain stable electrical characteristics of the transistor, it is effective to reduce the concentration of impurities in the oxide semiconductor. In addition, in order to reduce the concentration of impurities in the oxide semiconductor, the concentration of impurities in a film that is adjacent to the oxide semiconductor is preferably reduced. As examples of the impurities, hydrogen, nitrogen, alkali metal, alkaline earth metal, iron, nickel, silicon, and the like are given.

### [Impurity]

Here, the influence of impurities in the oxide semiconductor is described.

When silicon or carbon that is one of Group 14 elements is contained in the oxide semiconductor, defect states are formed. Thus, the concentration of silicon or carbon (the concentration is measured by SIMS) in the oxide semiconductor and the concentration of silicon or carbon in the vicinity of an interface with the oxide semiconductor (the concentration is measured by SIMS) is set to be lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated, in some cases. Thus, a transistor including an oxide semiconductor that contains an alkali metal or an alkaline earth metal is likely to be normally-on. Therefore, it is preferable to reduce the concentration of an alkali metal or an alkaline earth metal in the oxide semiconductor. Specifically, the concentration of alkali metal or alkaline earth metal in the oxide semiconductor, which is measured by SIMS, is lower than or equal to 1×10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase of carrier density. Thus, a transistor whose semiconductor includes an oxide semiconductor that contains nitrogen is likely to be normally-on. For this reason, nitrogen in the oxide semiconductor is preferably reduced as much as possible; for example, the concentration of nitrogen in the oxide semiconductor measured by SIMS is set to lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Hydrogen contained in an oxide semiconductor reacts with oxygen bonded to a metal atom to be water, and thus causes an oxygen vacancy, in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor including an oxide semiconductor that contains hydrogen is likely to be normally-on. For this reason, hydrogen in the oxide semiconductor is preferably reduced as much as possible. Specifically, the hydrogen concentration of the oxide semiconductor measured by SIMS is lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide semiconductor with sufficiently reduced impurity concentration is used for a channel formation region in a transistor, the transistor can have stable electrical characteristics.

### Structure Example 2 of Semiconductor Device

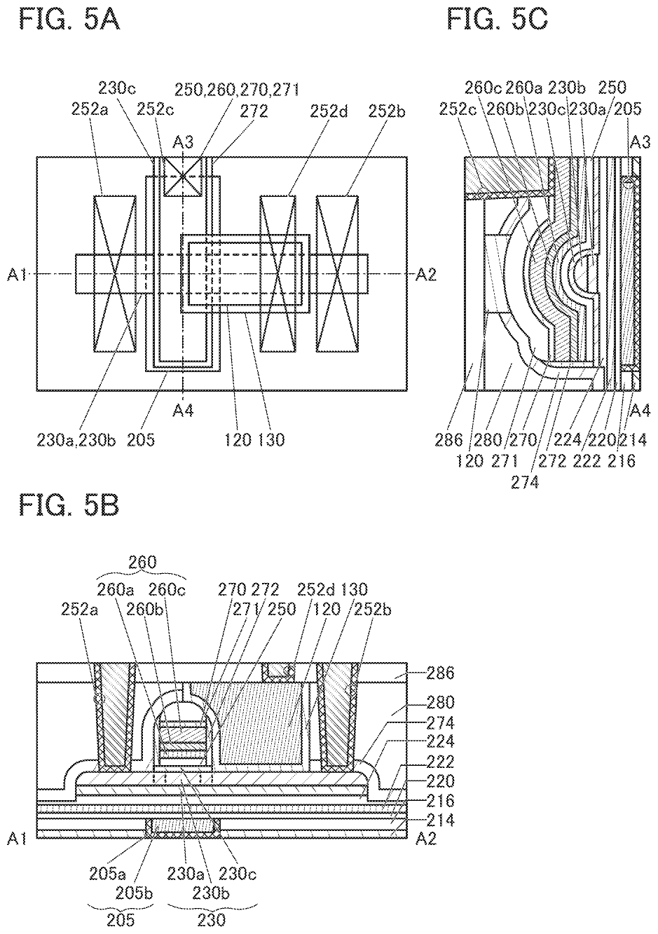

An example of a semiconductor device including the cell 600 of one embodiment of the present invention is described below with reference to FIGS. 5A to 5C.

FIG. 5A is a top view of the cell 600. Furthermore, FIGS. 5B and 5C are cross-sectional views of the cell 600. FIG. 5B is a cross-sectional view taken along dashed-dotted line A1-A2 in FIG. 5A, which corresponds to a cross-sectional view in the channel length direction of the transistor 200. FIG. 5C is a cross-sectional view taken along dashed-dotted line A3-A4 in FIG. 5A, which corresponds to a cross-sectional view in the channel width direction of the transistor 200. For simplification of the drawing, some components are not illustrated in the top view in FIG. 5A.

Note that in the semiconductor device illustrated in FIGS. 5A to 5C, components having the same functions as the components included in the semiconductor device described in <Structure example 1 of semiconductor device> are denoted by the same reference numerals.

A structure of the cell 600 is described with reference to FIGS. 5A to 5C below. Note that also in this section, the materials described in detail in <Structure example 1 of semiconductor device> can be used as materials of the cell 600.

### [Cell 600]

As illustrated in FIGS. 5A to 5C, the cell 600 differs from the semiconductor device described in <Structure example 1 of semiconductor device> at least in the shape of the capacitor 100.

Specifically, as illustrated in FIGS. 5A to 5C, the insulator 130 may be in contact with the insulator 280 over the insulator 271. Since the insulator 130 is in contact with the insulator 280, the conductor 252c electrically connected to the conductor 260 is connected to the conductor 260 in a region where the conductor 260 and the oxide 230 do not overlap with each other as illustrated in FIG. 5C.

For example, after the insulator 280 is formed, an opening is formed in the insulators 280 and 274 so that the region 231b of the oxide 230 is exposed. An insulating film to be the insulator 130 is formed to be in contact with the side surface of the opening and the region 231b of the oxide 230 in the opening. Then, a conductive film to be the conductor 120 is formed so as to be embedded in the opening with an insulating film to be the insulator 130 provided therebetween.

### Structure Example 3 of Semiconductor Device

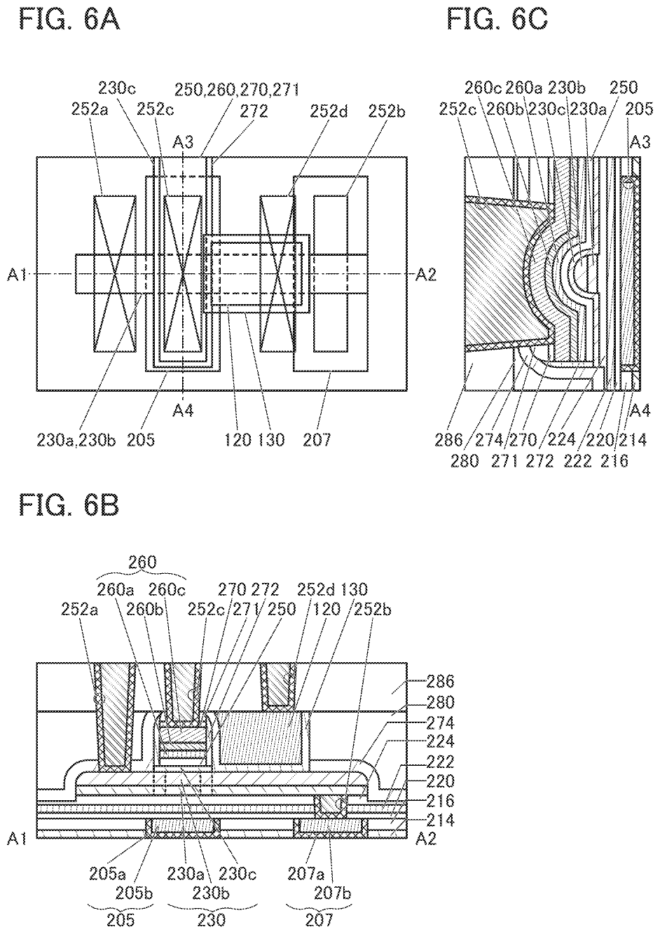

An example of a semiconductor device including the cell 600 of one embodiment of the present invention is described below with reference to FIGS. 6A to 6C.

FIG. 6A is a top view of the cell 600. Furthermore, FIGS. 6B and 6C are cross-sectional views of the cell 600. FIG. 6B is a cross-sectional view taken along dashed-dotted line A1-A2 in FIG. 6A, which corresponds to a cross-sectional view in the channel length direction of the transistor 200. FIG. 6C is a cross-sectional view taken along dashed-dotted line A3-A4 in FIG. 6A, which corresponds to a cross-sectional view in the channel width direction of the transistor 200. For simplification of the drawing, some components are not illustrated in the top view in FIG. 6A.

Note that in the semiconductor device illustrated in FIGS. 6A to 6C, components having the same functions as the components in the semiconductor device described in <Structure example 1 of semiconductor device> are denoted by the same reference numerals.

A structure of the cell 600 is described with reference to FIGS. 6A to 6C below. Note that as materials of the cell 600 in this section, the materials described in <Structure example 1 of semiconductor device> can be used.

### [Cell 600]

As illustrated in FIGS. 6A to 6C, the cell 600 differs from the semiconductor device described in <Structure example 1 of semiconductor device> at least in the shape of the conductor 252b which is electrically connected to the transistor 200.

Specifically, as illustrated in FIGS. 6A to 6C, the conductor 252b which is electrically connected to the region 231b of the transistor 200 may be in contact with the bottom portion of the oxide 230a. With this structure, the conductor 252b, a conductor 207 (a conductor 207a and a conductor 207b), and the cell 600 can be provided to overlap with each other. Furthermore, in the case where the cell 600 is electrically connected to the another structure body provided below the cell 600, a lead wiring above the cell 600 which is electrically connected to the conductor 252b, a plug which electrically connects the lead wiring to the structure body provided below the cell 600, or the like is unnecessary; thus, the process can be shortened.

For example, the conductor 207 can be formed in the same step as the conductor 205.

### <Method 1 for Manufacturing Semiconductor Device>

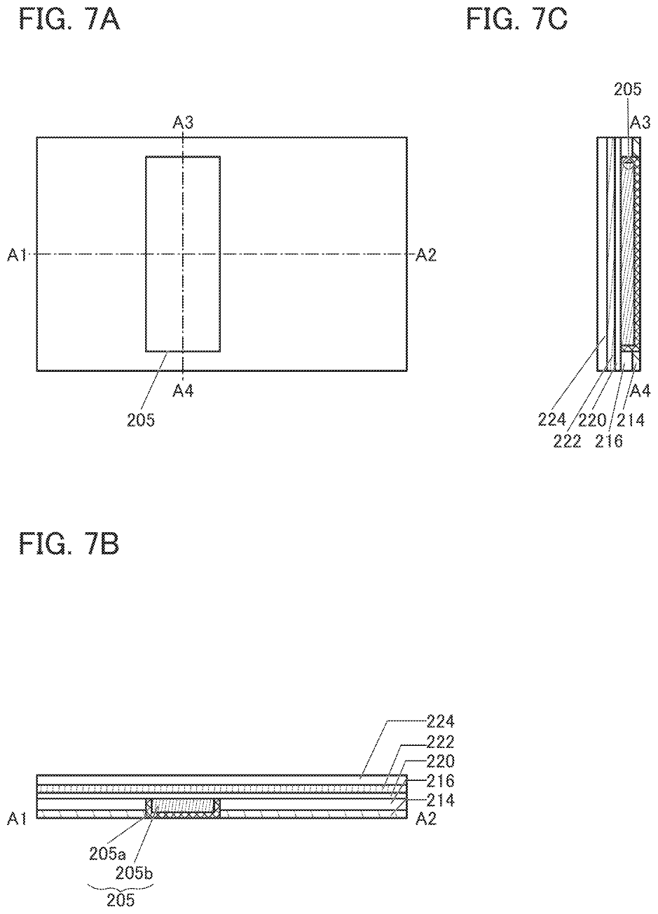

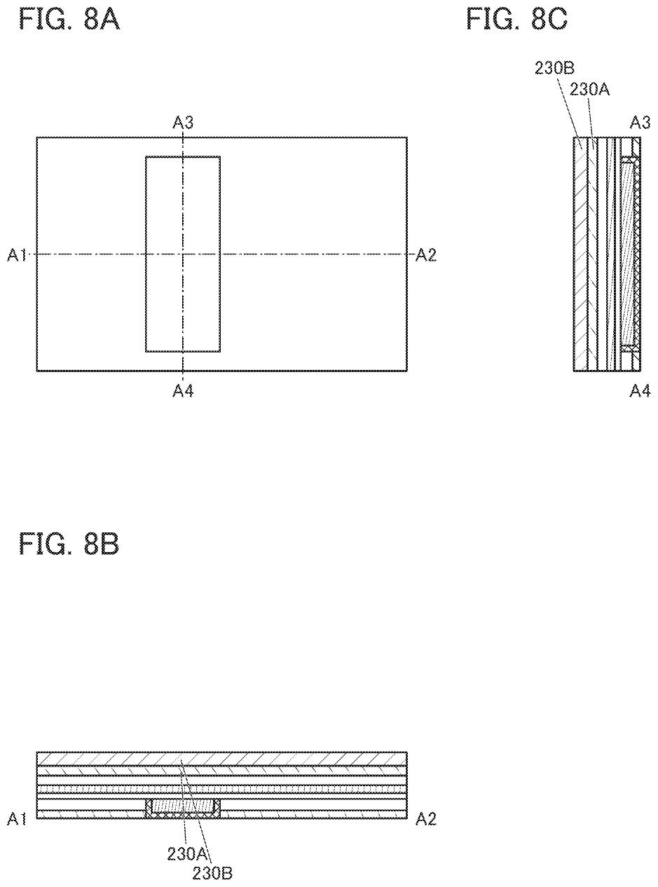

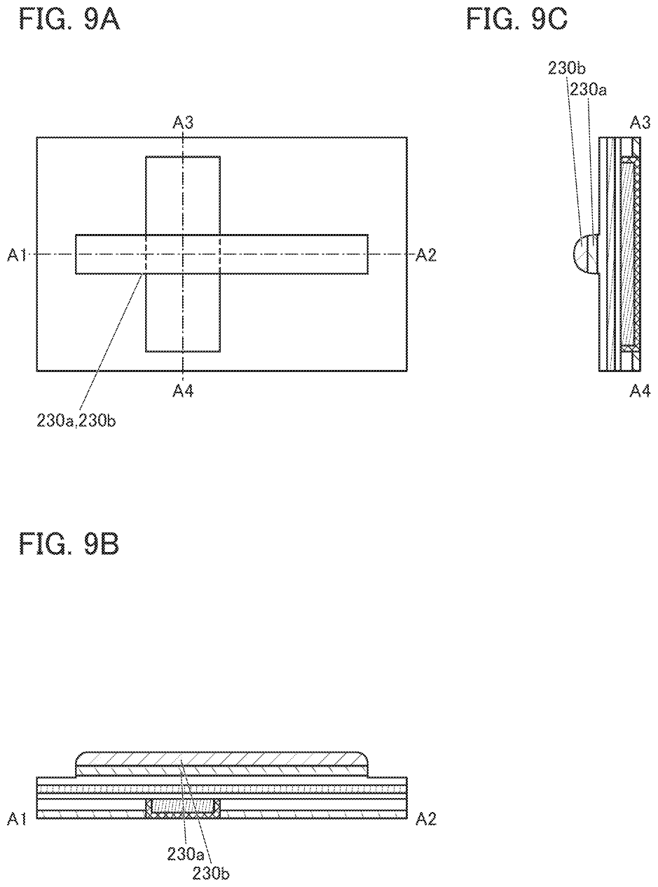

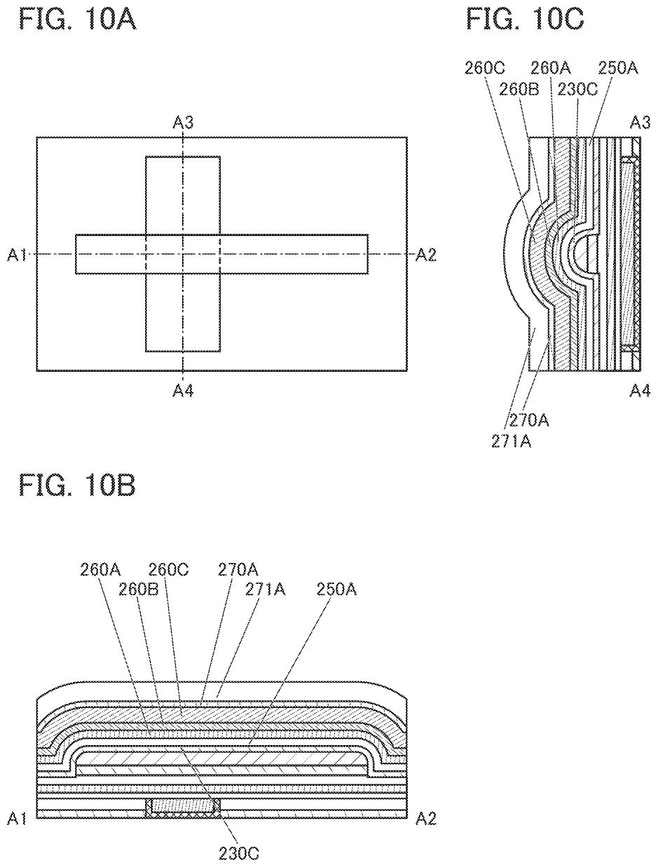

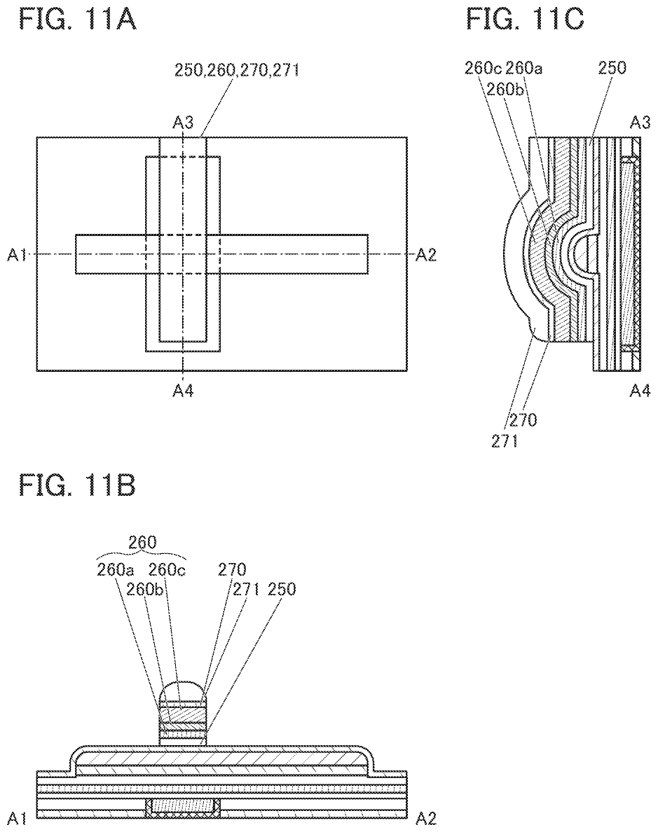

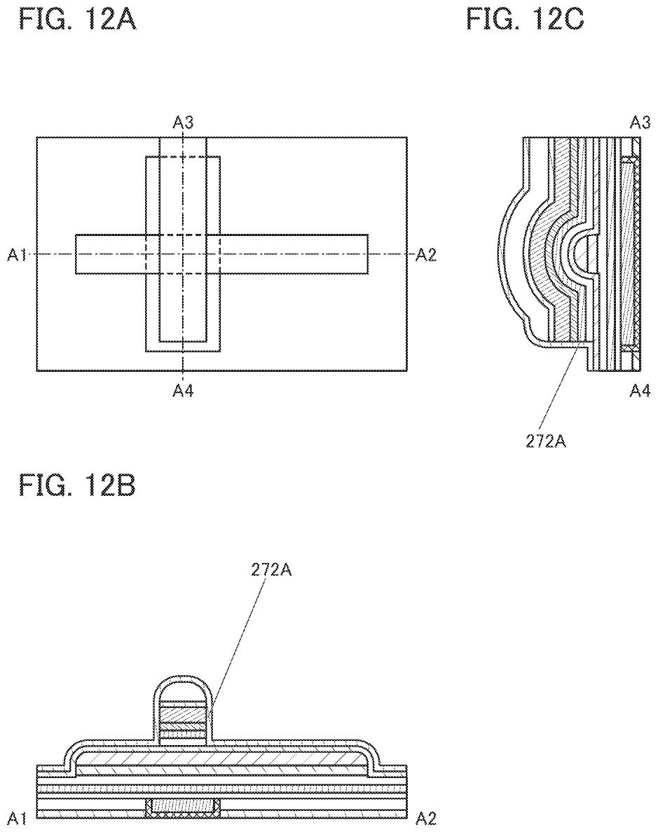

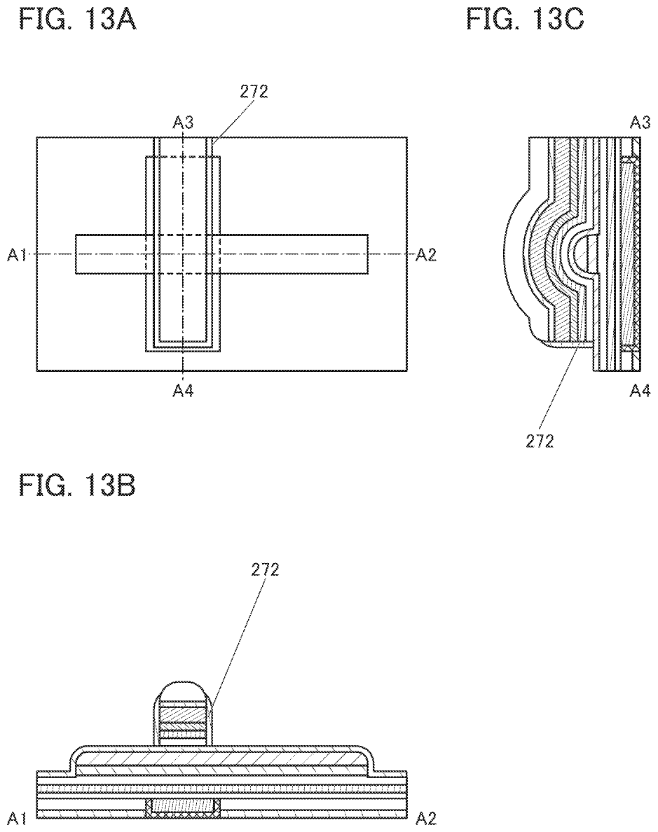

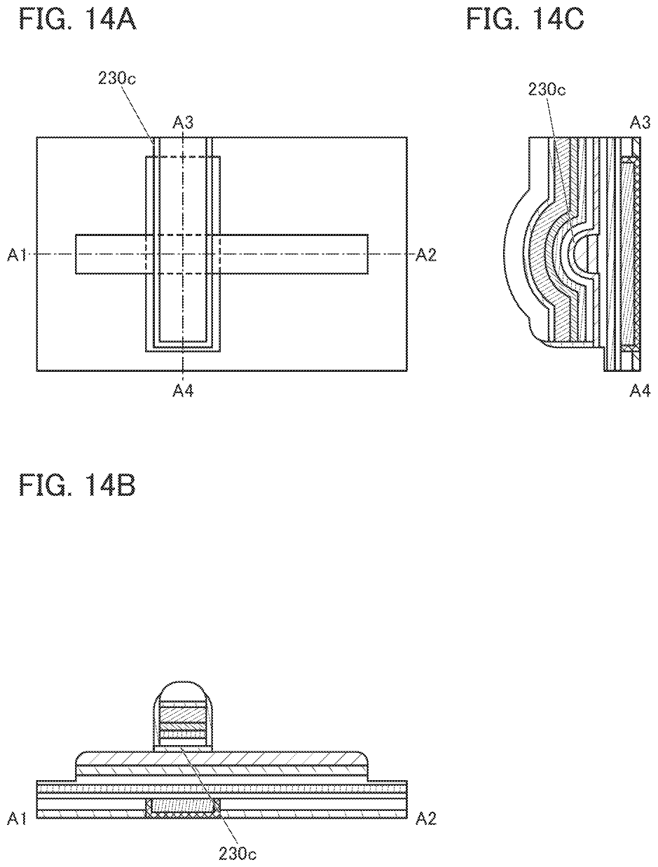

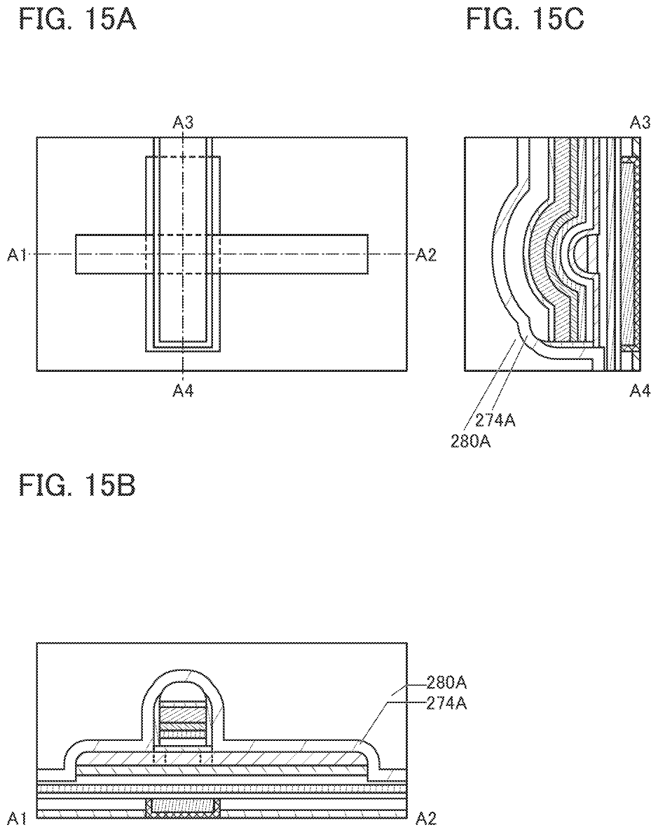

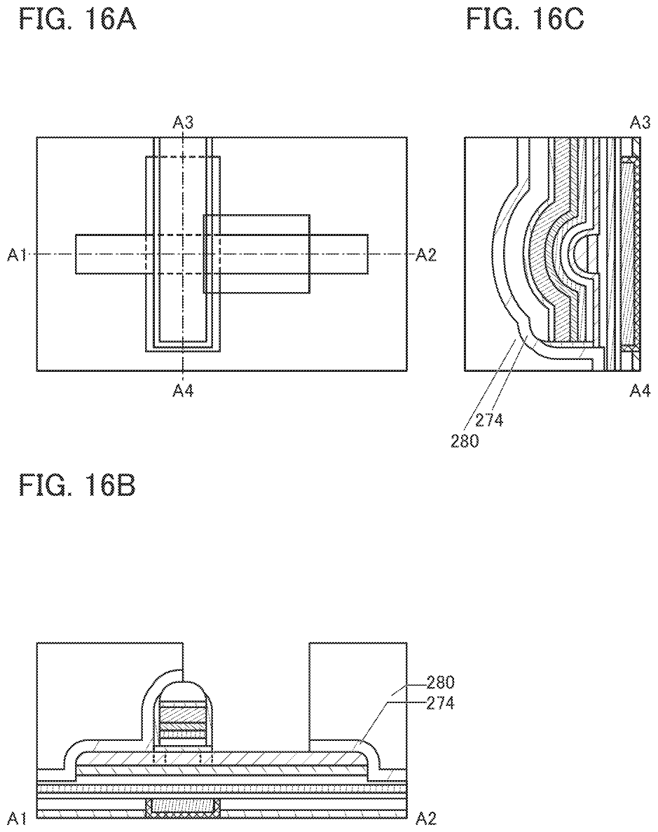

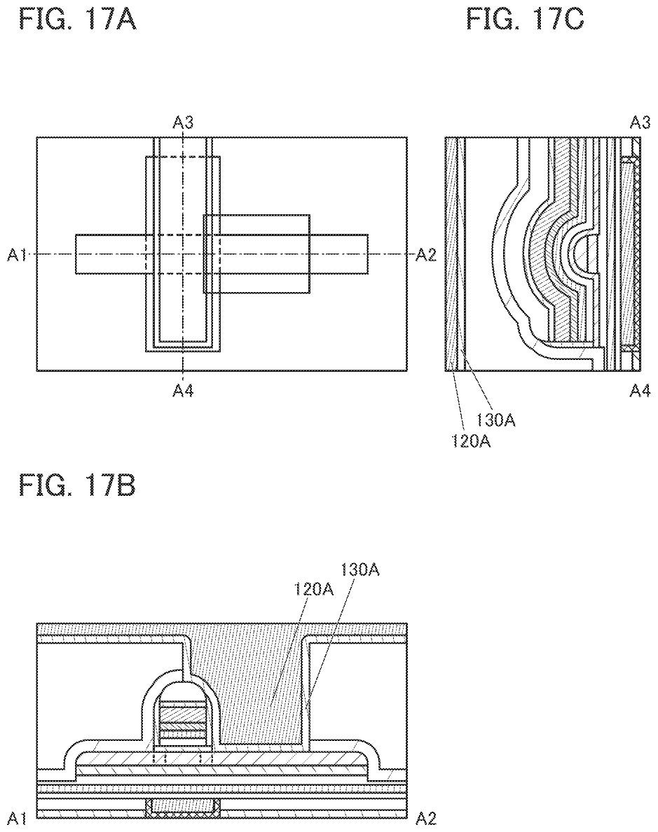

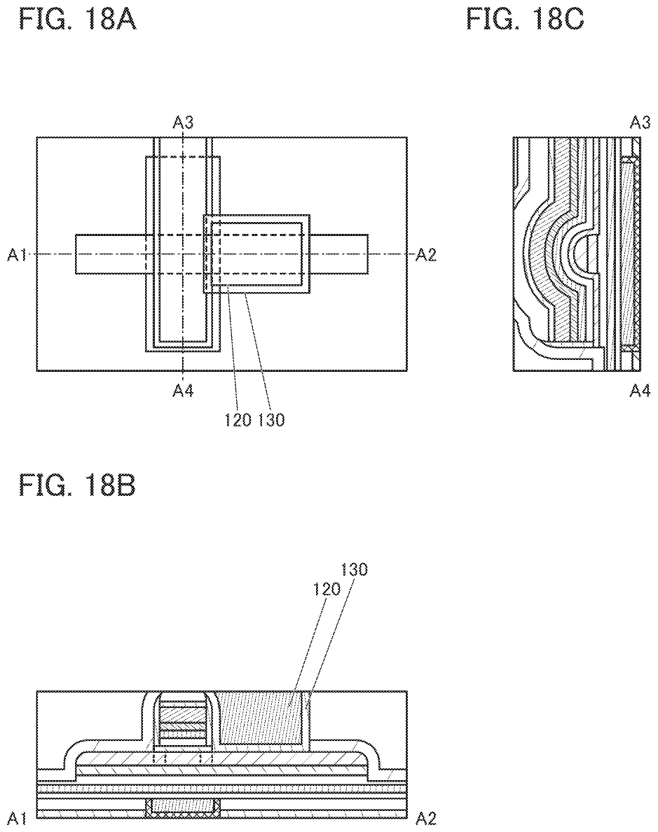

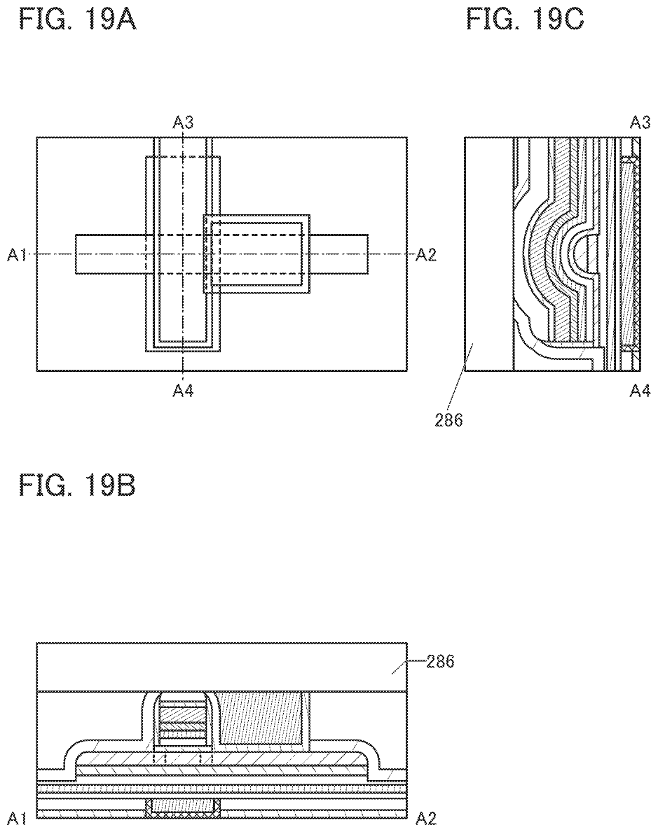

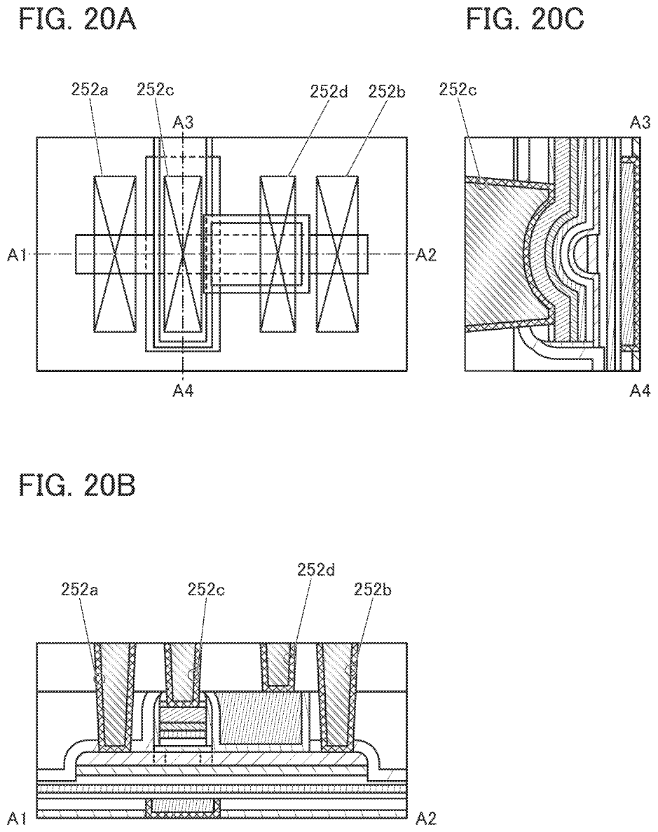

Next, a method for manufacturing a semiconductor device including the transistor 200 of one embodiment of the present invention is described with reference to FIGS. 7A to 7C, FIGS. 8A to 8C, FIGS. 9A to 9C, FIGS. 10A to 10C, FIGS. 11A to 11C, FIGS. 12A to 12C, FIGS. 13A to 13C, FIGS. 14A to 14C, FIGS. 15A to 15C, FIGS. 16A to 16A, FIGS. 17A to 17C, FIGS. 18A to 18C, FIGS. 19A to 19C, and FIGS. 20A to 20C. FIG. 7A, FIG. 8A, FIG. 9A, FIG. 10A, FIG. 11A, FIG. 12A, FIG. 13A, FIG. 14A, FIG. 15A, FIG. 16A, FIG. 17A, FIG. 18A, FIG. 19A, and FIG. 20A are top views. FIG. 7B, FIG. 8B, FIG. 9B, FIG. 10B, FIG. 11B, FIG. 12B, FIG. 13B, FIG. 14B, FIG. 15B, FIG. 16B, FIG. 17B, FIG. 18B, FIG. 19B, and FIG. 20B are cross-sectional views taken along dashed-dotted lines A1-A2 in FIG. 7A, FIG. 8A, FIG. 9A, FIG. 10A, FIG. 11A, FIG. 12A, FIG. 13A, FIG. 14A, FIG. 15A, FIG. 16A, FIG. 17A, FIG. 18A, FIG. 19A, and FIG. 20A. FIG. 7C, FIG. 8C, FIG. 9C, FIG. 10C, FIG. 11C, FIG. 12C, FIG. 13C, FIG. 14C, FIG. 15C, FIG. 16C, FIG. 17C, FIG. 18C, FIG. 19C, and FIG. 20C are cross-sectional views taken along dashed-dotted lines A3-A4 in FIG. 7A, FIG. 8A, FIG. 9A, FIG. 10A, FIG. 11A, FIG. 12A, FIG. 13A, FIG. 14A, FIG. 15A, FIG. 16A, FIG. 17A, FIG. 18A, FIG. 19A, and FIG. 20A.

First, a substrate (not illustrated) is prepared, and the insulator 214 is formed over the substrate. The insulator 214 can be formed by a sputtering method, a chemical vapor deposition (CVD) method, a molecular beam epitaxy (MBE) method, a pulsed laser deposition (PLD) method, an ALD method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

By using the PECVD method, a high-quality film can be formed at a relatively low temperature. Furthermore, a thermal CVD method does not use plasma and thus causes less plasma damage to an object. For example, a wiring, an electrode, an element (e.g., transistor or capacitor), or the like included in a semiconductor device might be charged up by receiving charges from plasma. In that case, accumulated charges might break the wiring, electrode, element, or the like included in the semiconductor device. By contrast, when a thermal CVD method not using plasma is employed, such plasma damage is not caused and the yield of the semiconductor device can be increased. A thermal CVD method does not cause plasma damage during deposition, so that a film with few defects can be obtained.

An ALD method also causes less plasma damage to an object. An ALD method does not cause plasma damage during deposition, so that a film with few defects can be obtained.

Unlike in a deposition method in which particles ejected from a target or the like are deposited, in a CVD method and an ALD method, a film is formed by reaction at a surface of an object. Thus, a CVD method and an ALD method enable favorable step coverage almost regardless of the shape of an object. In particular, an ALD method enables excellent step coverage and excellent thickness uniformity and can be favorably used for covering a surface of an opening with a high aspect ratio, for example. On the other hand, an ALD method has a relatively low deposition rate; thus, it is sometimes preferable to combine an ALD method with another deposition method with a high deposition rate such as a CVD method.

When a CVD method or an ALD method is used, composition of a film to be formed can be controlled with a flow rate ratio of the source gases. For example, by a CVD method or an ALD method, a film with a certain composition can be formed depending on a flow rate ratio of the source gases. Moreover, with a CVD method or an ALD method, by changing the flow rate ratio of the source gases while forming the film, a film whose composition is continuously changed can be formed. In the case where the film is formed while changing the flow rate ratio of the source gases, as compared to the case where the film is formed using a plurality of deposition chambers, time taken for the film formation can be reduced because time taken for transfer and pressure adjustment is omitted. Thus, semiconductor devices can be manufactured with improved productivity in some cases.

In this embodiment, aluminum oxide is formed as the insulator 214 by a sputtering method. The insulator 214 may have a multilayer structure. For example, the multilayer structure may be formed in such a manner that an aluminum oxide is formed by a sputtering method and an aluminum oxide is formed over the aluminum oxide by an ALD method. Alternatively, the multilayer structure may be formed in such a manner that an aluminum oxide is formed by an ALD method and an aluminum oxide is formed over the aluminum oxide by a sputtering method.

Next, the insulator 216 is formed over the insulator 214. The insulator 216 can be formed by a sputtering method, a CVD method, an MBE method, a PLD method, an ALD method, or the like. In this embodiment, as the insulator 216, silicon oxide is formed by a CVD method.

Then, an opening is formed in the insulator 216. Examples of the opening include grooves and slits. A region where the opening is formed may be referred to as an opening portion. The opening can be formed by wet etching; however, dry etching is preferable for microfabrication. The insulator 214 is preferably an insulator that serves as an etching stopper film used in forming the groove by etching the insulator to be the insulator 216. For example, in the case where a silicon oxide film is used as the insulator 216 in which the groove is to be formed, the insulator 214 is preferably formed using a silicon nitride film, an aluminum oxide film, or a hafnium oxide film.

After formation of the opening, a conductive film to be the conductor 205a is formed. The conductive film preferably includes a conductor that has a function of inhibiting the penetration of oxygen. For example, tantalum nitride, tungsten nitride, or titanium nitride can be used. Alternatively, a stacked-layer film formed using the conductor and tantalum, tungsten, titanium, molybdenum, aluminum, copper, or a molybdenum-tungsten alloy can be used. A conductor to be the conductor 205a is formed by a sputtering method, a CVD method, an MBE method, a PLD method, an ALD method, or the like.

In this embodiment, as the conductive film to be the conductor 205a, tantalum nitride or a stacked film of tantalum nitride and titanium nitride formed over the tantalum nitride is formed by a sputtering method. Even when a metal that is easily diffused, such as copper, is used for the conductor 205b to be described later, the use of such a metal nitride as the conductor 205a can prevent the metal from being diffused to the outside of the conductor 205a.

Next, a conductive film to be the conductor 205b is formed over the conductive film to be the conductor 205a. The conductive film can be formed by a sputtering method, a CVD method, an MBE method, a PLD method, an ALD method, or the like. In this embodiment, as the conductive film to be the conductor 205b, a low-resistant conductive material such as tungsten and copper is formed.

Next, by CMP treatment, the conductive film to be the conductor 205a and the conductive film to be the conductor 205b are partly removed to expose the insulator 216. As a result, the conductive film to be the conductor 205a and the conductive film to be the conductor 205b remain only in the opening. Thus, the conductor 205 including the conductors 205a and 205b, which has a flat top surface, can be formed (see FIGS. 7A to 7C). Note that the insulator 216 is partly removed by the CMP treatment in some cases.

Next, the insulator 220 is formed over the insulator 216 and the conductor 205. The insulator 220 can be formed by a sputtering method, a CVD method, an MBE method, a PLD method, an ALD method, or the like.

Then, the insulator 222 is formed over the insulator 220. The insulator 222 can be formed by a sputtering method, a CVD method, an MBE method, a PLD method, an ALD method, or the like.

It is particularly preferable that hafnium oxide be formed as the insulator 222 by an ALD method. Hafnium oxide formed by an ALD method has a barrier property against oxygen, hydrogen, and water. When the insulator 222 has a barrier property against hydrogen and water, hydrogen and water contained in structure bodies provided around the transistor 200 are not diffused into the transistor 200, and generation of oxygen vacancies in the oxide 230 can be inhibited.

Then, the insulator 224 is formed over the insulator 222. The insulator 224 can be formed by a sputtering method, a CVD method, an MBE method, a PLD method, an ALD method, or the like (see FIGS. 7A to 7C).

Subsequently, heat treatment is preferably performed. The heat treatment can be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. The first heat treatment is performed in a nitrogen atmosphere, an inert gas atmosphere, or an atmosphere containing an oxidizing gas at 10 ppm or more, 1% or more, or 10% or more. The first heat treatment may be performed under a reduced pressure. Alternatively, the first heat treatment may be performed in such a manner that heat treatment is performed in a nitrogen atmosphere or an inert gas atmosphere, and then another heat treatment is performed in an atmosphere containing an oxidizing gas at 10 ppm or more, 1% or more, or 10% or more in order to compensate for released oxygen.

By the above heat treatment, impurities such as hydrogen and water included in the insulator 224 can be removed, for example.

Alternatively, in the heat treatment, plasma treatment using oxygen may be performed under a reduced pressure. The plasma treatment using oxygen is preferably performed using an apparatus including a power source for generating high-density plasma using microwaves, for example. Alternatively, a power source for applying a radio frequency (RF) to a substrate side may be provided. The use of high-density plasma enables high-density oxygen radicals to be produced, and application of the RF to the substrate side allows oxygen radicals generated by the high-density plasma to be efficiently introduced into the insulator 224. Alternatively, after plasma treatment using an inert gas with the apparatus, plasma treatment using oxygen in order to compensate for released oxygen may be performed. Note that the first heat treatment is not necessarily performed in some cases.

This heat treatment can also be performed after the formation of the insulator 220 and after the formation of the insulator 222. Although the heat treatment can be performed under the conditions for the heat treatment, heat treatment after the formation of the insulator 220 is preferably performed in an atmosphere containing nitrogen.

In this embodiment, the heat treatment is performed in a nitrogen atmosphere at 400° C. for one hour after formation of the insulator 224.

Next, an oxide film 230A to be the oxide 230a, and an oxide film 230B to be the oxide 230b are sequentially formed over the insulator 224 (see FIGS. 8A to 8C). Note that the oxide films are preferably formed successively without exposure to the air. When the oxide films are formed without exposure to the air, impurities or moisture from the air can be prevented from being attached to the oxide films 230A and 230B, so that an interface between the oxide films 230A and 230B and the vicinity of the interface can be kept clean.

The oxide films 230A and 230B can be formed by a sputtering method, a CVD method, an MBE method, a PLD method, an ALD method, or the like.

In the case where the oxide films 230A and 230B are formed by a sputtering method, for example, oxygen or a mixed gas of oxygen and a rare gas is used as a sputtering gas. By increasing the proportion of oxygen in the sputtering gas, the amount of excess oxygen in the oxide films to be formed can be increased. In the case where the above oxide films are formed by a sputtering method, the above In-M-Zn oxide target can be used.

In particular, when the oxide film 230A is formed, part of oxygen contained in the sputtering gas is supplied to the insulator 224 in some cases. Note that the proportion of oxygen in the sputtering gas for formation of the oxide film 230A is preferably 70% or higher, further preferably 80% or higher, and still further preferably 100%.

In the case where the oxide film 230B is formed by a sputtering method, when the proportion of oxygen in the sputtering gas is higher than or equal to 1% and lower than or equal to 30%, preferably higher than or equal to 5%, and lower than or equal to 20%, an oxygen-deficient oxide semiconductor is formed. A transistor including an oxygen-deficient oxide semiconductor can have relatively high field-effect mobility.

In this embodiment, the oxide film 230A is formed using a target with an atomic ratio of In:Ga:Zn=1:3:4 by a sputtering method. The oxide film 230B is formed using a target with an atomic ratio of In:Ga:Zn=4:2:4.1 by a sputtering method. Note that each of the oxide films is preferably formed by appropriate selection of film formation conditions and an atomic ratio to have characteristics required for the oxide 230.

Next, heat treatment may be performed. For the heat treatment, the conditions for the heat treatment can be used. By the heat treatment, impurities such as hydrogen and water contained in the oxide films 230A and 230B can be removed, for example. In this embodiment, treatment is performed in a nitrogen atmosphere at 400° C. for one hour, and successively another treatment is performed in an oxygen atmosphere at 400° C. for one hour.

Then, the oxide films 230A and 230B are processed into island shapes to form the oxides 230a and 230b (see FIGS. 9A to 9C). In this step, the insulator 222 can be used as an etching stopper film, for example.

Note that in the above step, the insulator 224 may be processed into an island shape. Furthermore, the insulator 224 may be subjected to half-etching. The insulator 224 may be subjected to half-etching, in which case the insulator 224 remains under the oxide 230c to be formed in a later step. Note that the insulating film 224 can be processed into island shapes when an insulating film 272A is processed in a later step.

The oxides 230a and 230b are formed to at least partly overlap with the conductors 205. It is preferable that the side surfaces of the oxides 230a and 230b be substantially perpendicular to the insulator 222, in which case a smaller area and higher density can be achieved when the plurality of transistors 200 are provided. Note that an angle formed by the side surfaces of the oxides 230a and 230b and the top surface of the insulator 222 may be an acute angle. In that case, the angle formed by the side surfaces of the oxides 230a and 230b and the top surface of the insulator 222 is preferably larger.

The oxide 230 has a curved surface between the side surfaces of the oxides 230a and 230b and the top surfaces of the oxides 230a and 230b. That is, an end portion of the side surface and an end portion of the top surface are preferably curved (hereinafter such a curved shape is also referred to as a rounded shape). The radius of curvature of the curved surface at an end portion of the oxide 230b is greater than or equal to 3 nm and less than or equal to 10 nm, preferably greater than or equal to 5 nm and less than or equal to 6 nm.

Note that when the end portions are not angular, the coverage with films formed later in the film formation process can be improved.

Note that the oxide films may be processed by a lithography method. The processing can be performed by a dry etching method or a wet etching method. A dry etching method is suitable for microfabrication.

In the lithography method, first, a resist is exposed to light through a mask. Next, a region exposed to light is removed or left using a developing solution, so that a resist mask is formed. Then, etching through the resist mask is conducted. As a result, a conductor, a semiconductor, an insulator, or the like can be processed in to a desired shape. The resist mask is formed by, for example, exposure of the resist to light using KrF excimer laser light, ArF excimer laser light, extreme ultraviolet (EUV) light, or the like. Alternatively, a liquid immersion technique may be employed in which a portion between a substrate and a projection lens is filled with liquid (e.g., water) to perform light exposure. An electron beam or an ion beam may be used instead of the above-mentioned light. Note that a mask is not necessary in the case of using an electron beam or an ion beam. To remove the resist mask, dry etching treatment such as ashing or wet etching treatment can be used. Alternatively, wet etching treatment can be performed after dry etching treatment. Further alternatively, dry etching treatment can be performed after wet etching treatment.

A hard mask formed of an insulator or a conductor may be used instead of the resist mask. In the case where a hard mask is used, a hard mask with a desired shape can be formed in the following manner: an insulating film or a conductive film that is the material of the hard mask is formed over the oxide film 230B, a resist mask is formed thereover, and then the material of the hard mask is etched. The etching of the oxide films 230A and 230B may be performed after or without removal of the resist mask. In the latter case, the resist mask may be removed during the etching. The hard mask may be removed by etching after the etching of the oxide films. The hard mask does not need to be removed in the case where the material of the hard mask does not affect the following process or can be utilized in the following process.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, the capacitively coupled plasma etching apparatus may have a structure in which different high-frequency power sources are applied to one of the parallel plate type electrodes. Alternatively, the capacitively coupled plasma etching apparatus may have a structure in which high-frequency power sources with the same frequency are applied to the parallel plate type electrodes. Alternatively, the capacitively coupled plasma etching apparatus may have a structure in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

In some cases, the treatment such as dry etching causes the attachment or diffusion of impurities due to an etching gas or the like to a surface or an inside of the oxide 230a, the oxide 230b, or the like. Examples of the impurities include fluorine and chlorine.

In order to remove the impurities, cleaning is performed. As the cleaning, any of wet cleaning using a cleaning solution or the like, plasma treatment using plasma, cleaning by heat treatment, and the like can be performed by itself or in appropriate combination.

The wet cleaning may be performed using an aqueous solution in which oxalic acid, phosphoric acid, hydrofluoric acid, or the like is diluted with carbonated water or pure water. Alternatively, ultrasonic cleaning using pure water or carbonated water may be performed. In this embodiment, ultrasonic cleaning using pure water or carbonated water is performed.

Next, heat treatment may be performed. For the heat treatment, the conditions for the above heat treatment can be used.

Then, an oxide film 230C, an insulating film 250A, a conductive film 260A, a conductive film 260B, a conductive film 260C, an insulating film 270A, and the insulating film 272A are formed in this order over the insulator 222, the oxide 230a, and the oxide 230b (see FIGS. 10A to 10C).

The oxide film 230C can be formed by a sputtering method, a CVD method, an MBE method, a PLD method, an ALD method, or the like. The oxide film 230C may be formed by a method similar to that of the oxide film 230A or the oxide film 230B in accordance with characteristics required for the oxide 230c. In this embodiment, the oxide film 230C is formed using a target with an atomic ratio of In:Ga:Zn=4:2:4.1 by a sputtering method.

The insulating film 250A can be formed by a sputtering method, a CVD method, an MBE method, a PLD method, an ALD method, or the like.

Note that oxygen is excited by microwaves to generate high-density oxygen plasma, and the insulating film 250A is exposed to the oxygen plasma, whereby oxygen can be supplied to the insulating film 250A, the oxide 230a, the oxide 230b, and the oxide film 230C.

Furthermore, heat treatment may be performed. For the heat treatment, the conditions for the above heat treatment can be used. The heat treatment can reduce the moisture concentration and the hydrogen concentration in the insulating film 250A.

The conductive film 260A can be formed by a sputtering method, a CVD method, an MBE method, a PLD method, an ALD method, or the like. Here, when an oxide semiconductor that can be used as the oxide 230 is subjected to treatment for reducing resistance, for example, the oxide semiconductor becomes a conductive oxide. Accordingly, an oxide that can be used as the oxide 230 may be formed as the conductive film 260A and the resistance of the oxide may be reduced in a later step. Note that when an oxide that can be used as the oxide 230 is formed as the conductive film 260A in an atmosphere containing oxygen by a sputtering method, oxygen can be added to the insulating film 250A. When oxygen is added to the insulating film 250A, the added oxygen can be supplied to the oxide 230 through the insulating film 250A.

The conductive film 260B can be formed by a sputtering method, a CVD method, an MBE method, a PLD method, an ALD method, or the like. In the case where an oxide semiconductor that can be used as the oxide 230 is used for the conductive film 260A, the conductive film 260B is formed by a sputtering method, whereby the conductive film 260A can have reduced electric resistance and become a conductor. Such a conductor can be called an oxide conductor (OC) electrode. A conductor may be further formed over the conductor over the OC electrode by a sputtering method or the like.

Furthermore, when a low-resistance metal film is stacked as the conductive film 260C, a transistor with a low driving voltage can be provided.

Subsequently, heat treatment can be performed. For the heat treatment, the conditions for the above heat treatment can be used. Note that the heat treatment is not necessarily performed in some cases. In this embodiment, the heat treatment is performed in a nitrogen atmosphere at 400° C. for one hour.

The insulating film 270A can be formed by a sputtering method, a CVD method, an MBE method, a PLD method, an ALD method, or the like. The insulating film 270A which serves as a barrier film is formed using an insulating material having a function of inhibiting the penetration of oxygen and impurities such as water and hydrogen. For example, aluminum oxide or hafnium oxide is preferably used. Thus, oxidation of the conductor 260 can be prevented. This can prevent entry of impurities such as water or hydrogen into the oxide 230 through the conductor 260 and the insulator 250.

The side surface of the insulator 250, a side surface of the conductor 260a, a side surface of the conductor 260b, and the side surface of the insulator 270 are preferably on the same surface. It is preferable that the surface shared by the side surfaces of the insulator 250, the conductor 260a, the conductor 260b, and the insulator 270 be substantially perpendicular to the substrate. That is, in a cross section, an angle between the top surface of the oxide 230 and the side surfaces of the insulator 250, the conductor 260a, the conductor 260b, and the insulator 270 is preferably an acute angle and larger. Note that in the cross section, the angle formed by the top surface of the oxide 230 and the side surfaces of the insulator 250, the conductor 260a, the conductor 260b, and the insulator 270 may be an acute angle. In that case, the angle formed by the top surface of the oxide 230 and the side surfaces of the insulator 250, the conductor 260a, the conductor 260b, and the insulator 270 is preferably as large as possible.

The insulating film 271A can be formed by a sputtering method, a CVD method, an MBE method, a PLD method, an ALD method, or the like. Here, the thickness of the insulating film 271A is preferably larger than that of the insulating film 272A to be formed in a later step. In that case, when the insulator 272 is formed in the following process, the insulator 271 can remain easily over the conductor 260.

The insulator 271 functions as a hard mask. The provision of the insulator 271 makes it possible for the side surface of the insulator 250, the side surface of the conductor 260a, the side surface of the conductor 260b, the side surface of the conductor 260c, and the side surface of the insulator 270 to be formed substantially perpendicular to the substrate.

Next, the insulating film 271A is etched to form the insulator 271. Then, using the insulator 271 as a mask, the insulating film 250A, the conductive film 260A, the conductive film 260B, the conductive film 260C, and the insulating film 270A are etched to form the insulator 250, the conductor 260 (the conductor 260a, the conductor 260b, and the conductor 260c), and the insulator 270 (see FIGS. 11A to 11C). Note that after the processing, the following process may be performed without removal of the hard mask. The hard mask can also function as a hard mask used in a step of adding a dopant, which is to be performed later.

The insulator 250, the conductor 260, and the insulator 271 are formed to at least partly overlap with the conductor 205 and the oxide 230.

Note that an upper portion of the oxide film 230C in a region not overlapping with the insulator 250 may be etched by the above etching. In that case, the oxide film 230C may be thicker in the region overlapping with the insulator 250 than in the region not overlapping with the insulator 250.

Next, the insulating film 272A is formed to cover the insulator 222, the insulator 224, the oxide film 230C, the insulator 250, the conductor 260, the insulator 270, and the insulator 271 (see FIGS. 12A to 12C). The insulating film 272A is preferably formed with a sputtering apparatus. When the sputtering method is used, an excess-oxygen region can be easily formed in each of the insulator 250 in contact with the insulating film 272A and the insulator 224.

Here, during deposition by a sputtering method, ions and sputtered particles exist between a target and a substrate. For example, a potential E₀ is supplied to the target, to which a power source is connected. A potential E₁ such as a ground potential is supplied to the substrate. Note that the substrate may be electrically floating. In addition, there is a region at a potential E₂ between the target and the substrate. The potential relationship is E₂>E₁>E₀.

The ions in plasma are accelerated by a potential difference (E₂−E₀) and collide with the target; accordingly, the sputtered particles are ejected from the target. These sputtered particles are attached to a deposition surface and deposited thereover; as a result, a film is formed. Some ions recoil by the target and might, as recoil ions, pass through the formed film and be taken into the insulator 224 and the insulator 250 in contact with a formation surface. The ions in the plasma are accelerated by a potential difference (E₂−E₁) and collide with the deposition surface. At that time, some ions reach the inside of the insulators 250 and 224. When the ions are taken into the insulators 250 and 224, a region into which the ions are taken is formed in the insulators 250 and 224. That is, an excess-oxygen region is formed in the insulators 250 and 224 in the case where the ions include oxygen.

Introduction of excess oxygen to the insulators 250 and 224 can form an excess-oxygen region. The excess oxygen in the insulators 250 and 224 is supplied to the oxide 230 and can fill oxygen vacancies in the oxide 230.

Accordingly, when the insulating film 272A is formed in an oxygen gas atmosphere with a sputtering apparatus, oxygen can be introduced into the insulators 250 and 224 while the insulating film 272A is formed. When aluminum oxide having a barrier property is used for the insulating film 272A, for example, excess oxygen introduced into the insulator 250 can be effectively sealed.

The insulating film 272A may be formed by an ALD method. When an ALD method is used, the insulating film 272A having good coverage with respect to the side surfaces of the insulator 250, the conductor 260, and the insulator 270 can be formed.

Here, the region 231, the junction region 232, and the region 234 may be formed in the oxide 230a, the oxide 230b, and the oxide film 230C. The region 231 and the junction region 232 are low-resistance regions which are obtained by adding a metal atom such as indium or impurities to a metal oxide formed as the oxide 230a, the oxide 230b, and the oxide film 230C. Note that each of the regions has higher conductivity than at least the oxide 230b in the region 234.

In order to add impurities to the region 231 and the junction region 232, a dopant which is at least one of the metal element such as indium and the impurities is added through the insulating film 272A, for example.

For the addition of the dopant, an ion implantation method by which an ionized source gas is subjected to mass separation and then added, an ion doping method by which an ionized source gas is added without mass separation, a plasma immersion ion implantation method, or the like can be used. In the case of performing mass separation, ion species to be added and its concentration can be controlled properly. On the other hand, in the case of not performing mass separation, ions at a high concentration can be added in a short time. Alternatively, an ion doping method in which atomic or molecular clusters are generated and ionized may be employed. Instead of the term “dopant,” the term “ion,” “donor,” “acceptor,” “impurity,” “element,” or the like may be used.

A dopant may be added by plasma treatment. In this case, the plasma treatment is performed with a plasma CVD apparatus, a dry etching apparatus, or an ashing apparatus, so that a dopant can be added to the oxide 230a, the oxide 230b, and the oxide film 230C.

When the indium content in the oxide 230a, the oxide 230b, and the oxide film 230C is increased, the carrier density can be increased and the resistance can be decreased. Accordingly, as a dopant, a metal element that improves the carrier density of the oxide 230a, the oxide 230b, and the oxide film 230C, such as indium, can be used.

That is, when the content of a metal atom such as indium in the oxide 230a, the oxide 230b, and the oxide film 230C is increased in the region 231 and the junction region 232, the electron mobility can be increased and the resistance can be decreased.

Accordingly, the atomic ratio of indium to the element M at least in the region 231 is larger than the atomic ratio of indium to the element M in the region 234.

As the dopant, the element forming an oxygen vacancy, the element trapped by an oxygen vacancy, or the like may be used. Typical examples of the element are hydrogen, boron, carbon, nitrogen, fluorine, phosphorus, sulfur, chlorine, titanium, and a rare gas element. Typical examples of the rare gas element are helium, neon, argon, krypton, and xenon.

Here, the insulating film 272A is provided to cover the oxide 230, the insulator 250, the conductor 260, and the insulator 270. Accordingly, in the direction perpendicular to the top surface of the oxide 230a, the oxide 230b, and the oxide film 230C, the thickness of the insulating film 272A is different between a region on the periphery of the side of the insulator 250, the conductor 260, and the insulator 270 and a region other than the above region. That is, the thickness of the insulating film 272A in the region on the periphery of the side of the insulator 250, the conductor 260, and the insulator 270 is larger than that in the region other than the above region. That is, when a dopant is added through the insulating film 272A, the region 231 and the junction region 232 can be provided in a self-aligned manner, even in a minute transistor whose channel length is approximately 10 nm to 30 nm. The junction region 232 may be formed in such a manner that the dopant in the region 231 is diffused in a step of heat treatment to be performed in a later step, for example.

When the junction region 232 is provided in the transistor 200, high-resistance regions are not formed between the region 231 functioning as the source region and the drain region and the region 234 where a channel is formed, so that the on-state current and the mobility of the transistor can be increased. Since the gate does not overlap with the source and drain regions in the channel length direction owing to the junction region 232, formation of unnecessary capacitance can be suppressed. A leakage current in an off state can be reduced owing to the junction region 232.

Thus, by appropriately selecting the areas of the region 231a and the region 231b, a transistor having electrical characteristics necessary for the circuit design can be easily provided.

Next, the insulating film 272A is subjected to anisotropic etching, whereby the insulator 272 is formed in contact with side surfaces of the insulator 250, the conductor 260, and the insulator 270 (see FIGS. 13A to 13C). Dry etching is preferably performed as the anisotropic etching. In this manner, the insulating film in a region on a plane substantially parallel to the substrate can be removed, so that the insulator 272 can be formed in a self-aligned manner.

Here, the thickness of the insulator 270 is made larger than that of the insulating film 272A, whereby the insulator 270 and the insulator 272 can be left even when portions of the insulating film 272A that are over the insulator 270 are removed. The height of a structure body composed of the insulator 250, the conductor 260, and the insulator 270 is larger than the total height of the oxide 230a, the oxide 230b, and the oxide film 230C, whereby the insulating film 272A formed on the side surfaces of the oxides 230a and 230b with the oxide film 230C provided therebetween can be removed. Furthermore, when the end portions of the oxides 230a and 230b each have a rounded shape, time taken to remove the insulating film 272A formed on the side surfaces of the oxides 230a and 230b with the oxide film 230C provided therebetween can be shortened, leading to easy formation of the insulator 272.

Note that the anisotropic etching may be performed before the addition of the dopant. In this case, the dopant is added to the oxide 230a, the oxide 230b, and the oxide film 230C without through the insulating film 272A.

Subsequently, heat treatment can be performed. For the heat treatment, the conditions for the above heat treatment can be used. The heat treatment allows diffusion of the added dopant into the junction region 232 in the oxide 230, resulting in an increase in on-state current.

Then, with the use of the insulator 250, the conductor 260, the insulators 270, 271, and 272 as masks, the oxide film 230C is etched, and part of the oxide film 230C is removed, so that the oxide 230c is formed (see FIGS. 14A to 14C). Note that with this step, part of the top surface and the side surface of the oxide 230b and part of the side surface of the oxide 230a is removed in some cases.

Next, an insulating film 274A and an insulating film 280A are formed to cover the insulator 224, the oxide 230, the insulator 272, and the insulator 270 (see FIGS. 15A to 15C).

For the insulating film 274A, silicon nitride, silicon nitride oxide, or silicon oxynitride can be formed by a CVD method can be used, for example. In this embodiment, silicon nitride oxide is used for the insulating film 274A.

When the insulating film 274A containing an element serving as an impurity such as nitrogen is formed in contact with the oxide 230, impurity elements such as hydrogen and nitrogen, which are contained in a deposition atmosphere of the insulating film 274A, are added to the regions 231a and 231b. Oxygen vacancies are formed because of the added impurity elements, and the impurity elements enter the oxygen vacancies mainly in a region of the oxide 230 which is in contact with the insulating film 274A, thereby increasing the carrier density and reducing the resistance. The impurities are diffused also into the junction region 232 that is not in contact with the insulating film 274A at this time, whereby the resistances are reduced.

Therefore, the region 231a and the region 231b preferably have a higher concentration of at least one of hydrogen and nitrogen than the region 234. The concentration of hydrogen or nitrogen can be measured by secondary ion mass spectrometry (SIMS) or the like. Here, the concentration of hydrogen or nitrogen in the middle of the region of the oxide 230b that overlaps with the insulator 250 (e.g., a portion in the oxide 230b which is located equidistant from both side surfaces in the channel length direction of the insulator 250) is measured as the concentration of hydrogen or nitrogen in the region 234.

The region 231 and the junction region 232 are reduced in resistance when an element forming an oxygen vacancy or an element trapped by an oxygen vacancy is added thereto. Typical examples of the element are hydrogen, boron, carbon, nitrogen, fluorine, phosphorus, sulfur, chlorine, titanium, and a rare gas. Typical examples of the rare gas element are helium, neon, argon, krypton, and xenon. Accordingly, the region 231 and the junction region 232 are made to include one or more of the above elements.

A film which extracts and absorbs oxygen from the region 231 and the junction region 232 may be used as the insulator 274A. When oxygen is extracted from the region 231 and the junction region 232, oxygen vacancy is generated in the region 231 and the junction region 232. Hydrogen, boron, carbon, nitrogen, fluorine, phosphorus, sulfur, chlorine, titanium, rare gas, or the like is trapped by oxygen vacancies; thus, the resistance of the region 231 and the junction region 232 is reduced.

To form the insulator 274A as an insulator containing an element serving as an impurity or an insulator extracting oxygen from the oxide 230, a sputtering method, a CVD method, an MBE method, a PLD method, an ALD method, or the like can be used.

The insulating film 274A containing an element serving as an impurity is preferably formed in an atmosphere containing at least one of nitrogen and hydrogen. In that case, oxygen vacancies are formed mainly in the region of the oxides 230b and 230c not overlapping with the insulator 250 and the oxygen vacancies and impurity elements such as nitrogen and hydrogen are bonded to each other, leading to an increase in carrier density. In this manner, the regions 231a and 231b with reduced resistance can be formed. For the insulating film 274A, for example, silicon nitride, silicon nitride oxide, or silicon oxynitride can be formed by a CVD method. In this embodiment, silicon nitride oxide is used for the insulating film 274A.

Accordingly, a source region and a drain region can be formed in a self-aligned manner owing to the formation of the insulating film 274A. Thus, minute or highly integrated semiconductor devices can be manufactured with high yield.

Here, the top and side surfaces of the conductor 260 and the insulator 250 are covered with the insulators 270 and 272, whereby impurity elements such as nitrogen and hydrogen can be prevented from entering the conductor 260 and the insulator 250. Thus, impurity elements such as nitrogen and hydrogen can be prevented from entering the region 234 functioning as the channel formation region of the transistor 200 through the conductor 260 and the insulator 250. Accordingly, the transistor 200 having favorable electrical characteristics can be provided.

Note that although the region 231, the junction region 232, and the region 234 are formed by the addition of a dopant or the reduction in the resistance by the formation of the insulating film 274A in the above, this embodiment is not limited thereto. For example, the regions may be formed through both of the addition of a dopant and the reduction in the resistance by the formation of the insulating film 274A. Alternatively, plasma treatment may be performed.

For example, plasma treatment may be performed on the oxide 230 using the insulator 250, the conductor 260, the insulator 272, and the insulator 270 as masks. The plasma treatment is performed in an atmosphere containing the above-described element forming an oxygen vacancy or the above-described element trapped by an oxygen vacancy. For example, the plasma treatment is performed using an argon gas and a nitrogen gas.

Then, the insulating film 280A is formed over the insulating film 274A. The insulating film 280A can be formed by a sputtering method, a CVD method, an MBE method, a PLD method, an ALD method, or the like. Alternatively, the insulating film 280A can be formed by a spin coating method, a dipping method, a droplet discharging method (such as an ink-jet method), a printing method (such as screen printing or offset printing), a doctor knife method, a roll coater method, a curtain coater method, or the like. In this embodiment, silicon oxynitride is used for the insulating film.

Note that the insulating film 280A is preferably formed to have a flat top surface. For example, the insulator 280 may have a flat top surface right after the formation of the insulating film to be the insulator 280. Alternatively, for example, the insulator 280 may have a flat top surface by removing the insulator or the like from the top surface after the formation so that the top surface becomes parallel to a reference surface such as a rear surface of the substrate. Such treatment is referred to as planarization treatment. As the planarization treatment, for example, CMP treatment, dry etching treatment, or the like can be performed. In this embodiment, CMP treatment is performed as the planarization treatment. Note that the top surface of the insulator 280 does not necessarily have planarity.

Then, the opening reaching the region 231b of the oxide 230 is formed in the insulating films 280A and 274A. The region 231b of the oxide 230 is exposed, so that the insulators 274 and 280 are formed (see FIGS. 16A to 16C).

The opening may be formed by a lithography method.

Then, an insulating film 130A is formed so as to cover at least the region 231b of the oxide 230 and the side surface of the opening in the insulator 274 and the insulator 280. The insulating film 130A can have a single-layer structure or a stacked-layer structure formed using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like.

For example, a stacked-layer structure of a high-k material such as aluminum oxide and a material with high dielectric strength such as silicon oxynitride is preferably used. Such a structure enables the capacitor 100 to have sufficient capacitance due to the high-k material and increased dielectric strength due to the material with high dielectric strength. Thus, the electrostatic breakdown of the capacitor 100 can be suppressed, which leads to improvement in the reliability of the capacitor 100.

Then, a conductive film 120A is formed over the region 231 of the oxide 230 with the insulating film 130A provided therebetween (see FIGS. 17A to 17C). At that time, the conductive film 120A is formed to be embedded in the opening provided in the insulators 274 and 280. The film to be the conductor 120 can be formed using a material and a method similar to those for the conductor 260.

Then, part of the conductive film 120A, the insulating film 130A, the insulator 274, and the insulator 280 are partly removed by CMP treatment to expose the insulator 271. As a result, the conductive film remains only in the opening, so that the conductor 120 having flat top surfaces can be formed (see FIGS. 18A to 18C).

Note that unnecessary portions of the film to be the conductor 120 may be removed by etching. In this step, the insulator 271 is exposed, whereby the conductor over the conductor 260 functioning as a gate electrode can be removed; thus, parasitic capacitance or the like can be reduced.

The conductor 120 is preferably provided to cover the top and side surfaces of the region 231 of the oxide 230 with the insulator 130 therebetween. With this structure, the side surface of the region 231 of the oxide 230 faces the conductor 120 with the insulator 130 provided therebetween. Accordingly, in the capacitor 100, a capacitor having large capacitance per projected area can be formed because the sum of the area of the top and side surfaces of the region 231 of the oxide 230 functions as a capacitor.

Then, the insulator 286 is formed (see FIGS. 19A to 19C). An insulator to be the insulator 150 can be formed using a material and a method similar to those used for forming the insulator 280 and the like.

Then, an opening reaching the region 231 of the oxide 230, the conductor 260, and the conductor 120 is formed in the insulators 286, 280, 274, 271, and 270. The opening may be formed by a lithography method.

Note that in order that the conductors 252a and 252b are provided in contact with a side surface of the oxide 230, the openings are formed to reach the oxide 230 such that the side surface of the oxide 230 is exposed.

Next, a conductive film to be the conductor 252 is formed. The conductive film can be formed by a sputtering method, a CVD method, an MBE method, a PLD method, an ALD method, or the like.

Then, the conductive film to be the conductor 252 is partly removed by CMP treatment to expose the insulator 280. As a result, the conductive film remains only in the openings, so that the conductor 252 having a flat top surface can be formed (see FIGS. 20A to 20C).

Through the above process, the semiconductor device including the transistor 200 can be manufactured. As illustrated in FIGS. 7A to 7C to FIGS. 20A to 20C, the method for manufacturing a semiconductor device in this embodiment allows fabrication of the transistor 200.

According to one embodiment of the present invention, a semiconductor device that can be miniaturized or highly integrated can be provided. Alternatively, according to one embodiment of the present invention, a semiconductor device having favorable electrical characteristics can be provided. Alternatively, according to one embodiment of the present invention, a semiconductor device with low off-state current can be provided. Alternatively, according to one embodiment of the present invention, a transistor with high on-state current can be provided. Alternatively, according to one embodiment of the present invention, a highly reliable semiconductor device can be provided. Alternatively, according to one embodiment of the present invention, a semiconductor device with low power consumption can be provided. Alternatively, according to one embodiment of the present invention, a semiconductor device that can be manufactured with high producibility can be provided.

As described above, the structures, methods, and the like described in this embodiment can be combined as appropriate with any of the structures, methods, and the like described in the other embodiments.

### Embodiment 2

An example of a semiconductor device including the transistor 200 of one embodiment of the present invention is described below.

Note that in the semiconductor device described in this embodiment, components having the same functions as the components in the semiconductor device described in the above embodiment are denoted by the same reference numerals.

A structure of the cell 600 is described below. Note that in this section, the materials described in detail in the above embodiment can be used as materials of the cell 600.

### Structure Example 4 of Semiconductor Device

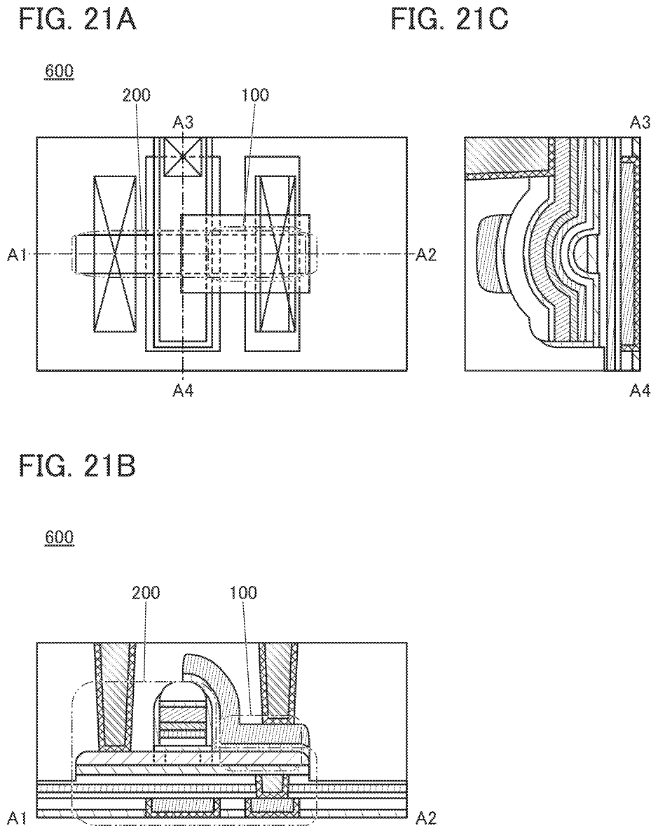

FIGS. 21A to 21C are a top view and cross-sectional views illustrating the transistor 200 and a capacitor 100 and the periphery of the transistor 200 of one embodiment of the present invention. Note that in this specification, a semiconductor device including one capacitor and at least one transistor is referred to as a cell.

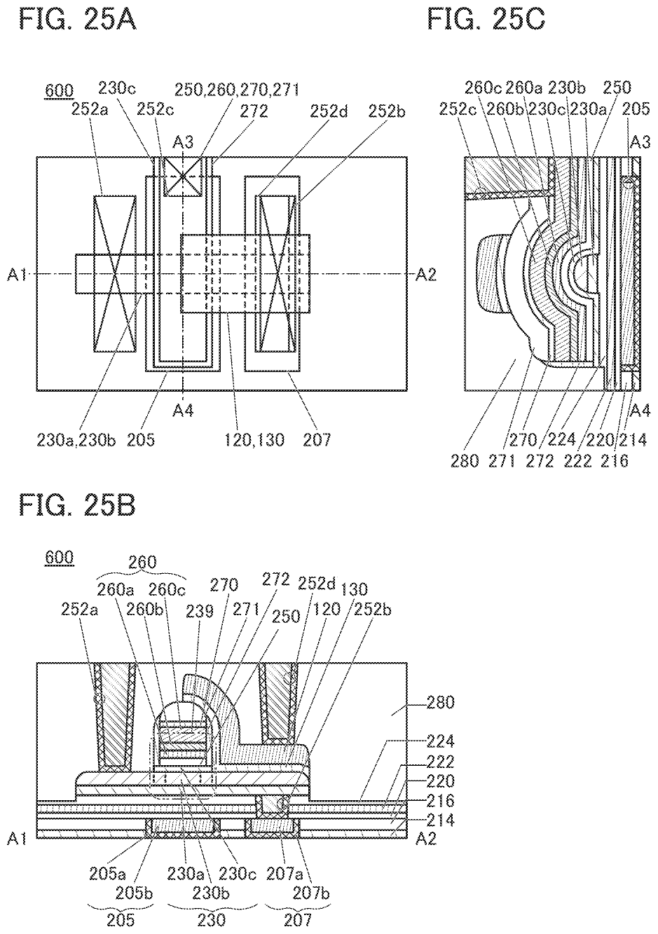

FIG. 21A is a top view of the cell 600 including the transistor 200 and a capacitor 100. FIGS. 21B and 21C are a cross-sectional view illustrating the cell 600. FIG. 21B is a cross-sectional view taken along dashed-dotted line A1-A2 in FIG. 21A, which corresponds to a cross-sectional view in the channel length direction of the transistor 200. FIG. 21C is a cross-sectional view taken along dashed-dotted line A3-A4 in FIG. 21A, which corresponds to a cross-sectional view in the channel width direction of the transistor 200. For simplification of the drawing, some components are not illustrated in the top view in FIG. 21A. Note that for simplification of the drawing, only some components are denoted by reference numerals in FIGS. 21A to 21C. Furthermore, the components of the cell 600 illustrated in FIGS. 21A to 21C are denoted by reference numerals in FIGS. 25A to 25C and detailed description thereof is described below.

The transistor 200 and the capacitor 100 are provided on the same layer, whereby part of components in the transistor 200 and part of components in the capacitor 100 can be used in common in the cell 600 of FIGS. 21A to 21C. That is, part of the components of the transistor 200 may function as part of the components of the capacitor 100.

Furthermore, part of the capacitor 100 or the entire capacitor 100 overlaps with the transistor 200, so that the total area of the projected area of the transistor 200 and the projected area of the capacitor 100 can be reduced.

Furthermore, a wiring or a plug which is electrically connected to the transistor 200 is provided below the region where the capacitor 100 and the transistor 200 overlap with each other, so that the cell 600 can be easily miniaturized or highly integrated.

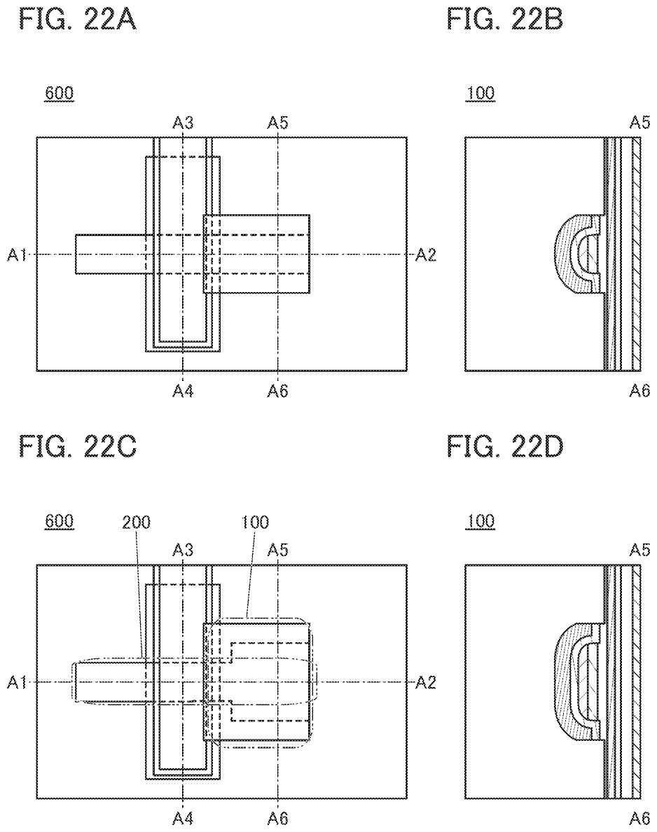

The layout of the transistor 200 and the capacitor 100 can be designed as appropriate depending on the required capacitance of the capacitor 100. For example, FIGS. 22A to 22D are top views and cross-sectional views illustrating the cell 600. FIG. 22B is a cross-sectional view taken along dashed-dotted line A5-A6 of the top view in FIG. 22A. FIG. 22D is a cross-sectional view taken along dashed-dotted line A5-A6 of the top view in FIG. 22C. Note that in FIGS. 22A to 22D, some components such as the conductor 252 functioning as the plug that is connected to the capacitor 100 or the transistor 200 are omitted and not illustrated for description of the capacitor 100.

As illustrated in FIGS. 22A to 22D, the area of the capacitor 100 is determined by widths of the oxides 230a and 230b in the A5-A6 direction and a width of the conductor 120 in the A1-A2 direction. Thus, in the case where the required capacitance for the cell 600 cannot be obtained by the capacitor 100 in FIGS. 22A and 22B, the width of the oxides 230a and 230b in the A5-A6 direction are increased as in FIGS. 22C and 22D, so that the capacitance can be increased.

With this structure, miniaturization or high integration of the semiconductor device can be achieved. Moreover, the design flexibility of the semiconductor device can be increased. Furthermore, the transistor 200 and the capacitor 100 can be formed through the same process. Accordingly, the process can be shortened, leading to an improvement in productivity.

### <Structure of Cell Array>

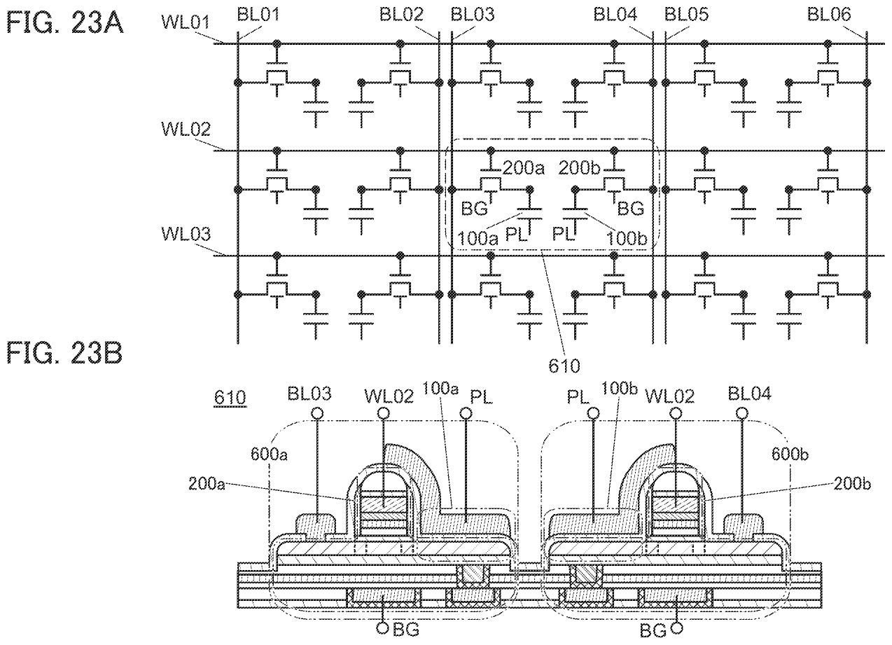

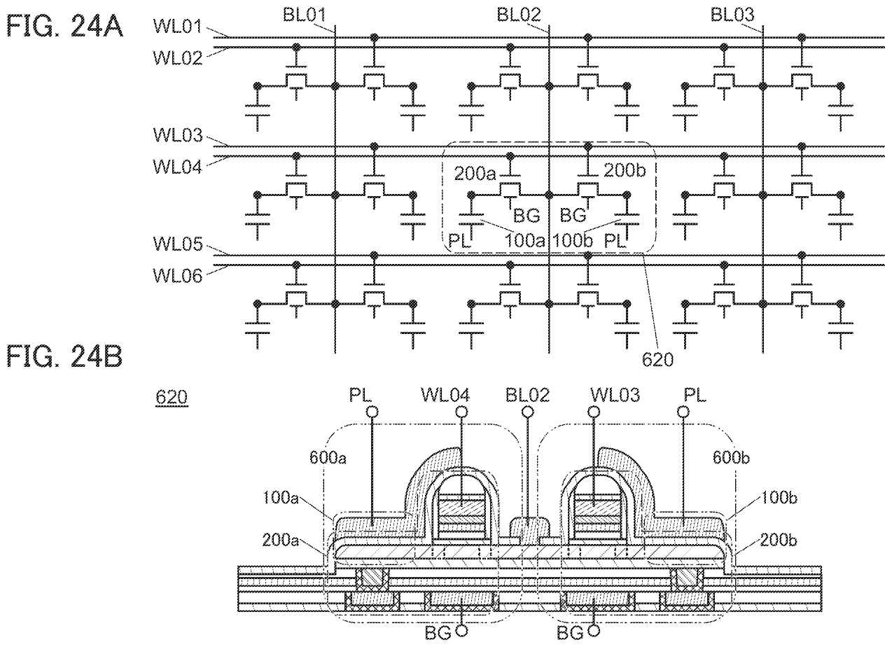

FIGS. 23A and 23B and FIGS. 24A and 24B illustrate examples of cell arrays of this embodiment. For example, the cells 600 each including the transistor 200 and the capacitor 100 illustrated in FIGS. 21A to 21C are arranged in a matrix, whereby a cell array can be formed.

FIG. 23A is a circuit diagram showing an embodiment in which the cells 600 in FIGS. 21A to 21C are arranged in a matrix. In FIG. 23A, first gates of transistors included in the cells 600 arranged in a row direction are electrically connected to common WLs (WL01, WL02, and WL03). Furthermore, one of a source and a drain of each of the transistors included in the cells 600 arranged in a column direction are electrically connected to common BLs (BL01 to BL06). In addition, the transistors included in the cells 600 may each be provided with a second gate BG. The threshold voltage of the transistor can be controlled by a potential applied to the BG. The first electrode of the capacitor included in the cell 600 is electrically connected to the other of the source and the drain of the transistor. At this time, the first electrode of the capacitor is formed using part of components of the transistor. In addition, the second electrode of the capacitor included in the cell 600 is electrically connected to a PL.

FIG. 23B is a cross-sectional view which illustrates part of a row including a circuit 610 including a cell 600a electrically connected to the WL02 and the BL03 and a cell 600b electrically connected to the WL02 and the BL04 in FIG. 23A. FIG. 23B illustrates a cross-sectional view of the cell 600a and the cell 600b.

The cell 600a includes a transistor 200a and a capacitor 100a. The cell 600b includes a transistor 200b and a capacitor 100b.

FIG. 24A is a circuit diagram showing an embodiment, which is different from that in FIG. 23A, in which the cells 600 in FIGS. 21A to 21C are arranged in a matrix. In FIG. 24A, one of the source and the drain of each of the transistors included in the cells 600 which are adjacent in the row direction are electrically connected to common BLs (BL01, BL02, and BL03). Furthermore, the BLs are also electrically connected to one of the source and the drain of each of the transistors included in the cells 600 arranged in the column direction. In contrast, the first gates of transistors included in the cells 600 which are adjacent in the row direction are electrically connected to different WLs (WL01 to WL06). In addition, the transistors included in the cells 600 may each be provided with a second gate BG. The threshold voltage of the transistor can be controlled by a potential applied to the BG. The first electrode of the capacitor included in the cell 600 is electrically connected to the other of the source and the drain of the transistor. At this time, the first electrode of the capacitor is formed using part of components of the transistor. In addition, the second electrode of the capacitor included in the cell 600 is electrically connected to a PL.

FIG. 24B is a cross-sectional view which illustrates part of a row including a circuit 620 including a cell 600a electrically connected to a WL04 and the BL02 and a cell 600b electrically connected to the WL03 and the BL02 in FIG. 24A. FIG. 24B illustrates a cross-sectional view of the cell 600a and the cell 600b.

The cell 600a includes a transistor 200a and a capacitor 100a. The cell 600b includes a transistor 200b and a capacitor 100b.

One of a source and a drain of the transistor 200a and one of a source and a drain of the transistor 200b are both electrically connected to the BL02.

In the above-described structure, line sharing of a wiring which is electrically connected to one of a source and a drain is possible; thus, the area occupied by the cell array can be further reduced.

### [Cell 600]

The semiconductor device of one embodiment of the present invention includes the transistor 200, the capacitor 100, and the insulator 280 functioning as an interlayer film. Furthermore, a conductor 252 (a conductor 252a, a conductor 252b, a conductor 252c, and a conductor 252d) functioning as a plug that is electrically connected to the transistor 200 is included.

The conductors 252 are in contact with inner walls of an opening in the insulator 280. Here, the top surface of the conductor 252 can be substantially level with the top surface of the insulator 280. Note that although the conductors 252 in the transistor 200 each have a two-layer structure, one embodiment of the present invention is not limited thereto. For example, the conductors 252 may have a single-layer structure or a stacked-layer structure of three or more layers.

The dielectric constant of each of the insulators 216 and 280 functioning as interlayer films is preferably lower than that of the insulator 214. In the case where a material with a low dielectric constant is used as an interlayer film, the parasitic capacitance between wirings can be reduced.

For example, the insulators 216 and 280 serving as interlayer films can have a single-layer structure or a stacked-layer structure using any of insulators such as silicon oxide, silicon oxynitride, silicon nitride oxide, aluminum oxide, hafnium oxide, tantalum oxide, zirconium oxide, lead zirconate titanate (PZT), strontium titanate (SrTiO₃), and (Ba,Sr)TiO₃ (BST). Aluminum oxide, bismuth oxide, germanium oxide, niobium oxide, silicon oxide, titanium oxide, tungsten oxide, yttrium oxide, or zirconium oxide may be added to the insulator, for example. The insulator may be subjected to nitriding treatment. A layer of silicon oxide, silicon oxynitride, or silicon nitride may be stacked over the insulator.

The insulator 270 functioning as the barrier film may be provided over the conductor 260c. Here, the insulator 270 is preferably formed using an insulating material that has a function of inhibiting the penetration of oxygen and impurities such as water and hydrogen. For example, an insulator including an oxide containing one of or both aluminum and hafnium can be used. Aluminum oxide, hafnium oxide, oxide containing aluminum and hafnium (hafnium aluminate), or the like may be used for the insulator including oxide with one of or both aluminum and hafnium. Accordingly, oxidation of the conductor 260 can be prevented. In addition, impurities such as water or hydrogen can be prevented from entering the oxide 230 through the conductor 260 and the insulator 250.

Here, the insulator 272 is preferably formed using an insulating material that has a function of inhibiting the penetration of oxygen and impurities such as water and hydrogen. For example, an insulator including an oxide containing one of or both aluminum and hafnium can be used. Aluminum oxide, hafnium oxide, oxide containing aluminum and hafnium (hafnium aluminate), or the like may be used for an insulator including oxide with one of or both aluminum and hafnium. Accordingly, oxygen contained in the insulator 250 can be prevented from diffusing outward. In addition, impurities such as hydrogen and water can be prevented from entering the oxide 230 through the end portion of the insulator 250 or the like.

The insulator 280 functioning as the interlayer film is preferably provided over the insulator 274. Like the insulator 224 or the like, the concentration of impurities such as water or hydrogen in the insulator 280 is preferably lowered. Note that the insulator 280 may have a stacked-layer structure of such insulators.

Furthermore, the conductors 252a, 252c, and 252d are provided in the opening formed in the insulators 280, 274, 271, and 270. Note that top surfaces of the conductors 252a, 252c, and 252d may be at the same level as the top surface of the insulator 280.

The conductor 252b which is electrically connected to the region 231b of the transistor 200 may be in contact with the bottom portion of the oxide 230a. With this structure, the conductor 252b, the conductor 207 (the conductor 207a and the conductor 207b), the transistor 200, and the capacitor 100 can be provided to overlap with one another. Furthermore, in the case where the transistor 200 is electrically connected to the another structure body provided below the cell 600, a lead wiring above the cell 600, which is electrically connected to the conductor 252b, the plug which electrically connects the lead wiring to the structure body provided below the cell 600, or the like is unnecessary; thus, the process can be shortened. Note that the conductor 207 can be formed in the same step as the conductor 205.

An insulator which has a function of inhibiting the passage of impurities such as water and hydrogen may be provided in contact with the inner wall of the opening in the insulators 274 and 280 in which the conductor 252 is embedded. As for such an insulator, an insulator which can be used for the insulator 214, such as aluminum oxide is preferably used. Accordingly, the insulator prevents impurities such as hydrogen and water from entering the oxide 230 through the conductor 252 from the insulator 280. The insulator can be formed with good coverage by using an ALD method, a CVD method, or the like.

Furthermore, the conductor 252d is in contact with the conductor 120 functioning as one electrode of the capacitor 100. The conductor 252d can be formed at the same time as the conductors 252a, 252b, and 252c; thus, the manufacturing process can be shortened.

### Structure Example 5 of Semiconductor Device

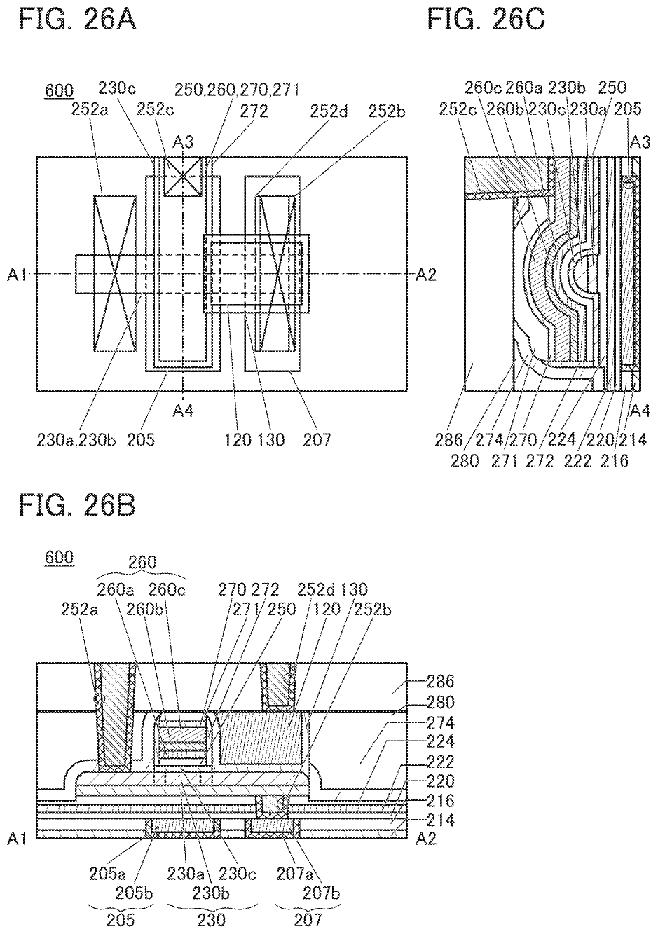

An example of the semiconductor device including the cell 600 of one embodiment of the present invention is described below with reference to FIGS. 26A to 26C.

FIG. 26A is a top view of the cell 600. Furthermore, FIGS. 26B and 26C are cross-sectional views of the cell 600. FIG. 26B is a cross-sectional view taken along dashed-dotted line A1-A2 in FIG. 26A, which corresponds to a cross-sectional view in the channel length direction of the transistor 200. FIG. 26C is a cross-sectional view taken along dashed-dotted line A3-A4 in FIG. 26A, which corresponds to a cross-sectional view in the channel width direction of the transistor 200. For simplification of the drawing, some components are not illustrated in the top view in FIG. 26A.

Note that in the semiconductor device illustrated in FIGS. 26A to 26C, components having the same functions as the components in the semiconductor device described in <Structure example 4 of semiconductor device> are denoted by the same reference numerals.

A structure of the cell 600 is described with reference to FIGS. 26A to 26C below. Note that as materials of the cell 600 in this section, the materials described in <Structure example 1 of semiconductor device> can be used.

### [Cell 600]

As illustrated in FIGS. 26A to 26C, the cell 600 differs from the semiconductor device described in <Structure example 1 of semiconductor device> at least in the shape of the capacitor 100.

The capacitor 100 includes the region 231b of the oxide 230, an insulator 130 over the region 231, and the conductor 120 over the insulator 130. Moreover, the conductor 120 is preferably provided over the insulator 130 to at least partly overlap with the region 231b of the oxide 230.

The region 231b of the oxide 230 functions as one electrode of the capacitor 100, and the conductor 120 functions as the other electrode of the capacitor 100. The insulator 130 functions as a dielectric of the capacitor 100. The resistance of the region 231b of the oxide 230 is reduced, and is a conductive oxide. Thus, the region 231b of the oxide 230 can function as one electrode of the capacitor 100.

The insulators 280 and 274 have an opening in the region overlapping with the region 231b of the oxide 230. In a bottom portion of the opening, the region 231b of the oxide 230 is exposed. The insulator 130 is provided in contact with the side surface of the opening and the region 231b of the oxide 230. The conductor 120 is preferably provided to be embedded in the opening with the insulator 130 provided therebetween.

Moreover, the insulator 286 is provided over the insulator 280 and the conductor 120. The conductors 252a, 252c, and 252d are formed to be embedded in the opening provided in the insulators 286, 280, and 274. Therefore, the top surfaces of the conductors 252a, 252c, and 252b and the top surface of the insulator 286 are arranged at the same level.

With the above structure, coverage of the structure formed in the stack is improved by stacking of flat layers. Thus, high integration is easily possible.

As described above, the structures, methods, and the like described in this embodiment can be combined with any of the structures, methods, and the like described in the other embodiments as appropriate.

### Embodiment 3

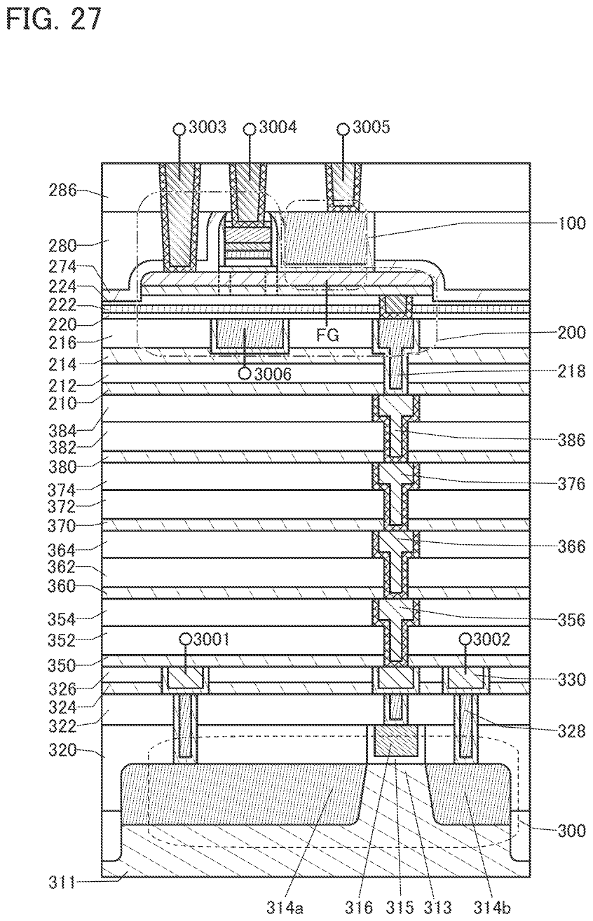

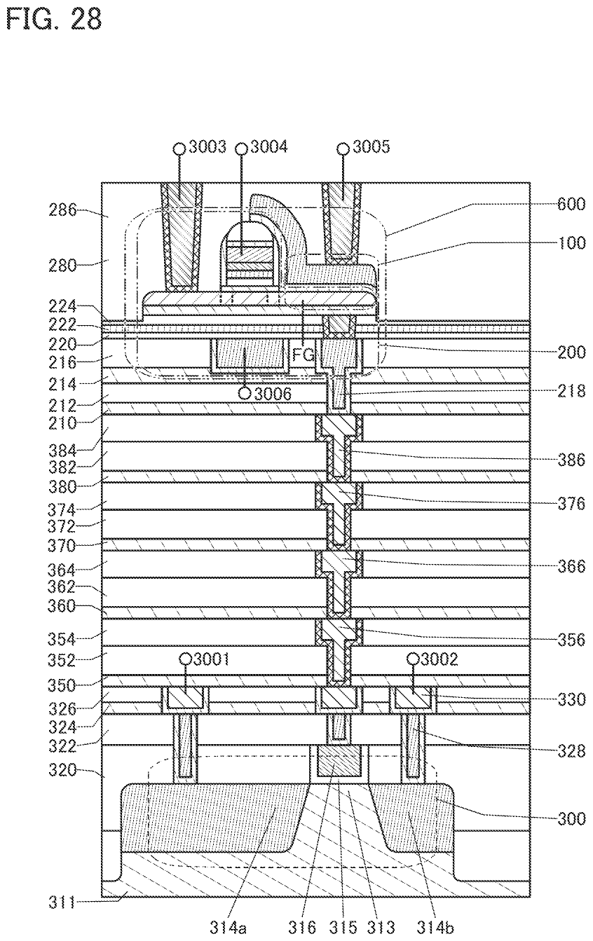

In this embodiment, one embodiment of a semiconductor device will be described with reference to FIG. 27 and FIG. 28.

### [Memory Device 1]

A memory device illustrated in FIG. 27 and FIG. 28 includes a transistor 300 and the cell 600 including the transistor 200 and the capacitor 100.

The transistor 200 is a transistor whose channel is formed in a semiconductor layer containing an oxide semiconductor. Since the off-state current of the transistor 200 is low, a memory device including the transistor 200 can retain stored data for a long time. In other words, such a memory device does not require refresh operation or has an extremely low frequency of the refresh operation, which leads to a sufficient reduction in power consumption of the memory device.

The transistor 200 and the capacitor 100 in the cell 600 have some components in common and thus have a small projected area, which enables miniaturization and high integration.

In FIG. 27 and FIG. 28, a wiring 3001 is electrically connected to a source of the transistor 300. A wiring 3002 is electrically connected to a drain of the transistor 300. A wiring 3003 is electrically connected to one of the source and the drain of the transistor 200. A wiring 3004 is electrically connected to the first gate of the transistor 200. A wiring 3006 is electrically connected to the second gate of the transistor 200. A gate of the transistor 300 and the other of the source and the drain of the transistor 200 are electrically connected to one electrode of the capacitor 100. A wiring 3005 is electrically connected to the other electrode of the capacitor 100.

The semiconductor device illustrated in FIG. 27 and FIG. 28 has a feature that the potential of the gate of the transistor 300 can be retained and thus enables writing, retaining, and reading of data as follows.

Writing and retaining of data are described. First, the potential of the wiring 3004 is set to a potential at which the transistor 200 is turned on, so that the transistor 200 is turned on. Accordingly, the potential of the wiring 3003 is supplied to a node FG where the gate of the transistor 300 and one electrode of the capacitor 100 are electrically connected to each other. That is, a predetermined charge is supplied to the gate of the transistor 300 (writing). Here, one of two kinds of charges providing different potential levels (hereinafter referred to as a low-level charge and a high-level charge) is supplied. After that, the potential of the wiring 3004 is set to a potential at which the transistor 200 is turned off, so that the transistor 200 is turned off. Thus, the charge is retained in the node FG (retaining).

In the case where the off-state current of the transistor 200 is low, the charge of the node FG is retained for a long time.

Next, reading of data is described. An appropriate potential (reading potential) is supplied to the wiring 3005 while a predetermined potential (constant potential) is supplied to the wiring 3001, whereby the potential of the wiring 3002 varies depending on the amount of charge retained in the node FG. This is because in the case of using an n-channel transistor as the transistor 300, an apparent threshold voltage V_{th_H} at the time when a high-level charge is given to the gate of the transistor 300 is lower than an apparent threshold voltage V_{th_L} at the time when a low-level charge is given to the gate of the transistor 300. Here, an apparent threshold voltage refers to the potential of the wiring 3005 which is needed to turn on the transistor 300. Thus, the potential of the wiring 3005 is set to a potential V₀ which is between V_{th_H} and V_{th_L}, whereby the charge supplied to the node FG can be determined. For example, in the case where a high-level charge is supplied to the node FG in writing and the potential of the wiring 3005 is V₀ (>V_{th_H}), the transistor 300 is turned on. Meanwhile, in the case where a low-level charge is supplied to the node FG in writing, the transistor 300 remains off even when the potential of the wiring 3005 is V₀ (<V_{th_L}). Thus, the data retained in the node FG can be read by determining the potential of the wiring 3002.

### <Structure of Memory Device 1>

The semiconductor device of one embodiment of the present invention includes the transistor 300, the transistor 200, and the capacitor 100 as illustrated in FIG. 27 and FIG. 28. The transistor 200 is provided above the transistor 300, and the capacitor 100 is provided above the transistor 300 and the transistor 200.

The transistor 300 is provided in and on a substrate 311 and includes a conductor 316, an insulator 315, a semiconductor region 313 that is a part of the substrate 311, and a low-resistance region 314a and a low-resistance region 314b functioning as a source region and a drain region.

The transistor 300 is either a p-channel transistor or an n-channel transistor.

It is preferable that a region of the semiconductor region 313 where a channel is formed, a region in the vicinity thereof, the low-resistance regions 314a and 314b functioning as the source and drain regions, and the like contain a semiconductor such as a silicon-based semiconductor, further preferably single crystal silicon. Alternatively, a material including germanium (Ge), silicon germanium (SiGe), gallium arsenide (GaAs), gallium aluminum arsenide (GaAlAs), or the like may be contained. Silicon whose effective mass is adjusted by applying stress to the crystal lattice and thereby changing the lattice spacing may be contained. Alternatively, the transistor 300 may be a high-electron-mobility transistor (HEMT) with GaAs and GaAlAs, or the like.

The low-resistance regions 314a and 314b contain an element which imparts n-type conductivity, such as arsenic or phosphorus, or an element which imparts p-type conductivity, such as boron, in addition to the semiconductor material used for the semiconductor region 313.

The conductor 316 functioning as a gate electrode can be formed using a semiconductor material such as silicon containing the element which imparts n-type conductivity, such as arsenic or phosphorus, or the element which imparts p-type conductivity, such as boron, or using a conductive material such as a metal material, an alloy material, or a metal oxide material.

Note that the work function of a conductor is determined by a material of the conductor, whereby the threshold voltage can be adjusted. Specifically, it is preferable to use titanium nitride, tantalum nitride, or the like for the conductor. Furthermore, in order to ensure the conductivity and embeddability, it is preferable to use a stacked layer of metal materials such as tungsten and aluminum for the conductor. It is particularly preferable to use tungsten in terms of heat resistance.

Note that the transistor 300 illustrated in FIG. 27 and FIG. 28 is only an example and the structure of the transistor 300 is not limited to that illustrated in FIG. 27 and FIG. 28; a transistor appropriate for a circuit configuration or a driving method can be used.

An insulator 320, an insulator 322, an insulator 324, and an insulator 326 are stacked sequentially to cover the transistor 300.

The insulator 320, the insulator 322, the insulator 324, and the insulator 326 can be formed using, for example, silicon oxide, silicon oxynitride, silicon nitride oxide, silicon nitride, aluminum oxide, aluminum oxynitride, aluminum nitride oxide, or aluminum nitride.

The insulator 322 may function as a planarization film for eliminating a level difference caused by the transistor 300 or the like underlying the insulator 322. For example, the top surface of the insulator 322 may be planarized by planarization treatment using a chemical mechanical polishing (CMP) method or the like to increase the level of planarity.

The insulator 324 is preferably formed using a film having a barrier property that prevents hydrogen or impurities from the substrate 311, the transistor 300, or the like from diffusing to a region where the transistor 200 is provided.

For the film having a barrier property against hydrogen, silicon nitride formed by a CVD method can be used, for example. The diffusion of hydrogen to a semiconductor element including an oxide semiconductor, such as the transistor 200, degrades the characteristics of the semiconductor element in some cases. Therefore, a film that prevents hydrogen diffusion is preferably provided between the transistor 200 and the transistor 300. The film that prevents hydrogen diffusion is specifically a film from which a small amount of hydrogen is released.

The amount of released hydrogen can be measured by thermal desorption spectroscopy (TDS), for example. The amount of hydrogen released from the insulator 324 that is converted into hydrogen atoms per unit area of the insulator 324 is less than or equal to 10×10¹⁵ atoms/cm², preferably less than or equal to 5×10¹⁵ atoms/cm², in the TDS analysis in the range from 50° C. to 500° C., for example.

Note that the permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 or less times that of the insulator 324, further preferably 0.6 or less times that of the insulator 324. In the case where a material with a low permittivity is used for an interlayer film, the parasitic capacitance between wirings can be reduced.

A conductor 328, a conductor 330, and the like that are electrically connected to the capacitor 100 or the transistor 200 are provided in the insulator 320, the insulator 322, the insulator 324, and the insulator 326. Note that the conductor 328 and the conductor 330 each function as a plug or a wiring. A plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor serves as a wiring and another part of the conductor serves as a plug.

As a material for each of plugs and wirings (e.g., the conductor 328 and the conductor 330), a conductive material such as a metal material, an alloy material, a metal nitride material, or a metal oxide material can be used in a single-layer structure or a stacked-layer structure. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, in FIG. 27 and FIG. 28, an insulator 350, an insulator 352, and an insulator 354 are stacked sequentially. Furthermore, a conductor 356 is formed in the insulator 350, the insulator 352, and the insulator 354. The conductor 356 functions as a plug or a wiring. Note that the conductor 356 can be formed using a material similar to those for the conductor 328 and the conductor 330.

Note that the insulator 350 is preferably formed using an insulator having a barrier property against hydrogen, as with the insulator 324, for example. Furthermore, the conductor 356 preferably contains a conductor having a barrier property against hydrogen. In particular, the conductor having a barrier property against hydrogen is formed in an opening of the insulator 350 having a barrier property against hydrogen. In such a structure, the transistor 300 and the transistor 200 can be separated by a barrier layer, so that the diffusion of hydrogen from the transistor 300 to the transistor 200 can be prevented.

Note that as the conductor having a barrier property against hydrogen, tantalum nitride is preferably used, for example. The use of a stack including tantalum nitride and tungsten having high conductivity can inhibit the diffusion of hydrogen from the transistor 300 while the conductivity of a wiring is ensured. In that case, the tantalum nitride layer having a barrier property against hydrogen is preferably in contact with the insulator 350 having a barrier property against hydrogen.

A wiring layer may be provided over the insulator 354 and the conductor 356. For example, in FIG. 27 and FIG. 28, an insulator 360, an insulator 362, and an insulator 364 are stacked sequentially. Furthermore, a conductor 366 is formed in the insulator 360, the insulator 362, and the insulator 364. The conductor 366 functions as a plug or a wiring. Note that the conductor 366 can be formed using a material similar to those for the conductor 328 and the conductor 330.

Note that the insulator 360 is preferably formed using an insulator having a barrier property against hydrogen, as with the insulator 324, for example. Furthermore, the conductor 366 preferably contains a conductor having a barrier property against hydrogen. In particular, the conductor having a barrier property against hydrogen is formed in an opening of the insulator 360 having a barrier property against hydrogen. In such a structure, the transistor 300 and the transistor 200 can be separated by a barrier layer, so that the diffusion of hydrogen from the transistor 300 to the transistor 200 can be prevented.

A wiring layer may be provided over the insulator 364 and the conductor 366. For example, in FIG. 27 and FIG. 28, an insulator 370, an insulator 372, and an insulator 374 are stacked sequentially. Furthermore, a conductor 376 is formed in the insulator 370, the insulator 372, and the insulator 374. The conductor 376 functions as a plug or a wiring. Note that the conductor 376 can be formed using a material similar to those for the conductor 328 and the conductor 330.

Note that the insulator 370 is preferably formed using an insulator having a barrier property against hydrogen, as with the insulator 324, for example. Furthermore, the conductor 376 preferably contains a conductor having a barrier property against hydrogen. In particular, the conductor having a barrier property against hydrogen is formed in an opening of the insulator 370 having a barrier property against hydrogen. In such a structure, the transistor 300 and the transistor 200 can be separated by a barrier layer, so that the diffusion of hydrogen from the transistor 300 to the transistor 200 can be prevented.

A wiring layer may be provided over the insulator 374 and the conductor 376. For example, in FIG. 27 and FIG. 28, an insulator 380, an insulator 382, and an insulator 384 are stacked sequentially. Furthermore, a conductor 386 is formed in the insulator 380, the insulator 382, and the insulator 384. The conductor 386 functions as a plug or a wiring. Note that the conductor 386 can be formed using a material similar to those for the conductor 328 and the conductor 330.

Note that the insulator 380 is preferably formed using an insulator having a barrier property against hydrogen, as with the insulator 324, for example. Furthermore, the conductor 386 preferably contains a conductor having a barrier property against hydrogen. In particular, the conductor having a barrier property against hydrogen is formed in an opening of the insulator 380 having a barrier property against hydrogen. In such a structure, the transistor 300 and the transistor 200 can be separated by a barrier layer, so that the diffusion of hydrogen from the transistor 300 to the transistor 200 can be prevented.

An insulator 210 and an insulator 212 are stacked sequentially over the insulator 384. A material having a barrier property against oxygen or hydrogen is preferably used for either of the insulators 210 and 212.

For example, the insulator 210 is preferably formed using a film having a barrier property that prevents hydrogen or impurities from the substrate 311, a region where the transistor 300 is provided, or the like from diffusing to a region where the cell 600 is provided. Therefore, the insulator 210 can be formed using a material similar to that for the insulator 324.

For the film having a barrier property against hydrogen, silicon nitride formed by a CVD method can be used, for example. The diffusion of hydrogen to a semiconductor element including an oxide semiconductor, such as the cell 600, degrades the characteristics of the semiconductor element in some cases. Therefore, a film that prevents hydrogen diffusion is preferably provided between the cell 600 and the transistor 300. The film that prevents hydrogen diffusion is specifically a film from which a small amount of hydrogen is released.

For the film having a barrier property against hydrogen used for the insulator 210, for example, a metal oxide such as aluminum oxide, hafnium oxide, or tantalum oxide is preferably used.

In particular, aluminum oxide has an excellent blocking effect that prevents permeation of oxygen and impurities such as hydrogen and moisture which cause a change in electrical characteristics of the transistor. Accordingly, the use of aluminum oxide can prevent the entry of impurities such as hydrogen and moisture into the cell 600 during and after a manufacturing process of the transistor. In addition, release of oxygen from the oxide contained in the cell 600 can be prevented. Therefore, aluminum oxide is suitably used for a protective film of the cell 600.

The insulator 212 can be formed using a material similar to that for the insulator 320, for example. In the case where a material with a relatively low permittivity is used for an interlayer film, the parasitic capacitance between wirings can be reduced. A silicon oxide film or a silicon oxynitride film can be used for the insulator 212, for example.

A conductor 218, a conductor (the conductor 205) included in the transistor 200, and the like are provided in the insulators 210, 212, 214, and 216. Note that the conductor 218 functions as a plug or a wiring that is electrically connected to the cell 600 or the transistor 300. The conductor 218 can be formed using a material similar to those for the conductors 328 and 330.

In particular, part of the conductor 218 that is in contact with the insulators 210 and 214 is preferably a conductor having a barrier property against oxygen, hydrogen, and water. In such a structure, the transistors 300 and 200 can be separated by a layer having a barrier property against oxygen, hydrogen, and water. As a result, the diffusion of hydrogen from the transistor 300 to the cell 600 can be prevented.

The cell 600 is provided over the insulator 212. Note that the structure of the cell 600 described in the above embodiment can be used as the structure of the cell 600 described here. Note that the cell 600 in FIG. 27 and FIG. 28 is only an example and the structure of the cell 600 is not limited to that illustrated in FIG. 27 and FIG. 28; a transistor appropriate for a circuit configuration or a driving method can be used.

The above is the description of the structure example. With the use of the structure, a change in electrical characteristics of a semiconductor device including a transistor containing an oxide semiconductor can be prevented and reliability can be improved. A transistor containing an oxide semiconductor with a high on-state current can be provided. A transistor containing an oxide semiconductor with a low off-state current can be provided. A semiconductor device with low power consumption can be provided.

The structures, the methods, and the like described in this embodiment can be combined as appropriate with any of the structures, the methods, and the like described in the other embodiments.

### Embodiment 4

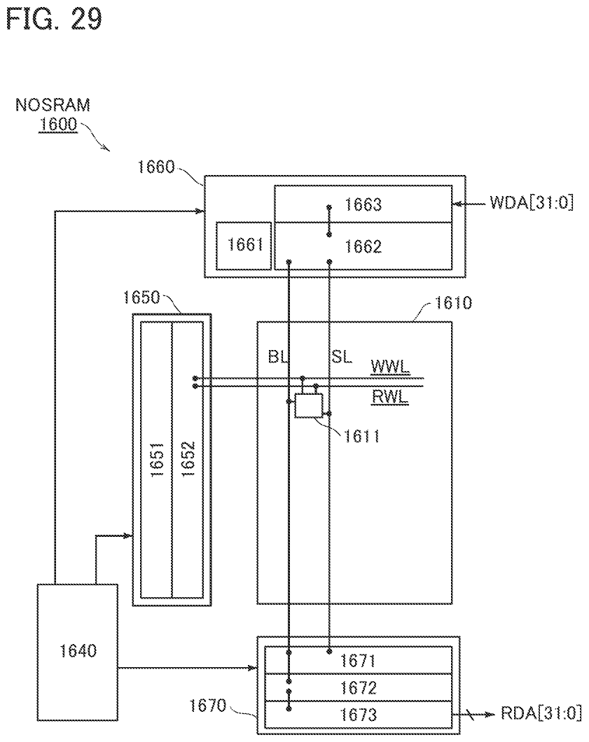

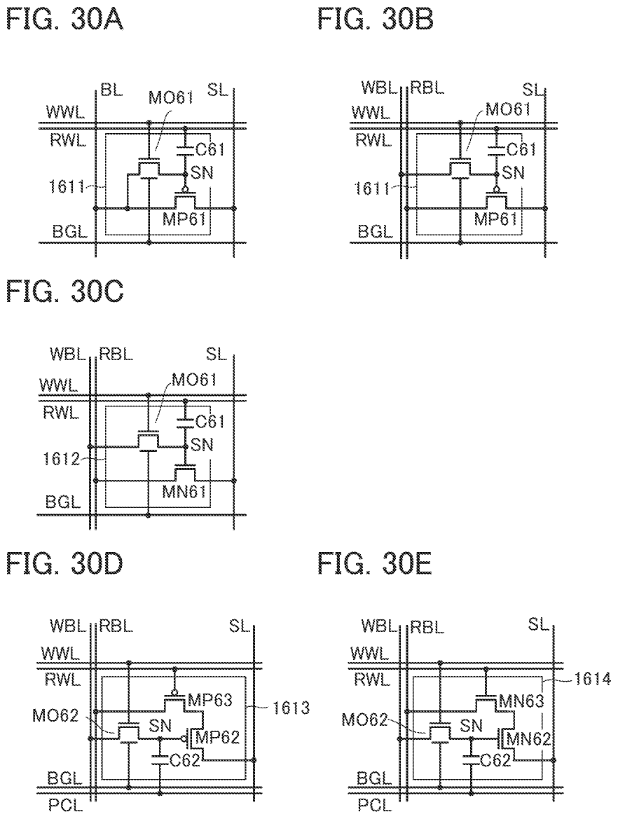

In this embodiment, NOSRAM is described as an example of a memory device including a transistor in which oxide is used for a semiconductor (hereinafter referred to as an OS transistor) and a capacitor, which is one embodiment of the present invention, with reference to FIG. 29 and FIGS. 30A to 30E. NOSRAM (registered trademark) is an abbreviation of “nonvolatile oxide semiconductor RAM”, which indicates RAM including a gain cell (2T or 3T) memory cell. Hereinafter, a memory device including an OS transistor, such as NOSRAM, is referred to as an OS memory in some cases.

A memory device in which OS transistors are used in memory cells (hereinafter referred to as an OS memory) is used in NOSRAM. The OS memory is a memory including at least a capacitor and an OS transistor that controls charge and discharge of the capacitor. The OS memory has excellent retention characteristics because the OS transistor has an extremely low off-state current and thus can function as a nonvolatile memory.

### <<NOSRAM>>

FIG. 29 shows a configuration example of NOSRAM. NOSRAM 1600 in FIG. 29 includes a memory cell array 1610, a controller 1640, a row driver 1650, a column driver 1660, and an output driver 1670. Note that the NOSRAM 1600 is multilevel NOSRAM in which one memory cell stores multilevel data.

The memory cell array 1610 includes a plurality of memory cells 1611, a plurality of word lines WWL, a plurality of word lines RWL, a plurality of bit lines BL, and a plurality of source lines SL. The word lines WWL are write word lines and the word lines RWL are read word lines. In the NOSRAM 1600, one memory cell 1611 stores 3-bit (8-level) data.

The controller 1640 controls the NOSRAM 1600 as a whole and writes data WDA[31:0] and reads out data RDA[31:0]. The controller 1640 processes command signals input from the outside (e.g., a chip enable signal and a write enable signal) to generate control signals of the row driver 1650, the column driver 1660, and the output driver 1670.

The row driver 1650 has a function of selecting a row to be accessed. The row driver 1650 includes a row decoder 1651 and a word line driver 1652.

The column driver 1660 drives a source line SL and a bit line BL. The column driver 1660 includes a column decoder 1661, a write driver 1662, and a digital-analog converter circuit (DAC) 1663.

The DAC 1663 converts 3-bit digital data into an analog voltage. The DAC 1663 converts 32-bit data WDA[31:0] into an analog voltage per 3 bits.

The write driver 1662 has a function of precharging the source line SL, a function of bringing the source line SL into an electrically floating state, a function of selecting the source line SL, a function of inputting a writing voltage generated from the DAC 1663 to the selected source line SL, a function of precharging the bit line BL, a function of bringing the bit line BL into an electrically floating state, and the like.

The output driver 1670 includes a selector 1671, an analog-digital converter circuit (ADC) 1672, and an output buffer 1673. The selector 1671 selects a source line SL to be accessed and transmits a voltage of the selected source line SL to the ADC 1672. The ADC 1672 has a function of converting an analog voltage into 3-bit digital data. The voltage of the source line SL is converted into 3-bit data in the ADC 1672, and the output buffer 1673 stores the data output from the ADC 1672.

### <Memory Cell>

FIG. 30A is a circuit diagram showing a configuration example of the memory cell 1611. The memory cell 1611 is a 2T gain cell and is electrically connected to the word lines WWL and RWL, the bit line BL, the source line SL, and the wiring BGL. The memory cell 1611 includes a node SN, an OS transistor MO61, a transistor MP61, and a capacitor C61. The OS transistor MO61 is a write transistor. The transistor MP61 is a read transistor and is formed using a p-channel Si transistor, for example. The capacitor C61 is a storage capacitor for holding the voltage of the node SN. The node SN is a data holding node and corresponds to a gate of the transistor MP61 here.

The write transistor of the memory cell 1611 is formed using the OS transistor MO61; thus, the NOSRAM 1600 can hold data for a long time.

In the example of FIG. 30A, a write bit line and a read bit line are a common bit line; however, as shown in FIG. 30B, a write bit line WBL and a read bit line RBL may be provided.

FIGS. 30C to 30E show other configuration examples of the memory cell. FIGS. 30C to 30E show examples where the write bit line and the read bit line are provided; however, as shown in FIG. 30A, the write bit line and the read bit line may be a common bit line.

The memory cell 1612 shown in FIG. 30C is a modification example of the memory cell 1611 where the read transistor is changed into an n-channel transistor (MN61). The transistor MN61 may be an OS transistor or a Si transistor.

In the memory cells 1611 and 1612, the OS transistor MO61 may be an OS transistor with no back gate.

The memory cell 1613 shown in FIG. 30D is a 3T gain cell and is electrically connected to the word lines WWL and RWL, the bit lines WBL and RBL, the source line SL, the wiring BGL, and a wiring PCL. The memory cell 1613 includes a node SN, an OS transistor MO62, a transistor MP62, a transistor MP63, and a capacitor C62. The OS transistor MO62 is a write transistor. The transistor MP62 is a read transistor and the transistor MP63 is a selection transistor.

The memory cell 1614 shown in FIG. 30E is a modification example of the memory cell 1613 where the read transistor and the selection transistor are changed into n-channel transistors (MN62 and MN63). Each of the transistors MN62 and MN63 may be an OS transistor or a Si transistor.

The OS transistors provided in the memory cells 1611 to 1614 may each be a transistor with no back gate or a transistor with a back gate.

There is theoretically no limitation on the number of rewriting operations of the NOSRAM 1600 because data is rewritten by charging and discharging of the capacitor C61; and data can be written to and read from the NOSRAM with low energy. Furthermore, since data can be held for a long time, the refresh rate can be reduced.

In the case where the semiconductor device described in any of the above embodiments is used for the memory cells 1611, 1612, 1613, and 1614, the transistor 200 can be used as the OS transistors MO61 and MO62, the capacitor 100 can be used as the capacitors C61 and C62, and the transistor 300 can be used as the transistors MP61 and MN62. Thus, the area occupied by each set consisting of one transistor and one capacitor in the top view can be reduced, so that the memory device of this embodiment can be highly integrated. As a result, storage capacity per unit area of the memory device of this embodiment can be increased.

The structure described in this embodiment can be used in appropriate combination with the structure described in any of the other embodiments.

### Embodiment 5

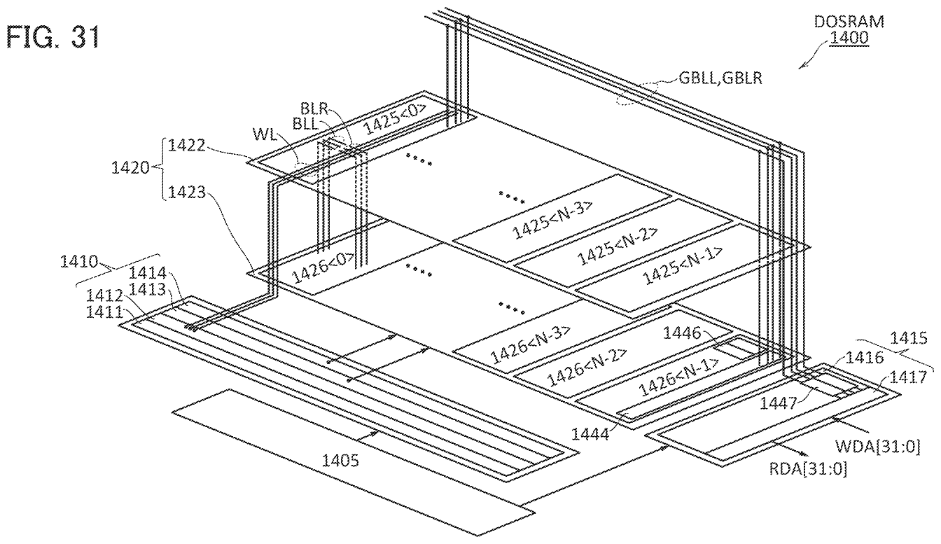

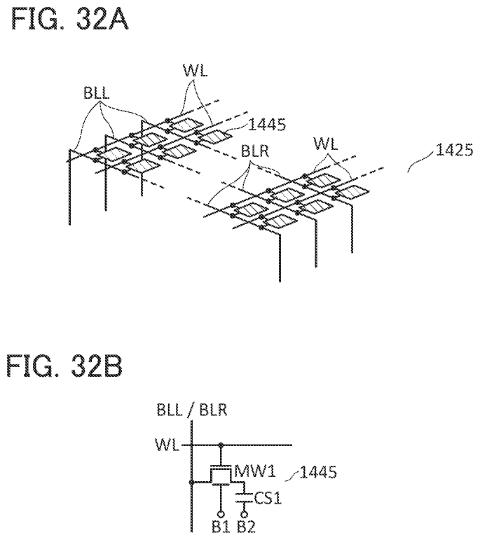

In this embodiment, a DOSRAM will be described as another example of the memory device of one embodiment of the present invention that includes an OS transistor and a capacitor, with reference to FIG. 31 and FIGS. 32A and 32B. A DOSRAM (registered trademark) stands for “dynamic oxide semiconductor RAM,” which is a RAM including a 1T1C (one-transistor/one-capacitor) memory cell. As in the NOSRAM, an OS memory is used in the DOSRAM.

### <<DOSRAM 1400>>

FIG. 31 illustrates a configuration example of the DOSRAM. As illustrated in FIG. 31, a DOSRAM 1400 includes a controller 1405, a row circuit 1410, a column circuit 1415, and a memory cell and sense amplifier array 1420 (hereinafter referred to as MC-SA array 1420).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR.

### (MC-SA Array 1420)

The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts a hierarchical bit line structure, where the bit lines are layered into local and global bit lines.

The memory cell array 1422 includes N local memory cell arrays 1425<0> to 1425<N−1>, where N is an integer greater than or equal to 2. FIG. 32A illustrates a configuration example of the local memory cell array 1425. The local memory cell array 1425 includes a plurality of memory cells 1445, a plurality of word lines WL, and a plurality of bit lines BLL and BLR. In the example in FIG. 32A, the local memory cell array 1425 has an open bit-line architecture but may have a folded bit-line architecture.

FIG. 32B illustrates a circuit configuration example of each of the memory cells 1445. The memory cells 1445 each include a transistor MW1, a capacitor CS1, and terminals B1 and B2. The transistor MW1 has a function of controlling the charging and discharging of the capacitor CS1. A gate of the transistor MW1 is electrically connected to the word line, a first terminal of the transistor MW1 is electrically connected to the bit line, and a second terminal of the transistor MW1 is electrically connected to a first terminal of the capacitor CS1. A second terminal of the capacitor CS1 is electrically connected to the terminal B2. A constant voltage (e.g., low power supply voltage) is applied to the terminal B2.

In the case where the semiconductor device described in any of the above embodiments is used in each of the memory cells 1445, the transistor 200 can be used as the transistor MW1, and the capacitor 100 can be used as the capacitor CS1. In this case, the area occupied by each set consisting of one transistor and one capacitor in the top view can be reduced; accordingly, the memory device of this embodiment can be highly integrated. As a result, storage capacity per unit area of the memory device of this embodiment can be increased.

The transistor MW1 includes a back gate, and the back gate is electrically connected to the terminal B1. This makes it possible to change the threshold voltage of the transistor MW1 with a voltage applied to the terminal B1. For example, a fixed voltage (e.g., negative constant voltage) may be applied to the terminal B1; alternatively, the voltage applied to the terminal B1 may be changed in response to the operation of the DOSRAM 1400.

The back gate of the transistor MW1 may be electrically connected to the gate, the first terminal, or the second terminal of the transistor MW1. The transistor MW1 does not necessarily include the back gate.

The sense amplifier array 1423 includes N local sense amplifier arrays 1426<0> to 1426<N−1>. The local sense amplifier arrays 1426 each include one switch array 1444 and a plurality of sense amplifiers 1446. Each of the sense amplifiers 1446 is electrically connected to a bit line pair. The sense amplifiers 1446 each have a function of precharging the corresponding bit line pair, a function of amplifying a voltage difference of the bit line pair, and a function of retaining the voltage difference. The switch array 1444 has a function of selecting a bit line pair and electrically connecting the selected bit line pair and a global bit line pair to each other.

Here, two bit lines that are compared simultaneously by the sense amplifier are collectively referred to as the bit line pair, and two global bit lines that are compared simultaneously by the global sense amplifier are collectively referred to as the global bit line pair. The bit line pair can be referred to as a pair of bit lines, and the global bit line pair can be referred to as a pair of global bit lines. Here, the bit line BLL and the bit line BLR form one bit line pair, and the global bit line GBLL and the global bit line GBLR form one global bit line pair. In the following description, the expressions “bit line pair (BLL, BLR)” and “global bit line pair (GBLL, GBLR)” are also used.

### (Controller 1405)

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

### (Row Circuit 1410)

The row circuit 1410 has a function of driving the MC-SA array 1420. The decoder 1411 has a function of decoding an address signal. The word line driver circuit 1412 generates a selection signal for selecting the word line WL of a row that is to be accessed.

The column selector 1413 and the sense amplifier driver circuit 1414 are circuits for driving the sense amplifier array 1423. The column selector 1413 has a function of generating a selection signal for selecting the bit line of a column that is to be accessed. With the selection signal from the column selector 1413, the switch array 1444 of each local sense amplifier array 1426 is controlled. With the control signal from the sense amplifier driver circuit 1414, each of the plurality of local sense amplifier arrays 1426 is driven independently.

### (Column Circuit 1415)

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

Each of the global sense amplifiers 1447 is electrically connected to the global bit line pair (GBLL, GBLR). The global sense amplifiers 1447 each have a function of amplifying a voltage difference of the global bit line pair (GBLL, GBLR), and a function of retaining the voltage difference. Data is written to and read from the global bit line pair (GBLL, GBLR) by the input/output circuit 1417.

The write operation of the DOSRAM 1400 is briefly described. Data is written to the global bit line pair by the input/output circuit 1417. The data of the global bit line pair is retained by the global sense amplifier array 1416. By the switch array 1444 of the local sense amplifier array 1426 specified by an address signal, the data of the global bit line pair is written to the bit line pair of a column where data is to be written. The local sense amplifier array 1426 amplifies the written data, and then retains the amplified data. In the specified local memory cell array 1425, the word line WL of the row where data is to be written is selected by the row circuit 1410, and the data retained at the local sense amplifier array 1426 is written to the memory cell 1445 of the selected row.

The read operation of the DOSRAM 1400 is briefly described. One row of the local memory cell array 1425 is specified with an address signal. In the specified local memory cell array 1425, the word line WL of a row where data is to be read is selected, and data of the memory cell 1445 is written to the bit line. The local sense amplifier array 1426 detects a voltage difference of the bit line pair of each column as data, and retains the data. The switch array 1444 writes the data of a column specified by the address signal to the global bit line pair; the data is chosen from the data retained at the local sense amplifier array 1426. The global sense amplifier array 1416 determines and retains the data of the global bit line pair. The data retained at the global sense amplifier array 1416 is output to the input/output circuit 1417. Thus, the read operation is completed.

The DOSRAM 1400 has no limitations on the number of rewrites in principle and data can be read and written with low energy consumption, because data is rewritten by charging and discharging the capacitor CS1. A simple circuit configuration of the memory cell 1445 allows a high memory capacity.

The transistor MW1 is an OS transistor. The extremely low off-state current of the OS transistor can inhibit charge leakage from the capacitor CS1. Therefore, the retention time of the DOSRAM 1400 is considerably longer than that of a DRAM. This allows less frequent refresh, which can reduce power needed for refresh operations. Thus, the DOSRAM 1400 is suitably used for a memory device that can rewrite a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which allows the storage capacitance of the memory cell 1445 to be reduced. In addition, providing the switch array 1444 in the local sense amplifier array 1426 allows the number of long bit lines to be reduced. For the reasons described above, a load to be driven during access to the DOSRAM 1400 is reduced, enabling a reduction in power consumption.

The structure described in this embodiment can be used in appropriate combination with any of the other structures described in the other embodiments.

### Embodiment 6

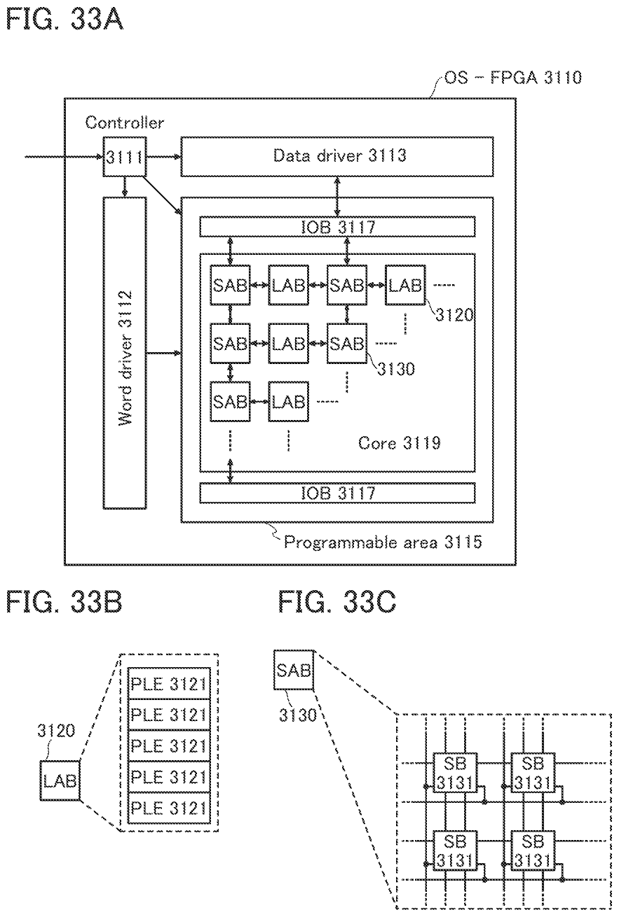

In this embodiment, a field-programmable gate array (FPGA) is described as an example of a semiconductor device one embodiment of the present invention in which an OS transistor and a capacitor according to are included, with reference to FIGS. 33A to 33C, FIGS. 34A to 34C, FIG. 35, and FIGS. 36A and 36B. In the FPGA of this embodiment, an OS memory is used for a configuration memory and a register. Here, such an FPGA is referred to as an “OS-FPGA”.

### <<OS-FPGA>>

FIG. 33A illustrates a configuration example of an OS-FPGA. An OS-FPGA 3110 illustrated in FIG. 33A is capable of normally-off (NOFF) computing for context switching by a multi-context configuration and fine-grained power gating in each PLE. The OS-FPGA 3110 includes a controller 3111, a word driver 3112, a data driver 3113, and a programmable area 3115.

The programmable area 3115 includes two input/output blocks (IOBs) 3117 and a core 3119. The IOB 3117 includes a plurality of programmable input/output circuits. The core 3119 includes a plurality of logic array blocks (LABs) 3120 and a plurality of switch array blocks (SABs) 3130. The LAB 3120 includes a plurality of PLEs 3121. FIG. 33B illustrates an example in which the LAB 3120 includes five PLEs 3121. As illustrated in FIG. 33C, the SAB 3130 includes a plurality of switch blocks (SBs) 3131 arranged in array. The LAB 3120 is connected to the LABs 3120 in four directions (on the left, right, top, and bottom sides) through its input terminals and the SABs 3130.

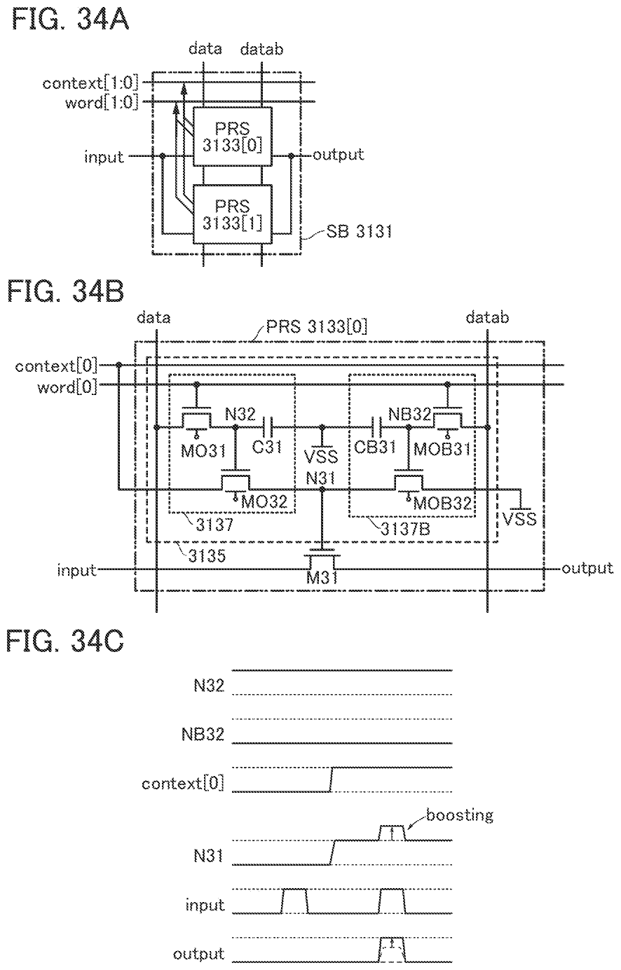

The SB 3131 is described with reference to FIGS. 34A to 34C. To the SB 3131 in FIG. 34A, data, datab, signals context[1:0], and signals word[1:0] are input. The data and the datab are configuration data, and the logics of the data and the datab are complementary to each other. The number of contexts in the OS-FPGA 3110 is two, and the signals context[1:0] are context selection signals. The signals word[1:0] are word line selection signals, and wirings to which the signals word[1:0] are input are each a word line.

The SB 3131 includes a programmable routing switch (PRS) 3133[0] and a PRS 3133[1]. The PRS 3133[0] and the PRS 3133[1] each include a configuration memory (CM) that can store complementary data. Note that in the case where the PRS 3133[0] and the PRS 3133[1] are not distinguished from each other, they are each referred to as a PRS 3133. The same applies to other elements.

FIG. 34B illustrates a circuit configuration example of the PRS 3133[0]. The PRS 3133[0] and the PRS 3133[1] have the same circuit configuration. The PRS 3133[0] and the PRS 3133[1] are different from each other in a context selection signal and a word line selection signal that are input. The signal context[0] and the signal word[0] are input to the PRS 3133[0], and the signal context[1] and the signal word[1] are input to the PRS 3133[1]. For example, in the SB 3131, when the signal context[0] is set to “H”, the PRS 3133[0] is activated.

The PRS 3133[0] includes a CM 3135 and a Si transistor M31. The Si transistor M31 is a pass transistor that is controlled by the CM 3135. The CM 3135 includes a memory circuit 3137 and a memory circuit 3137B. The memory circuit 3137 and the memory circuit 3137B have the same circuit configuration. The memory circuit 3137 includes a capacitor C31, an OS transistor MO31, and an OS transistor MO32. The memory circuit 3137B includes a capacitor CB31, an OS transistor MOB31, and an OS transistor MOB32.

In the case where the semiconductor device described in any of the above embodiments is used in the SAB 3130, the transistor 200 can be used as each of the OS transistors MO31 and MOB31, and the capacitor 100 can be used as each of the capacitors C31 and CB31. In this case, the area occupied by each set consisting of one transistor and one capacitor in the top view can be reduced; accordingly, the semiconductor device of this embodiment can be highly integrated.

The OS transistors MO31, MO32, MOB31, and MOB32 each include a back gate, and these back gates are electrically connected to power supply lines that each supply a fixed voltage.

A gate of the Si transistor M31, a gate of the OS transistor MO32, and a gate of the OS transistor MOB32 correspond to a node N31, a node N32, and a node NB32, respectively. The node N32 and the node NB32 are each a charge retention node of the CM 3135. The OS transistor MO32 controls the conduction state between the node N31 and a signal line for the signal context[0]. The OS transistor MOB32 controls the conduction state between the node N31 and a low-potential power supply line VSS.

A logic of data that the memory circuit 3137 retains and a logic of data that the memory circuit 3137B retains are complementary to each other. Thus, either the OS transistor MO32 or the OS transistor MOB32 is turned on.

The operation example of the PRS 3133[0] is described with reference to FIG. 34C. In the PRS 3133[0], in which configuration data has already been written, the node N32 is at “H”, whereas the node NB32 is at “L”.

The PRS 3133[0] is inactivated while the signal context[0] is at “L”. During this period, even when an input terminal of the PRS 3133[0] is transferred to “H”, the gate of the Si transistor M31 is kept at “L” and an output terminal of the PRS 3133[0] is also kept at “L”.

The PRS 3133[0] is activated while the signal context[0] is at “H”. When the signal context[0] is transferred to “H”, the gate of the Si transistor M31 is transferred to “H” by the configuration data stored in the CM 3135.

While the PRS 3133[0] is active, when the potential of the input terminal is changed to “H”, the gate voltage of the Si transistor M31 is increased by boosting because the OS transistor MO32 of the memory circuit 3137 is a source follower. As a result, the OS transistor MO32 of the memory circuit 3137 loses the driving capability, and the gate of the Si transistor M31 is brought into a floating state.

In the PRS 3133 with a multi-context function, the CM 3135 also functions as a multiplexer.

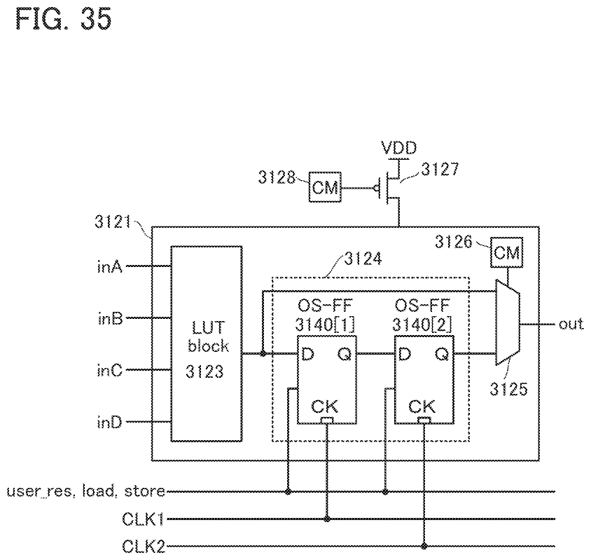

FIG. 35 illustrates a configuration example of the PLE 3121. The PLE 3121 includes a lookup table (LUT) block 3123, a register block 3124, a selector 3125, and a CM 3126. The LUT block 3123 is configured to select and output data in the LUT block in accordance with inputs inA to inD. The selector 3125 selects an output of the LUT block 3123 or an output of the register block 3124 in accordance with the configuration data stored in the CM 3126.

The PLE 3121 is electrically connected to a power supply line for a voltage VDD through a power switch 3127. Whether the power switch 3127 is turned on or off is determined in accordance with configuration data stored in a CM 3128. Fine-grained power gating can be performed by providing the power switch 3127 for each PLE 3121. The PLE 3121 that is not used after context switching can be power gated owing to the fine-grained power gating function; thus, standby power can be effectively reduced.

The register block 3124 is formed by nonvolatile registers to achieve NOFF computing. The nonvolatile registers in the PLE 3121 are each a flip-flop provided with an OS memory (hereinafter referred to as OS-FF).

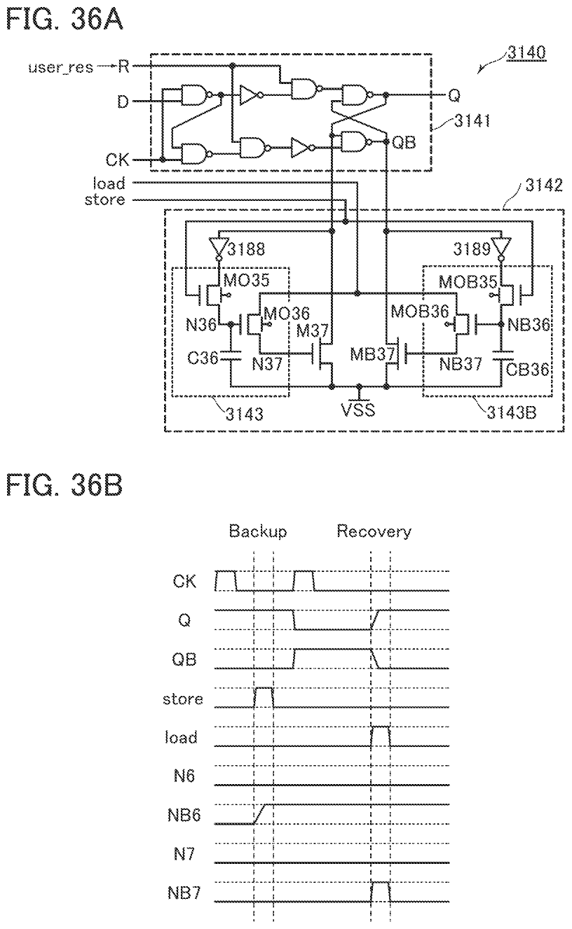

The register block 3124 includes an OS-FF 3140[1] and an OS-FF 3140[2]. A signal user_res, a signal load, and a signal store are input to the OS-FFs 3140[1] and 3140[2]. A clock signal CLK1 is input to the OS-FF 3140[1] and a clock signal CLK2 is input to the OS-FF 3140[2]. FIG. 36A illustrates a configuration example of the OS-FF 3140.

The OS-FF 3140 includes a FF 3141 and a shadow register 3142. The FF 3141 includes a node CK, a node R, a node D, a node Q, and a node QB. A clock signal is input to the node CK. The signal user_res is input to the node R. The signal user_res is a reset signal. The node D is a data input node, and the node Q is a data output node. The logics of the node Q and the node QB are complementary to each other.

The shadow register 3142 can function as a backup circuit of the FF 3141. The shadow register 3142 backs up data of the node Q and data of the node QB in response to the signal store and writes back the backed up data to the node Q and the node QB in response to the signal load.

The shadow register 3142 includes an inverter circuit 3188, an inverter circuit 3189, a Si transistor M37, a Si transistor MB37, a memory circuit 3143, and a memory circuit 3143B. The memory circuit 3143 and the memory circuit 3143B each have the same circuit configuration as the memory circuit 3137 of the PRS 3133. The memory circuit 3143 includes a capacitor C36, an OS transistor MO35, and an OS transistor MO36. The memory circuit 3143B includes a capacitor CB36, an OS transistor MOB35, and an OS transistor MOB36. A node N36 and a node NB36 correspond to a gate of the OS transistor MO36 and a gate of the OS transistor MOB36, respectively, and are each a charge retention node. A node N37 and a node NB37 correspond to a gate of the Si transistor M37 and a gate of the Si transistor MB37, respectively.

In the case where the semiconductor device described in any of the above embodiments is used in the LAB 3120, the transistor 200 can be used as each of the OS transistors MO35 and MOB35, and the capacitor 100 can be used as each of the capacitors C36 and CB36. In this case, the area occupied by each set consisting of one transistor and one capacitor in the top view can be reduced; accordingly, the semiconductor device of this embodiment can be highly integrated.

The OS transistors MO35, MO36, MOB35, and MOB36 each include a back gate, and these back gates are electrically connected to power supply lines that each supply a fixed voltage.

An example of an operation method of the OS-FF 3140 is described with reference to FIG. 36B.

### (Backup)

When the signal store at “H” is input to the OS-FF 3140, the shadow register 3142 backs up data of the FF 3141. The node N36 becomes “L” when the data of the node Q is written thereto, and the node NB36 becomes “H” when the data of the node QB is written thereto. After that, power gating is performed and the power switch 3127 is turned off. Although the data of the node Q and the data of the node QB of the FF 3141 are lost, the shadow register 3142 retains the backed up data even when power supply is stopped.

### (Recovery)

The power switch 3127 is turned on to supply power to the PLE 3121. After that, when the signal load at “H” is input to the OS-FF 3140, the shadow register 3142 writes back the backed up data to the FF 3141. The node N37 is kept at “L” because the node N36 is at “L”, and the node NB37 becomes “H” because the node NB36 is at “H”. Thus, the node Q becomes “H” and the node QB becomes “L”. That is, the OS-FF 3140 is restored to a state at the backup operation.

A combination of the fine-grained power gating and backup/recovery operation of the OS-FF 3140 allows power consumption of the OS-FPGA 3110 to be effectively reduced.

A possible error in a memory circuit is a soft error due to the entry of radiation. The soft error is a phenomenon in which a malfunction such as inversion of data stored in a memory is caused by electron-hole pair generation when a transistor is irradiated with at rays emitted from a material of a memory or a package or the like, secondary cosmic ray neutrons generated by nuclear reaction of primary cosmic rays entering the Earth's atmosphere from outer space with nuclei of atoms existing in the atmosphere, or the like. An OS memory including an OS transistor has a high soft-error tolerance. Therefore, the OS-FPGA 3110 including an OS memory can have high reliability.

The structure described in this embodiment can be used in appropriate combination with any of the other structures described in the other embodiments.

### Embodiment 7

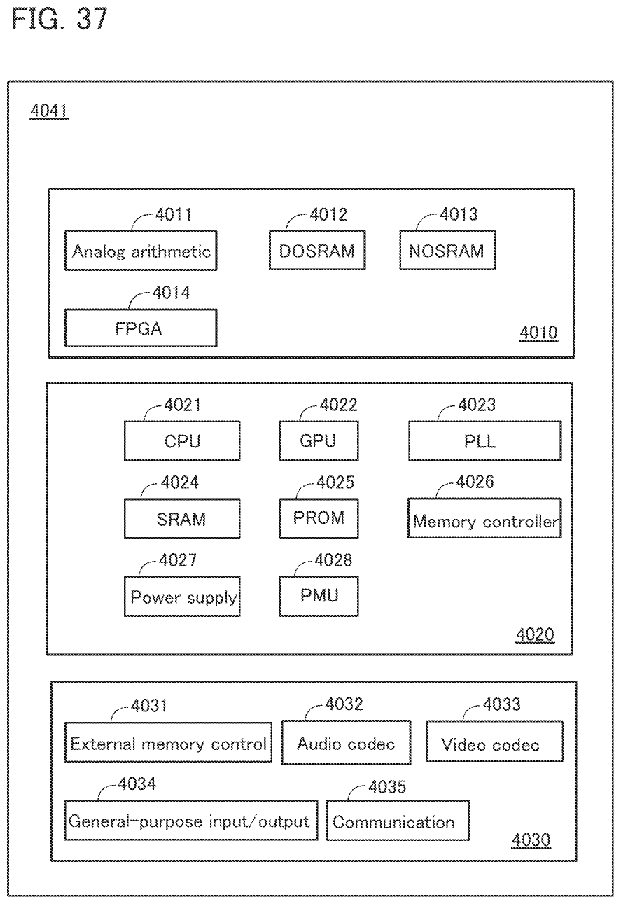

In this embodiment, an AI system in which the semiconductor device of any of the above-described embodiments is used will be described with reference to FIG. 37.

FIG. 37 is a block diagram illustrating a structure example of an AI system 4041. The AI system 4041 includes an arithmetic portion 4010, a control portion 4020, and an input/output portion 4030.

The arithmetic portion 4010 includes an analog arithmetic circuit 4011, a DOSRAM 4012, a NOSRAM 4013, and an FPGA 4014. The DOSRAM 1400, the NOSRAM 1600, and the OS-FPGA 3110 described in the above embodiments can be used as the DOSRAM 4012, the NOSRAM 4013, and the FPGA 4014, respectively.

The control portion 4020 includes a central processing unit (CPU) 4021, a graphics processing unit (GPU) 4022, a phase locked loop (PLL) 4023, a static random access memory (SRAM) 4024, a programmable read only memory (PROM) 4025, a memory controller 4026, a power supply circuit 4027, and a power management unit (PMU) 4028.

The input/output portion 4030 includes an external memory control circuit 4031, an audio codec 4032, a video codec 4033, a general-purpose input/output module 4034, and a communication module 4035.

The arithmetic portion 4010 can perform neural network learning or neural network inference.

The analog arithmetic circuit 4011 includes an analog/digital (A/D) converter circuit, a digital/analog (D/A) converter circuit, and a product-sum operation circuit.

The analog arithmetic circuit 4011 is preferably formed using an OS transistor. The analog arithmetic circuit 4011 formed using an OS transistor includes an analog memory and can execute a product-sum operation necessary for the learning and the inference with low power consumption.

The DOSRAM 4012 is a DRAM including an OS transistor which temporarily stores digital data sent from the CPU 4021. The DOSRAM 4012 includes a memory cell including an OS transistor and a read circuit portion including a Si transistor. Because the memory cell and the read circuit portion can be provided in different layers that are stacked, the entire circuit area of the DOSRAM 4012 can be small.

In the calculation with the neural network, the number of input data exceeds 1000 in some cases. In the case where the input data are stored in an SRAM, the input data has to be stored piece by piece because of the circuit area limitation and small storage capacity of the SRAM. The DOSRAM 4012 has a larger storage capacity than an SRAM because memory cells of the DOSRAM can be highly integrated even in a limited circuit area. Therefore, the DOSRAM 4012 can efficiently store the input data.

The NOSRAM 4013 is a nonvolatile memory including an OS transistor. The NOSRAM 4013 consumes less power in writing data than the other nonvolatile memories such as a flash memory, a resistive random access memory (ReRAM), and a magnetoresistive random access memory (MRAM). Furthermore, unlike a flash memory and a ReRAM which deteriorate by data writing, the NOSRAM does not have a limit on the number of times of data writing.

Furthermore, the NOSRAM 4013 can store multilevel data of two or more bits as well as one-bit binary data. The multilevel data storage in the NOSRAM 4013 leads to a reduction of the memory cell area per bit.

Because the NOSRAM 4013 can store analog data as well as digital data, the analog arithmetic circuit 4011 can use the NOSRAM 4013 as an analog memory. The NOSRAM 4013 can store analog data as it is, and thus a D/A converter circuit and an A/D converter circuit are unnecessary. Therefore, the area of a peripheral circuit for the NOSRAM 4013 can be reduced. In this specification, analog data refers to data having a resolution of three bits (eight levels) or more. The above-described multilevel data might be included in the analog data.

Data and parameters used in the neural network calculation can be once stored in the NOSRAM 4013. The data and parameters may be stored in a memory provided outside the AI system 4041 via the CPU 4021. However, the NOSRAM 4013 provided inside the AI system 4041 can store the data and parameters more quickly with lower power consumption. Furthermore, the NOSRAM 4013 enables a longer bit line than the DOSRAM 4012 and thus can have an increased storage capacity.

The FPGA 4014 is an FPGA including an OS transistor. By including the FPGA 4014, the AI system 4041 can establish a connection of a neural network such as a deep neural network (DNN), a convolutional neural network (CNN), a recurrent neural network (RNN), an autoencoder, a deep Boltzmann machine (DBM), a deep belief network (DBN), or the like described later, with a hardware. The connection of the neural network with a hardware enables higher speed performance.

The FPGA 4014 is an OS-FPGA. An OS-FPGA can have a smaller memory area than an FPGA formed using an SRAM. Thus, adding a context switching function only causes a small increase in area. Moreover, an OS-FPGA can transmit data and parameters at high speed by utilizing the boosting.

In the AI system 4041, the analog arithmetic circuit 4011, the DOSRAM 4012, the NOSRAM 4013, and the FPGA 4014 can be provided on one die (chip). Thus, the AI system 4041 can perform calculation of the neural network quickly with low power consumption. The analog arithmetic circuit 4011, the DOSRAM 4012, the NOSRAM 4013, and the FPGA 4014 can be manufactured through the same manufacturing process. This enables the AI system 4041 to be manufactured at low cost.

Note that the arithmetic portion 4010 need not necessarily include all of the following: the DOSRAM 4012, the NOSRAM 4013, and the FPGA 4014. One or more memories are selected from the DOSRAM 4012, the NOSRAM 4013, and the FPGA 4014 in accordance with a problem that is desired to be solved in the AI system 4041.

The AI system 4041 can implement a method such as a deep neural network (DNN), a convolutional neural network (CNN), a recurrent neural network (RNN), an autoencoder, a deep Boltzmann machine (DBM), or a deep belief network (DBN) in accordance with the problem that is desired to be solved. The PROM 4025 can store a program for implementing at least one of the methods. Part or the whole of the program may be stored in the NOSRAM 4013.

Most of the existing programs used as libraries are designed on the premise that the programs are processed by a GPU. Therefore, the AI system 4041 preferably includes the GPU 4022. The AI system 4041 can execute the bottleneck product-sum operation among all the product-sum operations used for learning and inference in the arithmetic portion 4010, and execute the other product-sum operations in the GPU 4022. In this manner, the learning and inference can be performed at high speed.

The power supply circuit 4027 generates not only a low power supply potential for a logic circuit but also a potential for an analog operation. The power supply circuit 4027 may include an OS memory. In this case, storing a reference potential in the OS memory can reduce the power consumption of the power supply circuit 4027.

The PMU 4028 is configured to temporarily stop the power supply to the AI system 4041.

As a register in each of the CPU 4021 and the GPU 4022, an OS memory is preferably included. By including the OS memory, each of the CPU 4021 and the GPU 4022 can retain data (logic value) in the OS memory even when power supply is stopped. As a result, the AI system 4041 can save the power.

The PLL 4023 is configured to generate a clock. The AI system 4041 performs an operation on the basis of the clock generated by the PLL 4023. The PLL 4023 preferably includes an OS memory. When an OS memory is included in the PLL 4023, an analog potential with which the clock oscillation frequency is controlled can be held.

The AI system 4041 may store data in an external memory such as a DRAM. For this reason, the AI system 4041 preferably includes the memory controller 4026 functioning as an interface with the external DRAM. Furthermore, the memory controller 4026 is preferably provided near the CPU 4021 or the GPU 4022. Thus, quick data transmission can be achieved.

Some or all of the circuits illustrated in the control portion 4020 can be formed on the same die as the arithmetic portion 4010. Thus, the AI system 4041 can execute neural network calculation at high speed with low power consumption.

Data used for neural network calculation is stored in an external storage device such as a hard disk drive (HDD) or a solid state drive (SSD) in many cases. Therefore, the AI system 4041 preferably includes the external memory control circuit 4031 functioning as an interface with the external storage device.

Because audio and video are often subjects of the learning and inference using the neural network, the AI system 4041 includes the audio codec 4032 and the video codec 4033. The audio codec 4032 encodes and decodes audio data, and the video codec 4033 encodes and decodes video data.

The AI system 4041 can perform learning or make an inference using data obtained from an external sensor. For this reason, the AI system 4041 includes the general-purpose input/output module 4034. The general-purpose input/output module 4034 includes a universal serial bus (USB), an inter-integrated circuit (I2C), or the like, for example.

The AI system 4041 can perform learning or make an inference using data obtained via the Internet. For this reason, the AI system 4041 preferably includes the communication module 4035.

The analog arithmetic circuit 4011 may include a multi-level flash memory as an analog memory. However, the flash memory has a limit on the number of rewriting times. In addition, the multi-level flash memory is extremely difficult to embed; in other words, the arithmetic circuit and the memory are difficult to form on the same die.

Alternatively, the analog arithmetic circuit 4011 may include a ReRAM as an analog memory. However, the ReRAM has a limit on the number of rewriting times and also has a problem in storage accuracy. Moreover, because the ReRAM is a two-terminal element, the complicated circuit design is necessary for separating data writing and data reading.

Further alternatively, the analog arithmetic circuit 4011 may include an MRAM as an analog memory. However, the MRAM has a problem in storage capacity because of its low magnetoresistive ratio.

In consideration of the above, an OS memory is preferably used as an analog memory in the analog arithmetic circuit 4011.

The structure described in this embodiment can be used in appropriate combination with any of the other structures described in the other embodiments.

### Embodiment 8

### Application Example of AI System

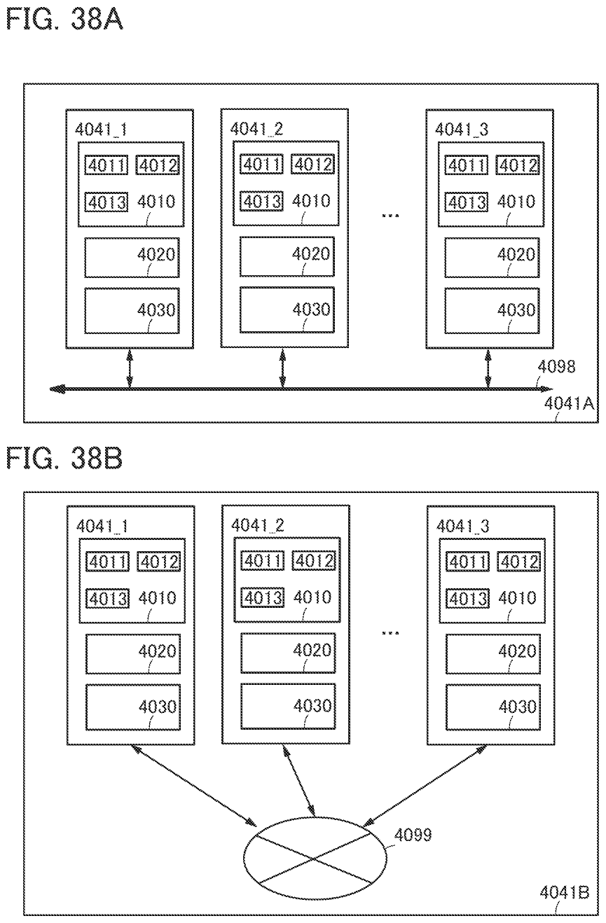

In this embodiment, application examples of the AI system described in the above embodiment will be described with reference to FIGS. 38A and 38B.

FIG. 38A illustrates an AI system 4041A in which the AI systems 4041 described with FIG. 37 are arranged in parallel and a signal can be transmitted between the systems via a bus line.

The AI system 4041A illustrated in FIG. 38A includes AI systems 4041_1 to 4041_n (n is a natural number). The AI systems 4041_1 to 4041_n are connected to each other via a bus line 4098.

FIG. 38B illustrates an AI system 4041B in which the AI systems 4041 described with FIG. 37 are arranged in parallel as in FIG. 38A and a signal can be transmitted between the systems via a network.

The AI system 4041B illustrated in FIG. 38B includes the AI systems 4041_1 to 4041_n. The AI systems 4041_1 to 4041_n are connected to each other via a network 4099.

A communication module is provided in each of the AI systems 4041_1 to 4041_n; such a configuration enables wireless or wired communication via the network 4099. A communication module can communicate via an antenna. Communication can be performed when an electronic device is connected to a computer network such as the Internet (infrastructure of the World Wide Web, WWW), an intranet, an extranet, a personal area network (PAN), a local area network (LAN), a campus area network (CAN), a metropolitan area network (MAN), a wide area network (WAN), or a global area network (GAN), for example. In the case of performing wireless communication, it is possible to use, as a communication protocol or a communication technology, a communications standard such as Long-Term Evolution (LTE), Global System for Mobile Communication (GSM: registered trademark), Enhanced Data Rates for GSM Evolution (EDGE), Code Division Multiple Access 2000 (CDMA2000), or W-CDMA (registered trademark), or a communications standard developed by IEEE such as Wi-Fi (registered trademark), Bluetooth (registered trademark), or ZigBee (registered trademark).

With the configuration illustrated in FIG. 38A or FIG. 38B, analog signals obtained with external sensors or the like can be processed by different AI systems. For example, analog signals containing biological information such as brain waves, a pulse, blood pressure, and body temperature obtained with a variety of sensors such as a brain wave sensor, a pulse wave sensor, a blood pressure sensor, and a temperature sensor can be processed by different AI systems. Since each of the AI systems performs signal processing or learning, the amount of information processed by each AI system can be reduced. Accordingly, the signal processing or learning requires a smaller amount of arithmetic processing. As a result, recognition accuracy can be increased. With the use of data obtained with each AI system, biological information that irregularly changes should be able to be collectively grasped instantly.

The structure described in this embodiment can be used in appropriate combination with any of the other structures described in the other embodiments.

### Embodiment 9

In this embodiment, an example of an IC incorporating the AI system described in the above embodiment will be described.

In the AI system described in the above embodiment, a digital processing circuit (e.g., a CPU) that includes a Si transistor and an OS-FPGA, an OS memory (e.g., a DOSRAM or a NOSRAM), and an analog arithmetic circuit that include OS transistors can be integrated into one die.

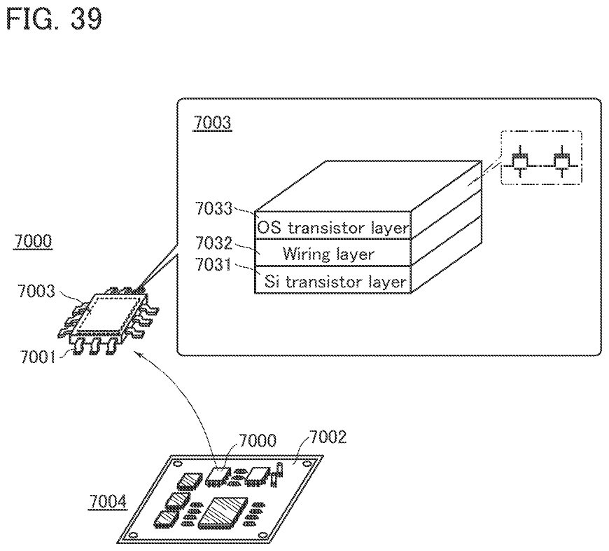

FIG. 39 illustrates the example of the IC incorporating the AI system. An AI system IC 7000 illustrated in FIG. 39 includes a lead 7001 and a circuit portion 7003. The AI system IC 7000 is mounted on a printed circuit board 7002, for example. A plurality of such IC chips are combined and electrically connected to each other on the printed circuit board 7002; thus, a circuit board on which electronic components are mounted (a circuit board 7004) is formed. In the circuit portion 7003, the circuits described in the above embodiment are provided on one die. The circuit portion 7003 has a stacked-layer structure as illustrated in FIG. 27 and FIG. 28 in the above embodiment, which is broadly divided into a Si transistor layer 7031, a wiring layer 7032, and an OS transistor layer 7033. Since the OS transistor layer 7033 can be stacked over the Si transistor layer 7031, the size of the AI system IC 7000 can be easily reduced.

Although a Quad Flat Package (QFP) is used as a package of the AI system IC 7000 in FIG. 39, the package is not limited thereto.

The digital processing circuit (e.g., a CPU) and the OS-FPGA, the OS memory (e.g., a DOSRAM or a NOSRAM), and the analog arithmetic circuit that include OS transistors can all be formed in the Si transistor layer 7031, the wiring layer 7032, and the OS transistor layer 7033. In other words, elements included in the AI system can be formed through the same manufacturing process. Thus, the number of steps in the manufacturing process of the IC described in this embodiment does not need to be increased even when the number of elements is increased, and accordingly the AI system can be incorporated into the IC at low cost.

The structure described in this embodiment can be used in appropriate combination with any of the other structures described in the other embodiments.

### Embodiment 10

### <Electronic Device>

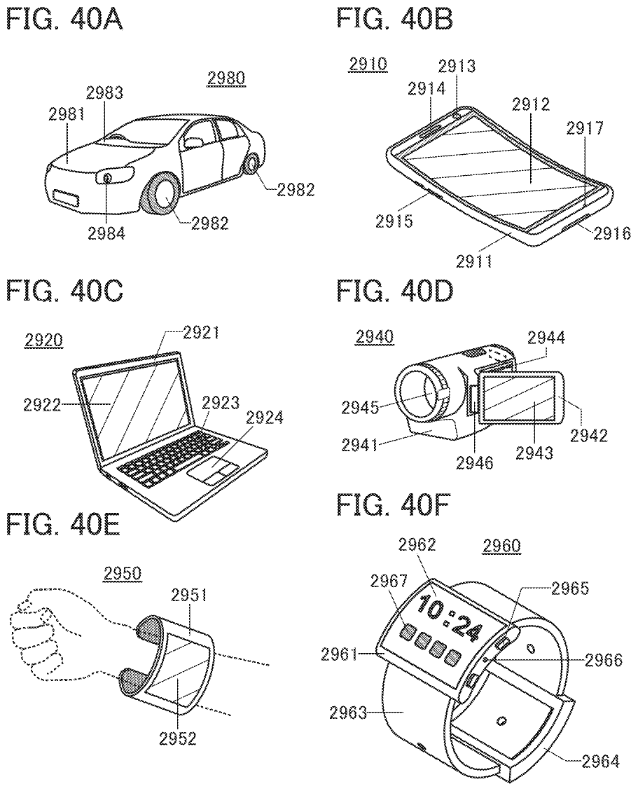

A semiconductor device of one embodiment of the present invention can be used for a variety of electronic devices. FIGS. 40A to 40F illustrate specific examples of the electronic devices including the semiconductor device of one embodiment of the present invention.

FIG. 40A is an external view illustrating an example of a car. A car 2980 includes a car body 2981, wheels 2982, a dashboard 2983, lights 2984, and the like. The car 2980 includes an antenna, a battery, and the like.

An information terminal 2910 illustrated in FIG. 40B includes a housing 2911, a display portion 2912, a microphone 2917, a speaker portion 2914, a camera 2913, an external connection portion 2916, an operation switch 2915, and the like. A display panel and a touch screen that use a flexible substrate are provided in the display portion 2912. In the housing 2911 of the information terminal 2910, an antenna, a battery, and the like are provided. The information terminal 2910 can be used as, for example, a smartphone, a mobile phone, a tablet information terminal, a tablet personal computer, or an e-book reader.

A notebook personal computer 2920 illustrated in FIG. 40C includes a housing 2921, a display portion 2922, a keyboard 2923, a pointing device 2924, and the like. In the housing 2921 of the notebook personal computer 2920, an antenna, a battery, and the like are provided.

A video camera 2940 illustrated in FIG. 40D includes a housing 2941, a housing 2942, a display portion 2943, operation switches 2944, a lens 2945, a joint 2946, and the like. The operation switches 2944 and the lens 2945 are provided for the housing 2941, and the display portion 2943 is provided for the housing 2942. In the housing 2941 of the video camera 2940, an antenna, a battery, and the like are provided. The housing 2941 and the housing 2942 are connected to each other with the joint 2946, and the angle between the housing 2941 and the housing 2942 can be changed with the joint 2946. The orientation of an image on the display portion 2943 may be changed and display and non-display of an image can be switched depending on the angle between the housings 2941 and 2942.

FIG. 40E illustrates an example of a bangle-type information terminal. An information terminal 2950 includes a housing 2951, a display portion 2952, and the like. In the housing 2951 of the information terminal 2950, an antenna, a battery, and the like are provided. The display portion 2952 is supported by the housing 2951 having a curved surface. A display panel formed with a flexible substrate is provided in the display portion 2952, whereby the information terminal 2950 can be a user-friendly information terminal that is flexible and lightweight.

FIG. 40F illustrates an example of a watch-type information terminal. An information terminal 2960 includes a housing 2961, a display portion 2962, a band 2963, a buckle 2964, an operation switch 2965, an input/output terminal 2966, and the like. In the housing 2961 of the information terminal 2960, an antenna, a battery, and the like are provided. The information terminal 2960 is capable of executing a variety of applications such as mobile phone calls, e-mailing, viewing and editing texts, music reproduction, Internet communication, and a computer game.

The display surface of the display portion 2962 is curved, and images can be displayed on the curved display surface. In addition, the display portion 2962 includes a touch sensor, and operation can be performed by touching the screen with a finger, a stylus, or the like. For example, by touching an icon 2967 displayed on the display portion 2962, an application can be started. With the operation switch 2965, a variety of functions such as time setting, power on/off, on/off of wireless communication, setting and cancellation of a silent mode, and setting and cancellation of a power saving mode can be performed. For example, the functions of the operation switch 2965 can be set by setting the operation system incorporated in the information terminal 2960.

The information terminal 2960 can employ near field communication that is a communication method based on an existing communication standard. In that case, for example, mutual communication between the information terminal 2960 and a headset capable of wireless communication can be performed, and thus hands-free calling is possible. Moreover, the information terminal 2960 includes the input/output terminal 2966, and data can be directly transmitted to and received from another information terminal via a connector. In addition, charging via the input/output terminal 2966 is possible. Note that the charging operation may be performed by wireless power feeding without using the input/output terminal 2966.

For example, a memory device including the semiconductor device of one embodiment of the present invention can hold control data, a control program, or the like of the above electronic device for a long time. With the use of the semiconductor device of one embodiment of the present invention, a highly reliable electronic device can be provided.

This embodiment can be implemented in an appropriate combination with any of the structures described in the other embodiments and the like.

### REFERENCE NUMERALS

100: capacitor, 100a: capacitor, 100b: capacitor, 120: conductor, 120A: conductive film, 130: insulator, 130A: insulating film, 150: insulator, 200: transistor, 200a: transistor, 200b: transistor, 205: conductor, 205a: conductor, 205b: conductor, 207: conductor, 207a: conductor, 207b: conductor, 210: insulator, 212: insulator, 214: insulator, 216: insulator, 218: conductor, 220: insulator, 222: insulator, 224: insulator, 230: oxide, 230a: oxide, 230A: oxide film, 230b: oxide, 230B: oxide film, 230c: oxide, 230C: oxide film, 231: region, 231a: region, 231b: region, 232: junction region, 232a: junction region, 232b: junction region, 233: region, 234: region, 239: region, 250: insulator, 250A: insulating film, 252: conductor, 252a: conductor, 252b: conductor, 252c: conductor, 252d: conductor, 260: conductor, 260a: conductor, 260A: conductive film, 260b: conductor, 260B: conductive film, 260c: conductor, 260C: conductive film, 270: insulator, 270A: insulating film, 271: insulator, 271A: insulating film, 272: insulator, 272A: insulating film, 274: insulator, 274A: insulating film, 280: insulator, 280A: insulating film, 286: insulator, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: insulator, 330, insulator, 350: insulator, 352: insulator, 354: insulator, 356: insulator, 360: insulator, 362: insulator, 364: insulator, 366: insulator, 370: insulator, 372: insulator, 374: insulator, 376: conductor, 380: insulator, 382: insulator, 384: insulator, 386: conductor, 600: cell, 600a: cell, 600b: cell.

This application is based on Japanese Patent Application Serial No. 2017-023595 filed with Japan Patent Office on Feb. 10, 2017 and Japanese Patent Application Serial No. 2017-027613 filed with Japan Patent Office on Feb. 17, 2017, the entire contents of which are hereby incorporated by reference.

1. A semiconductor device comprising:
a first oxide comprising:
a first region and a second region adjacent to each other; and
a third region and a fourth region with the first region and the second region provided between the third region and the fourth region;
a second oxide over the first region;
a first insulator over the second oxide;
a first conductor over the first insulator;
a second insulator over the second oxide, the second insulator being in contact with a side surface of the first insulator and a side surface of the first conductor;
a third insulator over the second region, the third insulator being in contact with a side surface of the second insulator; and
a second conductor over the second region with the third insulator provided between the second conductor and the second region,
wherein a part of the third insulator is positioned between the second conductor and the side surface of the second insulator.

2. The semiconductor device according to claim 1,
wherein the first oxide is over a third conductor, and
wherein a bottom surface of the fourth region is in contact with a top surface of the third conductor.

3. The semiconductor device according to claim 1,
wherein the second insulator comprises an oxide comprising one of or both aluminum and hafnium.

4. The semiconductor device according to claim 1,
wherein the first oxide comprises In, an element M, and Zn, and
wherein the element M is Al, Ga, Y, or Sn.

5. The semiconductor device according to claim 1,
wherein the second oxide comprises In, an element M, and Zn, and
wherein the element M is Al, Ga, Y, or Sn.

6. A semiconductor device comprising:
a transistor;
a capacitor;
a first oxide comprising:
a first region and a second region adjacent to each other; and
a third region and a fourth region with the first region and the second region provided between the third region and the fourth region;
a second oxide over the first region;
a first insulator over the second oxide;
a first conductor over the first insulator;
a second insulator over the second oxide, the second insulator being in contact with a side surface of the first insulator and a side surface of the first conductor;
a third insulator over the second region, the third insulator being in contact with a side surface of the second insulator; and
a second conductor over the second region with the third insulator provided between the second conductor and the second region,
wherein a part of the third insulator is positioned between the second conductor and the side surface of the second insulator,
wherein a part of the first region serves as a channel formation region of the transistor,
wherein the first insulator serves as a gate insulating film of the transistor,
wherein the first conductor serves as a gate electrode of the transistor,
wherein the second region serves as a first electrode of the capacitor,
wherein the third insulator serves as a dielectric of the capacitor, and
wherein the second conductor serves as a second electrode of the capacitor.

7. The semiconductor device according to claim 6,
wherein the fourth region is adjacent to the second region,
wherein the third region serves as one of a source and a drain of the transistor, and
wherein the second region and the fourth region serve as the other of the source and the drain of the transistor.

8. The semiconductor device according to claim 6,
wherein the first oxide is over a third conductor, and
wherein a bottom surface of the fourth region is in contact with a top surface of the third conductor.

9. The semiconductor device according to claim 6,
wherein the second insulator comprises an oxide comprising one of or both aluminum and hafnium.

10. The semiconductor device according to claim 6,
wherein the first oxide comprises In, an element M, and Zn, and
wherein the element M is Al, Ga, Y, or Sn.

11. The semiconductor device according to claim 6,
wherein the second oxide comprises In, an element M, and Zn, and
wherein the element M is Al, Ga, Y, or Sn.

12. A semiconductor device comprising:
a first oxide comprising:
a first region and a second region adjacent to each other;
a second oxide over the first region;
a first insulator over the second oxide;
a first conductor over the first insulator;
a second insulator over the second oxide, the second insulator being in contact with a side surface of the first insulator and a side surface of the first conductor;
a third insulator over the second region, the third insulator being in contact with a side surface of the second insulator;
a second conductor over the second region with the third insulator provided between the second conductor and the second region; and
a third conductor overlapping with the second conductor with the second region provided between the third conductor and the second conductor,
wherein a part of the third insulator is positioned between the second conductor and the side surface of the second insulator.

13. The semiconductor device according to claim 12,
wherein a part of the first region serves as a channel formation region of the transistor,
wherein the first insulator serves as a gate insulating film of the transistor,
wherein the first conductor serves as a gate electrode of the transistor,
wherein the second region serves as a first electrode of the capacitor,
wherein the third insulator serves as a dielectric of the capacitor,
wherein the second conductor serves as a second electrode of the capacitor, and
wherein the third conductor serves as a plug electrically connected to the transistor.

14. The semiconductor device according to claim 12,
wherein the first oxide further comprises a third region and a fourth region with the first region and the second region provided between the third region and the fourth region.

15. The semiconductor device according to claim 14,
wherein the second region serves as one of a source and a drain of the transistor, and
wherein the third region serves as the other of the source and the drain of the transistor.

16. The semiconductor device according to claim 12,
wherein the first oxide is over the third conductor, and
wherein a bottom surface of the second region is in contact with a top surface of the third conductor.

17. The semiconductor device according to claim 12,
wherein the second insulator comprises an oxide comprising one of or both aluminum and hafnium.

18. The semiconductor device according to claim 12,
wherein the first oxide comprises In, an element M, and Zn, and
wherein the element M is Al, Ga, Y, or Sn.

19. The semiconductor device according to claim 12,
wherein the second oxide comprises In, an element M, and Zn, and
wherein the element M is Al, Ga, Y, or Sn.
